(19) United States
(12) Patent Application Publication
(10) Pub. No.: US 2026/0197994 A1
(43) Pub. Date: Jul. 9, 2026

(54) SEMICONDUCTOR MEMORY DEVICES

(71) Applicant: Samsung Electronics Co., Ltd., Suwon-si (KR)

(72) Inventors: Juho Lee, Suwon-si (KR); Seungmin Lee, Suwon-si (KR); Sungjin Kim, Suwon-si (KR); Wonsok Lee, Suwon-si (KR); Minhee Cho, Suwon-si (KR); Daewon Ha, Suwon-si (KR); Sungduk Hong, Suwon-si, (KR)

(21) Appl. No.: 19/431,536

(22) Filed: Dec. 23, 2025

(30) Foreign Application Priority Data
Jan. 8, 2025 (KR) 10-2025-0002881

(51) Int. Cl. H10B 12/00

(52) U.S. Cl. CPC H10B 12/482; H10B 12/03; H10B 12/315

(57) ABSTRACT

A semiconductor memory device includes a channel pattern, a gate electrode layer configured to surround at least part of each of an upper surface and a lower surface of the channel pattern and extend in a first horizontal direction, a bit line structure connected to one end of the channel pattern in a second horizontal direction orthogonal to the first horizontal direction and configured to extend in a vertical direction, a capacitor structure connected to another end of the channel pattern in the second horizontal direction, a gate dielectric layer between the channel pattern and the gate electrode layer and configured to cover the upper surface, the lower surface, and both side surfaces, in the first horizontal direction, of the channel pattern, and a bit line shield structure on both sides of the bit line structure in the first horizontal direction and configured to extend in the vertical direction.

### CROSS-REFERENCE TO RELATED APPLICATION

This application is based on and claims priority under 35 U.S.C. § 119 to Korean Patent Application No. 10-2025-0002881, filed on Jan. 8, 2025, in the Korean Intellectual Property Office, the disclosure of which is incorporated by reference herein in its entirety.

### BACKGROUND

As miniaturization, multi-functionality, and high performance of electronic products are required, high-capacity semiconductor memory devices are required, and accordingly, in order to provide the high-capacity semiconductor memory devices, integrations of the semiconductor memory devices need to be increased. Because integrations of conventional two-dimensional semiconductor memory devices are mainly determined by areas occupied by unit memory cells, integrations of two-dimensional semiconductor memory devices are increasing but are still restrictive. A three-dimensional semiconductor memory device that increases memory capacity by vertically stacking a plurality of memory cells on a substrate is proposed.

### SUMMARY

The present disclosure relates to a semiconductor memory device, and more specifically, to a three-dimensional semiconductor memory device.

The present disclosure provides a three-dimensional semiconductor memory device that is improved in operation reliability and operation characteristics and may increase integration by facilitating a manufacturing process.

According to an aspect of the present disclosure, a semiconductor memory device includes a channel pattern, a gate electrode layer configured to surround at least part of each of an upper surface and a lower surface of the channel pattern and extend in a first horizontal direction, a bit line structure connected to one end of the channel pattern in a second horizontal direction orthogonal to the first horizontal direction and configured to extend in a vertical direction, a capacitor structure connected to another end of the channel pattern in the second horizontal direction, a gate dielectric layer provided between the channel pattern and the gate electrode layer and configured to cover the upper surface, the lower surface, and both side surfaces, in the first horizontal direction, of the channel pattern, and a bit line shield structure arranged on both sides of the bit line structure in the first horizontal direction and configured to extend in the vertical direction, wherein the gate dielectric layer includes a base insulating layer covering at least one of the upper surface and the lower surface of the channel pattern, and a channel cover insulating layer covering the upper surface, the lower surface, and both side surfaces, in the first horizontal direction, of the channel structure including the channel pattern and the base insulating layer.

According to another aspect of the present disclosure, a semiconductor memory device includes a plurality of channel patterns separated from each other in a first horizontal direction, a second horizontal direction orthogonal to the first horizontal direction, and a vertical direction, a plurality of gate electrode layers configured to respectively surround at least parts of each of upper surfaces and lower surfaces of the plurality of channel patterns and extend in the first horizontal direction, a plurality of bit line structures connected to first ends of the plurality of channel patterns in the second horizontal direction, separated from each other in the first horizontal direction, and configured to extend in the vertical direction, a plurality of bit line shield structures alternately arranged with the plurality of bit line structures in the first horizontal direction and configured to extend in the vertical direction, a plurality of capacitor structures connected to second ends of the plurality of channel patterns in the second horizontal direction, and a plurality of gate dielectric layers arranged respectively between the plurality of channel patterns and the plurality of gate electrode layers, configured to respectively cover upper surfaces, lower surfaces, and both side surfaces, in the first horizontal direction, of the plurality of channel patterns, wherein each of the plurality of gate dielectric layers includes a pair of base insulating layers respectively covering an upper surface and a lower surface of each of the plurality of channel patterns, and a channel cover insulating layer covering an upper surface, a lower surface, and both side surfaces, in the first horizontal direction, of the channel structure including each of the plurality of channel patterns and the pair of base insulating layers.

According to another aspect of the present disclosure, a semiconductor memory device includes a plurality of channel patterns separated from each other in a first horizontal direction, a second horizontal direction orthogonal to the first horizontal direction, and a vertical direction, and each including an oxide semiconductor material, a plurality of gate electrode layers configured to respectively surround at least parts of each of upper surfaces and lower surfaces of the plurality of channel patterns and extend in the first horizontal direction, a plurality of bit line structures connected to first ends of the plurality of channel patterns in the second horizontal direction, separated from each other in the first horizontal direction and configured to extend in the vertical direction, and each of the plurality of bit line structures includes a core conductive layer and an oxide semiconductor layer between the core conductive layer and each of the plurality of channel patterns, a plurality of bit line shield structures alternately arranged with the plurality of bit line structures in the first horizontal direction and configured to extend in the vertical direction, and separated from the plurality of channel patterns, a plurality of capacitor structures connected to second ends of the plurality of channel patterns in the second horizontal direction, and a plurality of gate dielectric layers arranged respectively between the plurality of channel patterns and the plurality of gate electrode layers, configured to respectively cover upper surfaces, lower surfaces, and both side surfaces, in the first horizontal direction, of the plurality of channel patterns, wherein each of the plurality of gate dielectric layers includes a pair of base insulating layers respectively covering an upper surface and a lower surface of each of the plurality of channel patterns, and a channel cover insulating layer covering an upper surface, a lower surface, and both side surfaces, in the first horizontal direction, of the channel structure including each of the plurality of channel patterns and the pair of base insulating layers.

According to another aspect of the present disclosure, a method of manufacturing a semiconductor memory device includes forming a plurality of sacrificial insulating layers, a plurality of base insulating layers, and a plurality of sacrificial semiconductor layers on a substrate; partially removing the plurality of sacrificial insulating layers, the plurality of base insulating layers, and the plurality of sacrificial semiconductor layers to form a plurality of first element isolation cut regions separated from each other in a first horizontal direction and extending in a second horizontal direction orthogonal to the first horizontal direction; partially removing the plurality of sacrificial insulating layers, the plurality of base insulating layers, and the plurality of sacrificial semiconductor layers to form a plurality of second element isolation cut regions and a plurality of capacitor isolation cut regions separated from each other and arranged alternately in the second horizontal direction and extending in the first horizontal direction; partially removing the plurality of sacrificial insulating layers, the plurality of base insulating layers, and the plurality of sacrificial semiconductor layers through the plurality of capacitor isolation cut regions; forming a plurality of capacitor structures respectively including a plurality of first electrodes, a plurality of second electrodes respectively covering the plurality of first electrodes, and a plurality of capacitor dielectric layers provided respectively between the plurality of first electrodes and the plurality of second electrodes, in a space where a part of each of the plurality of base insulating layers and a part of each of the plurality of sacrificial semiconductor layers are removed; removing the plurality of sacrificial semiconductor layers through the plurality of second element isolation cut regions and then forming a plurality of channel patterns in a space where the plurality of sacrificial semiconductor layers are removed; removing the plurality of sacrificial insulating layers through the plurality of first element isolation cut regions and the plurality of second element isolation cut regions, and then forming a plurality of channel cover insulating layers in a part of each of the plurality of first element isolation cut regions and a part of a space where the plurality of sacrificial insulating layers are removed and forming a plurality of gate dielectric layers including the plurality of base insulating layers and the plurality of channel cover insulating layers; forming a plurality of gate electrode layers covering the plurality of channel cover insulating layers; and forming a plurality of bit line structures connected to first ends of the plurality of channel patterns opposite to the plurality of first electrodes, separated from each other in the first horizontal direction, and extending in the vertical direction;

The plurality of sacrificial insulating layers, the plurality of base insulating layers, and the plurality of sacrificial semiconductor layers may be formed by a deposition process.

The plurality of base insulating layers may be provided respectively between the plurality of sacrificial insulating layers and the plurality of sacrificial semiconductor layers.

The plurality of sacrificial insulating layers, the plurality of sacrificial semiconductor layers, and the plurality of base insulating layers may be alternately stacked on the substrate.

The plurality of sacrificial insulating layers, the plurality of base insulating layers, and the plurality of sacrificial semiconductor layers may be alternately stacked on the substrate.

The plurality of channel patterns may each include an oxide semiconductor material. The plurality of gate electrode layers may be formed such that a horizontal width of each of the plurality of gate electrode layers in the second horizontal direction is less than a horizontal width of each of the plurality of channel patterns.

The method may further include forming a plurality of bit line shield structures alternately arranged with the plurality of bit line structures in the first horizontal direction and extending in the vertical direction.

The plurality of bit line shield structures may be formed such that a horizontal width of each of the plurality of bit line shield structures in the first horizontal direction is less than a horizontal width of each of the plurality of bit line structures in the first horizontal direction, and a horizontal width of each of the plurality of bit line shield structures in the second horizontal direction is equal to a horizontal width of the plurality of bit line structures in the second horizontal direction.

The plurality of bit line structures may each include a core conductive layer and an oxide semiconductor layer having a ring shape that extends continuously in a plane and surrounds the core conductive layer.

### BRIEF DESCRIPTION OF THE DRAWINGS

Implementations will be more clearly understood from the following detailed description taken in conjunction with the accompanying drawings in which:

FIG. 1 is an equivalent circuit diagram illustrating a memory cell array of a semiconductor memory device according to an implementation;

FIG. 2 is a block diagram illustrating a semiconductor memory device according to an implementation;

FIGS. 3A, 3B, 3C, 3D, and 3E are views illustrating a semiconductor memory device according to an implementation;

FIGS. 4A, 4B, 5A, 5B, 6A, 6B, 7A, 7B, 8A, 8B, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 21A, 21B, 22A, 22B, 23A, 23B, 24A, 24B, 25A, 25B, 26A, 26B,. 27A, 27B, 28A, 28B, 29A, 29B, 30A, 30B, 31A, 31B, 32A, 32B, 33A, 33B, 34A, 34B, 34C, 35A, 35B, 35C, 36A, 36B, 36C, 37A, 37B, 37C, 38A, 38B, and 38C are views illustrating a method of manufacturing a semiconductor memory device, according to an implementation;

FIG. 39 is a perspective view illustrating a semiconductor memory device according to an implementation, and FIGS. 40A, 40B, and 40C are cross-sectional views illustrating a semiconductor memory device according to an implementation;

FIGS. 41A and 41B are cross-sectional views illustrating a semiconductor memory device according to an implementation;

FIGS. 42A, 42B, and 42C are cross-sectional views illustrating a semiconductor memory device according to an implementation;

FIGS. 43A and 43B are cross-sectional views illustrating a semiconductor memory device according to an implementation;

FIG. 44A is a view illustrating a method of manufacturing a semiconductor memory device, according to an implementation, and FIG. 44B is a view illustrating a semiconductor memory device according an implementation;

FIG. 45A is a view illustrating a method of manufacturing a semiconductor memory device, according to an implementation, and FIG. 45B is a view illustrating a semiconductor memory device according to an implementation;

FIG. 46A is a view illustrating a method of manufacturing a semiconductor memory device, according to an implementation, and FIG. 46B is a view illustrating a semiconductor memory device according to an implementation;

FIG. 47A is a view illustrating a method of manufacturing a semiconductor memory device, according to an implementation, and FIG. 47B is a view illustrating a semiconductor memory device according to an implementation;

FIG. 48A is a view illustrating a method of manufacturing a semiconductor memory device, according to an implementation, and FIG. 48B is a view illustrating a semiconductor memory device according to an implementation;

FIG. 49A is a view illustrating a method of manufacturing a semiconductor memory device, according to an implementation, and FIG. 49B is a view illustrating a semiconductor memory device according to an implementation; and

FIG. 50A is a view illustrating a method of manufacturing a semiconductor memory device, according to an implementation, and FIG. 50B is a view illustrating a semiconductor memory device according to an implementation.

### DETAILED DESCRIPTION

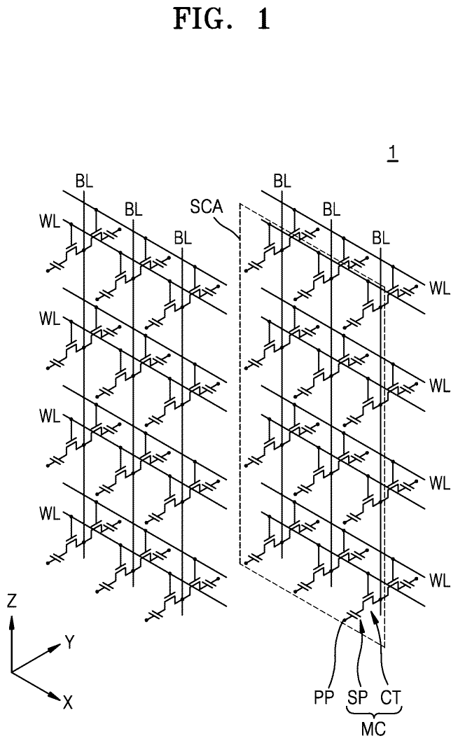

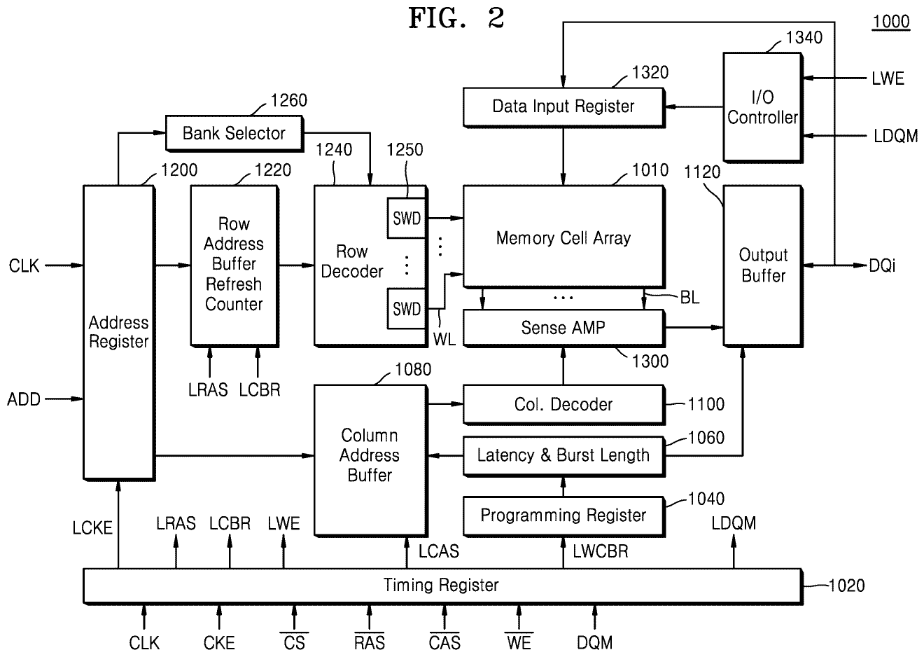

FIG. 1 is an equivalent circuit diagram illustrating a memory cell array of a semiconductor memory device according to an implementation.

Referring to FIG. 1, a memory cell array of a semiconductor memory device 1 according to an implementation may include a plurality of sub-cell arrays SCA. The plurality of sub-cell arrays SCA may each include a plurality of bit lines BL, a plurality of word lines WL, and a plurality of memory cells MC. The plurality of memory cells MC may each include a cell transistor CT and an information storage SP. The cell transistor CT may be between one word line WL and one bit line BL. The information storage SP may be a memory element capable of storing data.

The plurality of word lines WL may each be a conductive pattern (for example, a metal line) that is separated from a substrate and arranged on the substrate. The plurality of word lines WL may extend in a first horizontal direction (the X direction). The plurality of word lines WL in one sub-cell array SCA may be separated from each other in a vertical direction (the Z direction). The plurality of bit lines BL may extend in the vertical direction (the Z direction) from the substrate. The plurality of bit lines BL in one sub-cell array SCA may be separated from each other in the first horizontal direction (the X direction).

In the memory cell array of the semiconductor memory device 1, the plurality of word lines WL may extend in the first horizontal direction (the X direction) and may be separated from each other in a second horizontal direction (the Y direction) and the vertical direction (the Z direction). In the memory cell array of the semiconductor memory device 1, the plurality of bit lines BL may extend in the vertical direction (the Z direction) and may be separated from each other in the first horizontal direction (the X direction) and the second horizontal direction (the Y direction). The plurality of sub-cell arrays SCA may be arranged in the second horizontal direction (the Y direction).

In some implementations, the information storage SP may be a memory element using a capacitor, a memory element using a magnetic tunnel junction pattern, or a memory element using a variable resistor including a phase-change material. For example, the memory cell MC may be a dynamic random access memory (DRAM) cell, and the information storage SP may be a capacitor. In another implementation, the information storage SP may be a transistor capable of storing data together with the cell transistor CT.

A gate of the cell transistor CT may be connected to the word line WL, and a source region of the cell transistor CT may be connected to the bit line BL. The information storage SP may be connected to a drain region of the cell transistor CT. In some implementations, the information storage SP may be a capacitor including a first electrode, a second electrode, and a capacitor dielectric layer between the first electrode and the second electrode, and the first electrode of the capacitor may be connected to the drain region of the cell transistor CT, and the second electrode of the capacitor may be connected to a ground wire PP. In some implementations, the second electrode of the capacitor may be a part of the ground wire PP.

The memory cell array of the semiconductor memory device 1 may include the plurality of sub-cell arrays SCA, each including the plurality of memory cells MC arranged in rows and columns and separated from each other in the first horizontal direction (the X direction) and the vertical direction (the Z direction), the plurality of bit lines BL connected to a plurality of cell transistors CT of the plurality of memory cells MC arranged in the vertical direction (the Z direction) and separated from each other in the first horizontal direction (the X direction), and the plurality of word lines WL extending in the first horizontal direction (the X direction) and separated from each other in the vertical direction (the Z direction). The plurality of sub-cell arrays SCA may be arranged in the second horizontal direction (the Y direction). The semiconductor memory device 1 may include a plurality of memory cell arrays.

The first horizontal direction (the X direction), the second horizontal direction (the Y direction), and the vertical direction (the Z direction) may be respectively referred to as a first direction, a second direction, and a third direction. Alternatively, the first horizontal direction (the X direction), the vertical direction (the Z direction), and the second horizontal direction (the Y direction) may be respectively referred to as the first direction, the second direction, and the third direction. The first direction, the second direction, and the third direction may be orthogonal to each other.

Two sub-cell arrays SCA adjacent to each other in the second horizontal direction (the Y direction) may share the plurality of bit lines BL. Source regions of the cell transistors CT included in each of the two sub-cell arrays SCA may be connected to the bit lines BL shared by the two sub-cell arrays SCA. From each of the bit lines BL shared by the two sub-cell arrays SCA, source and drain regions of the cell transistors CT of the two sub-cell arrays SCA and the information storages SP may be arranged in opposite directions. For example, the source and drain regions of the cell transistors CT of one sub-cell array SCA connected to one bit line BL shared by the two sub-cell arrays SCA and the information storage SP may be arranged sequentially in the second horizontal direction (the Y direction), and the source and drain regions of the cell transistors CT of another sub-cell array SCA and the information storages SP may be arranged in a direction opposite to the second horizontal direction (the Y direction). For example, the plurality of bit lines BL may be arranged sequentially in the second horizontal direction (the Y direction), and two memory cells MC may be arranged, between a pair of bit lines BL adjacent to each other, in the second horizontal direction (the Y direction) at the same vertical level.

FIG. 2 is a block diagram illustrating a semiconductor memory device according to an implementation.

Referring to FIG. 2, a semiconductor memory device 1000 may include a memory cell array 1010 including DRAM cells, which are memory cells, and various circuit blocks for driving the DRAM cells. For example, a timing register 1020 may be activated when a chip select signal CSB changes from a deactivated level (for example, a logic high level) to an activated level (for example, a logic low level). The timing register 1020 may receive command signals, such as a clock signal CLK, a clock enable signal CKE, a chip select signal CSB, a row address strobe signal RASB, a column address strobe signal CASB, a write enable signal WEB, and a data input/output mask signal DQM, from the outside, and may process the received command signals to generate various internal command signals LRAS, LCBR, LWE, LCAS, LWCBR, and LDQM for controlling circuit blocks.

Some of the internal command signals generated by the timing register 1020 are stored in a programming register 1040. For example, latency information or burst length information related to data output may be stored in the programming register 1040. The internal command signals stored in the programming register 1040 may be provided to a latency/burst length controller 1060, and the latency/burst length controller 1060 may provide a control signal for controlling the latency or burst length of data output to the column decoder 1100 or the output buffer 1120 through a column address buffer 1080.

An address register 1200 may receive the clock signal CLK and an address signal ADD from the outside. A row address signal may be provided to a row decoder 1240 through a row address buffer 1220. Also, a column address signal may be provided to the column decoder 1100 through the column address buffer 1080. The row address buffer 1220 may further receive a refresh address signal generated by a refresh counter in response to refresh commands LRAS and LCBR, and may provide either the row address signal or the refresh address signal to the row decoder 1240. Also, the address register 1200 may provide a bank signal for selecting a bank to the bank selector 1260.

The row decoder 1240 may decode the row address signal or the refresh address signal received from the row address buffer 1220. The row decoder 1240 may include a plurality of sub-word line drivers 1250. The sub-word line drivers 1250 may activate the plurality of word lines WL of the memory cell array 1010. The sub-word line drivers 1250 may be arranged in blocks at predetermined intervals within the row decoder 1240 and arranged adjacent to the memory cell array 1010. For example, the sub-word line drivers 1250 may be arranged adjacent to one end of the memory cell array 1010 to be vertical to a sense amplifier 1300.

The column decoder 1100 may decode the column address signal and perform a selection operation on the plurality of bit lines BL of the memory cell array 1010. For example, a column selection line may be provided in the semiconductor memory device 1000, and the selection operation may be performed through the column selection line.

The sense amplifier 1300 may amplify data of a memory cell selected by the row decoder 1240 and the column decoder 1100 and provide the amplified data to the output buffer 1120. Data to be stored in data cells may be provided to the memory cell array 1010 through a data input register 1320, and an input/output controller 1340 may control a data transmission operation through the data input register 1320.

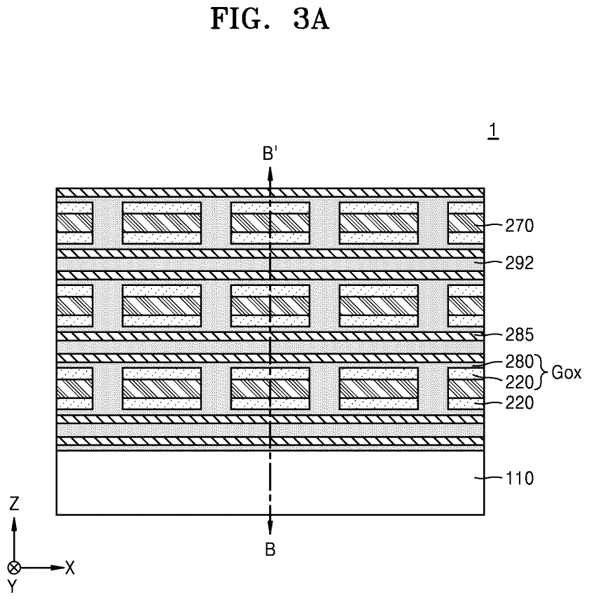

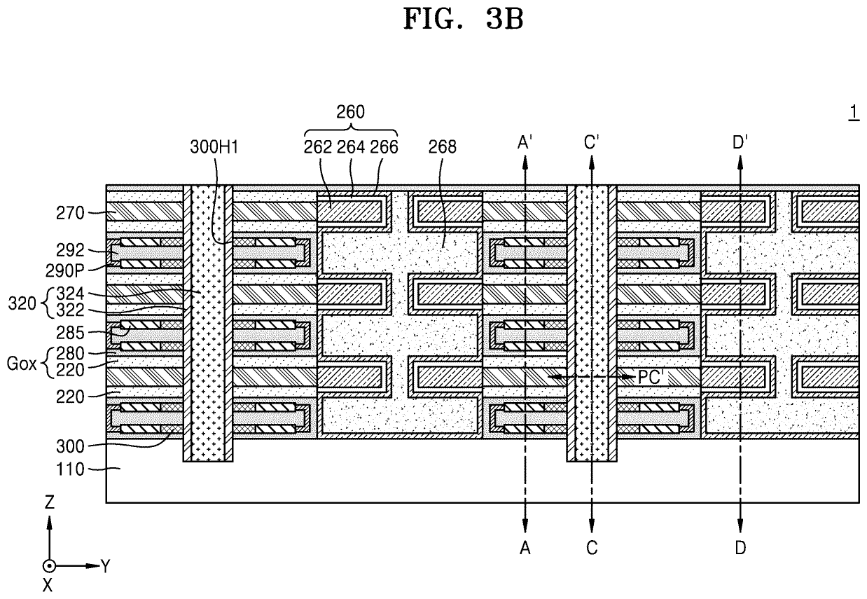

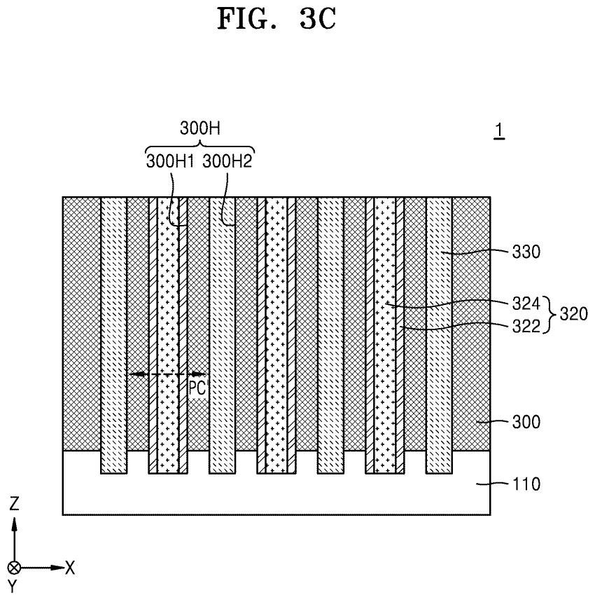

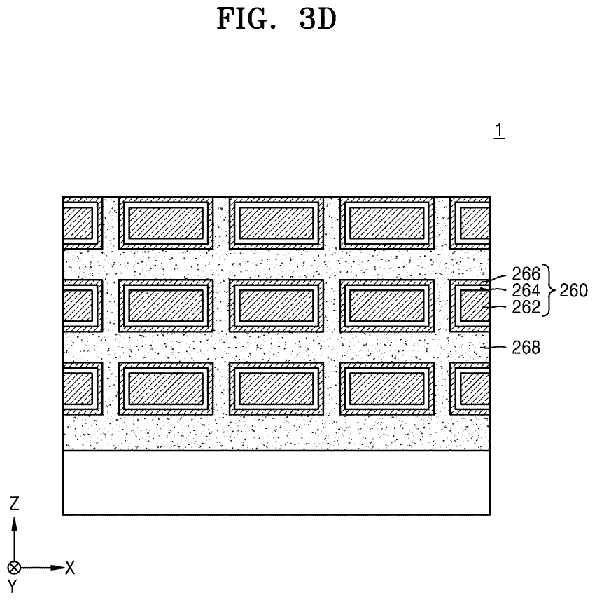

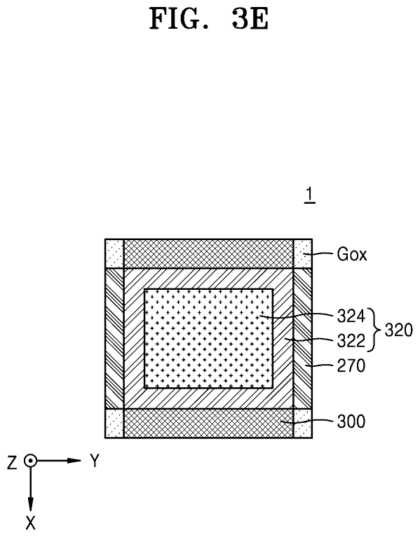

FIGS. 3A, 3B, 3C, 3D, and 3E are views illustrating a semiconductor memory device according to an implementation. Specifically, FIG. 3A is a cross-sectional view taken along line A-A′ of FIG. 3B, FIG. 3B is a cross-sectional view taken along line B-B′ of FIG. 3A, FIG. 3C is a cross-sectional view taken along line C-C′ of FIG. 3B, FIG. 3D is a cross-sectional view taken along line D-D′ of FIG. 3B, and FIG. 3E is a cross-sectional view taken along line PC′ of FIGS. 3B and 3C.

Referring to FIG. 3A, FIG. 3B, FIG. 3C, FIG. 3D, and FIG. 3E, a semiconductor memory device 1 includes a substrate 110, a plurality of channel patterns 270 on the substrate 110, a plurality of gate electrode layers 285 provided between a plurality of gate dielectric layers Gox and surrounding at least part of the plurality of channel patterns 270, a plurality of bit line structures 320 connected to the plurality of channel patterns 270, and a plurality of capacitor structures 260 connected to the plurality of channel patterns 270. A second horizontal direction (the Y direction) may be orthogonal to a first horizontal direction (the X direction). In the second horizontal direction (the Y direction), the plurality of bit line structures 320 may each be connected to one end of each of the plurality of channel patterns 270, and the plurality of capacitor structures 260 may each be connected to the other end of each of the plurality of channel patterns 270. The plurality of gate electrode layers 285 may be the plurality of word lines WL illustrated in FIG. 1. The plurality of bit line structures 320 may be the plurality of bit lines BL illustrated in FIG. 1. The plurality of capacitor structures 260 may each be the information storage SP illustrated in FIG. 1. The channel pattern 270, the gate dielectric layer Gox, the gate electrode layer 285, and the bit line structure 320 may constitute the cell transistor CT illustrated in FIG. 1.

The plurality of channel patterns 270 may be separated from each other in the first horizontal direction (the X direction), the second horizontal direction (the Y direction), and the vertical direction (the Z direction) on the substrate 110. The plurality of channel patterns 270 may be arranged in a row in the first horizontal direction (the X direction) and the second horizontal direction (the Y direction) in a plane like a matrix form, and may be aligned in the vertical direction (the Z direction). In some implementations, the plurality of channel patterns 270 may each be formed of an oxide semiconductor material. In some implementations, the plurality of channel patterns 270 may each have the same impurity concentration as a whole, or may each be an intrinsic semiconductor that is not injected with impurities as a whole. For example, the plurality of channel patterns 270 may each have a junctionless structure.

The plurality of gate dielectric layers Gox may respectively surround the plurality of channel patterns 270. The plurality of gate dielectric layers Gox may respectively cover upper and lower surfaces of the plurality of channel patterns 270 and both side surfaces in the first horizontal direction (the X direction) of the plurality of channel patterns 270. The plurality of gate dielectric layers Gox may each include a base insulating layer 220 and a channel cover insulating layer 280. The base insulating layer 220 may cover an upper surface and a lower surface of the channel pattern 270, and the channel cover insulating layer 280 may cover an upper surface, a lower surface, and both side surfaces, in the first horizontal direction (the X direction), of a channel structure including the channel pattern 270 and a pair of base insulating layers 220 covering the upper surface and the lower surface of the channel pattern 270. The base insulating layer 220 covering the lower surface of the channel pattern 270 may be referred to as a first base insulating layer, and the base insulating layer 220 covering the upper surface of the channel pattern 270 may be referred to as a second base insulating layer. The base insulating layer 220 may cover an upper surface or a lower surface of one of the plurality of channel patterns 270. In some implementations, the upper surface, the lower surface, and side surfaces in the first horizontal direction (the X direction) of each of the channel structures separated from each other in the first horizontal direction (the X direction) may be covered by one channel cover insulating layer 280.

The plurality of gate electrode layers 285 may extend in the first horizontal direction (the X direction) and may be separated from each other in the second horizontal direction (the Y direction) and the vertical direction (the Z direction). The plurality of gate electrode layers 285 may extend in the first horizontal direction (the X direction) along upper and lower surfaces of the channel cover insulating layer 280 covering the channel structures separated from each other in the first horizontal direction (the X direction). The gate electrode layer 285 extending along a lower surface of the channel cover insulating layer 280 may be referred to as a first gate electrode layer, and the gate electrode layer 285 extending along an upper surface of the channel cover insulating layer 280 may be referred to as a second gate electrode layer. A pair of gate electrode layers 285 separated from each other in the vertical direction (the Z direction) may be arranged between a pair of channel patterns 270 adjacent to each other in the vertical direction (the Z direction). The gate electrode layer 285 on an upper side among the pair of gate electrode layers 285 may be a first gate electrode layer corresponding to the channel pattern 270 on an upper side among the pair of channel patterns 270, and the gate electrode layer 285 on a lower side among the pair of gate electrode layers 285 may be a second gate electrode layer corresponding to the channel pattern 270 on a lower side among the pair of channel patterns 270. An interlayer insulating layer 292 may be between the pair of gate electrode layers 285, which are arranged between the pair of channel patterns 270 adjacent to each other in the vertical direction (the Z direction) and are separated from each other in the vertical direction (the Z direction). The interlayer insulating layer 292 may extend in the first horizontal direction (the X direction), which is an extension direction of the gate electrode layer 285. In some implementations, the first gate electrode layer and the second gate electrode layer corresponding to one channel pattern 270 may be formed integrally.

A horizontal width of each of the plurality of gate electrode layers 285 in the second horizontal direction (the Y direction) may be less than a horizontal width of each of the plurality of channel patterns 270 or a horizontal width of each of the plurality of base insulating layers 220. For example, the pair of gate electrode layers 285 may have the plurality of gate dielectric layers Gox therebetween and surround a part of an upper surface and a part of a lower surface of each of the plurality of channel patterns 270.

The plurality of bit line structures 320 may be separated from each other in the first horizontal direction (the X direction) and the second horizontal direction (the Y direction) and may extend in the vertical direction (the Z direction). Respective ends of the bit line structure 320 in the second horizontal direction (the Y direction) may be connected to channel patterns 270 aligned in the vertical direction (the Z direction) among the plurality of channel patterns 270.

The plurality of bit line structures 320 may each include a core conductive layer 324 and an oxide semiconductor layer 322. The oxide semiconductor layer 322 may be between the core conductive layer 324 and the channel pattern 270. The oxide semiconductor layer 322 may cover a side surface of the core conductive layer 324. In some implementations, the oxide semiconductor layer 322 may cover all of side surfaces of the core conductive layer 324. For example, the oxide semiconductor layer 322 may have a ring shape that extends continuously in a plane and surrounds the core conductive layer 324. Although FIG. 3E illustrates that a planar shape of the core conductive layer 324 is a square, the present disclosure is not limited thereto. For example, the planar shape of the core conductive layer 324 may be a square, a polygon having five or more angles, a circle, or an ellipse. To correspond to the planar shape of the core conductive layer 324, a planar shape of the oxide semiconductor layer 322 may be a square ring, a polygonal ring having five or more angles, a circular ring, or an elliptical ring.

Bit line shield structures 330 may be between the bit line structures 320 arranged in rows in the first horizontal direction (the X direction). The bit line structures 320 and the bit line shield structures 330 may be arranged alternately while being separated from each other in the first horizontal direction (the X direction). For example, a pair of bit line shield structures 330 may be arranged on two sides of each of the plurality of bit line structures 320 in the first horizontal direction (the X direction). The plurality of bit line shield structures 330 may be separated from each other in the first horizontal direction (the X direction) and the second horizontal direction (the Y direction) and may extend in the vertical direction (the Z direction). The plurality of bit line shield structures 330 may be separated from each other so as not to be connected to the plurality of channel patterns 270.

A plurality of spacer layers 300 may be between the plurality of bit line structures 320 and the plurality of bit line shield structures 330, and between the plurality of bit line structures 320 and the plurality of gate electrode layers 285. The spacer layer 300 provided between the bit line structure 320 and the bit line shield structure 330 may be referred to as a bit line spacer layer, and the spacer layer 300 between the bit line structure 320 and the gate electrode layer 285 may be referred to as a gate spacer layer. The bit line spacer layer and the gate spacer layer may be formed of the same material.

In the second horizontal direction (the Y direction), the gate spacer layer may be connected to one end of the gate electrode layer 285, and a gate isolation insulating pattern 290P may be connected to the other end of the gate electrode layer 285. In the second horizontal direction (the Y direction), one gate spacer layer may be connected to one end of one gate electrode layer 285. The interlayer insulating layer 292 may be between a pair of gate electrode layers 285, which are arranged between a pair of channel patterns 270 adjacent to each other in the vertical direction (the Z direction) and are separated from each other in the vertical direction (the Z direction), and a pair of gate spacer layers which are connected to the other ends of the pair of gate electrode layers 285.

The gate isolation insulating pattern 290P may be connected to the other ends of a pair of gate electrode layers 285, which are arranged between a pair of channel patterns 270 adjacent to each other in the vertical direction (the Z direction) and are separated from each other in the vertical direction (the Z direction). In some implementations, a plurality of gate isolation insulating patterns 290P may each have a U-shaped vertical cross-section in a vertical cross-section (a Y-Z vertical cross-section) formed by a second horizontal direction (the Y direction) and a vertical direction (the Z direction), and may each have a U-shaped vertical cross-section rotated by 90 degrees such that an open portion of the U-shaped vertical cross-section faces the gate electrode layer 285. For example, the plurality of gate isolation insulating patterns 290P may each have a pair of horizontal portions between the pair of channel cover insulating layers 280 and the interlayer insulating layer 292, and a vertical portion between a second electrode 266 and the interlayer insulating layer 292. The pair of horizontal portions of the gate isolation insulating pattern 290P may be connected to the other ends of a pair of gate electrode layers 285, which are arranged between a pair of channel patterns 270 adjacent to each other in the vertical direction (the Z direction) and are separated from each other in the vertical direction (the Z direction). One end of each of the pair of horizontal portions of the gate isolation insulating pattern 290P in the second horizontal direction (the Y direction) may be connected to the other end of each of the pair of gate electrode layers 285, and the other end of each of the pair of horizontal portions of the gate isolation insulating pattern 290P in the second horizontal direction (the Y direction) may be connected to each of two ends of the vertical portion of the gate isolation insulating pattern 290P in the vertical direction (the Z direction). A thickness of each of the pair of horizontal portions of the gate isolation insulating pattern 290P may be less than a thickness of the gate electrode layer 285. The gate isolation insulating patterns 290P may be formed of nitride.

The plurality of spacer layers 300 may have a plurality of vertical holes 300H. The plurality of vertical holes 300H may penetrate the plurality of spacer layers 300 in the vertical direction (the Z direction). In some implementations, the plurality of vertical holes 300H may penetrate the plurality of spacer layers 300 and extend into the substrate 110. The plurality of vertical holes 300H may include a plurality of first vertical holes 300H1 and a plurality of second vertical holes 300H2 that are alternately arranged in the first horizontal direction (the X direction). The plurality of channel patterns 270 may be exposed within the plurality of first vertical holes 300H1. The plurality of channel patterns 270 may not be exposed within the plurality of second vertical holes 300H2. The plurality of bit line structures 320 may fill the plurality of first vertical holes 300H1, and the plurality of bit line shield structures 330 may fill the plurality of second vertical holes 300H2. In some implementations, a horizontal width of the first vertical hole 300H1 in the first horizontal direction (the X direction) may be greater than a horizontal width of the second vertical hole 300H2. The horizontal width of the first vertical hole 300H1 and the horizontal width of the second vertical hole 300H2 in the second horizontal direction (the Y direction) may be substantially equal to each other. For example, a horizontal width of the bit line structure 320 in the first horizontal direction (the X direction) may be greater than a horizontal width of the bit line shield structure 330, and a horizontal width of the bit line structure 320 in the second horizontal direction (the Y direction) may be substantially equal to a horizontal width of the bit line shield structure 330 in the second horizontal direction. A plurality of oxide semiconductor layers 322 included in the plurality of bit line structures 320 may cover inner side surfaces of the plurality of first vertical holes 300H1, and a plurality of core conductive layers 324 included in the plurality of bit line structures 320 may cover the plurality of oxide semiconductor layers 322 and fill the plurality of first vertical holes 300H1.

In the second horizontal direction (the Y direction), a capacitor structure 260 may be connected to the other end opposite to one end facing the bit line structure 320 of the channel pattern 270. A plurality of capacitor structures 260 may be separated from each other in the first horizontal direction (the X direction) and the vertical direction (the Z direction). In some implementations, a pair of capacitor structures 260 adjacent to each other in the second horizontal direction (the Y direction) may have a mirror-symmetrical structure in the second horizontal direction (the Y direction). For example, the plurality of capacitor structures 260 may be separated from each other in the first horizontal direction (the X direction), the second horizontal direction (the Y direction), and the vertical direction (the Z direction), but a pair of capacitor structures 260 adjacent to each other in the second horizontal direction (the Y direction) may have a mirror-symmetrical structure in the second horizontal direction (the Y direction).

The capacitor structure 260 may include a first electrode 262, the second electrode 266, and a capacitor dielectric layer 264 between the first electrode 262 and the second electrode 266. The first electrode 262 may be connected to the other end of the channel pattern 270, the capacitor dielectric layer 264 may cover the first electrode 262, and the second electrode 266 may cover the capacitor dielectric layer 264. For example, one side surface of the first electrode 262 in the second horizontal direction (the Y direction) may be connected to the other end of the channel pattern 270. For example, the capacitor dielectric layer 264 may conformally cover the other side surface of the first electrode 262 in the second horizontal direction (the Y direction), upper and lower surfaces of the first electrode 262, and one side surface and the other side surface of the first electrode 262 in the first horizontal direction (the X direction). In some implementations, the second electrode 266 may be integrally formed with and cover the first electrode 262 and the capacitor dielectric layer 264 between the second electrode 266 and the first electrode 262. A capacitor spacer layer 268 may be provided between the plurality of capacitor structures 260. For example, the capacitor spacer layer 268 may cover the second electrode 266. In some implementations, the capacitor spacer layer 268 may fill a space defined by a plurality of second electrodes 266. For example, the capacitor spacer layer 268 may fill spaces between the plurality of capacitor structures 260 that are separated from each other in the first horizontal direction (the X direction), the second horizontal direction (the Y direction), and the vertical direction (the Z direction).

The channel pattern 270 included in the semiconductor memory device 1 according to the present disclosure may be formed of an oxide semiconductor material having a junctionless structure. Therefore, in the semiconductor memory device 1 according to the present disclosure, a leakage current may be reduced, the channel pattern 270 may be formed to be relatively small, and thus, integration density may be increased.

The gate dielectric layer Gox included in the semiconductor memory device 1 according to the present disclosure has a structure in which the base insulating layer 220 and the channel cover insulating layer 280 are stacked, and accordingly, the base insulating layer 220 in contact with the channel pattern 270 may not be in direct contact with a configuration including a nitride, for example, the gate isolation insulating pattern 290P. Therefore, hydrogen may be prevented from penetrating the channel pattern 270 from the configuration including a nitride to prevent the channel pattern 270 from deteriorating, and thus, operational reliability of the semiconductor memory device 1 may be improved.

Also, because the bit line structure 320 included in the semiconductor memory device 1 according to the present disclosure includes the oxide semiconductor layer 322 in contact with the channel pattern 270, a contact area between the bit line structure 320 and the channel pattern 270 may be increased to reduce contact resistance between the channel pattern 270 and the bit line structure 320, and thus, operation characteristics of the semiconductor memory device 1 may be improved.

In the semiconductor memory device 1 according to the present disclosure, a main component, such as the base insulating layer 220, may be formed by a deposition process rather than an epitaxial growth process, and thus, a process of manufacturing the semiconductor memory device 1 may be easily performed.

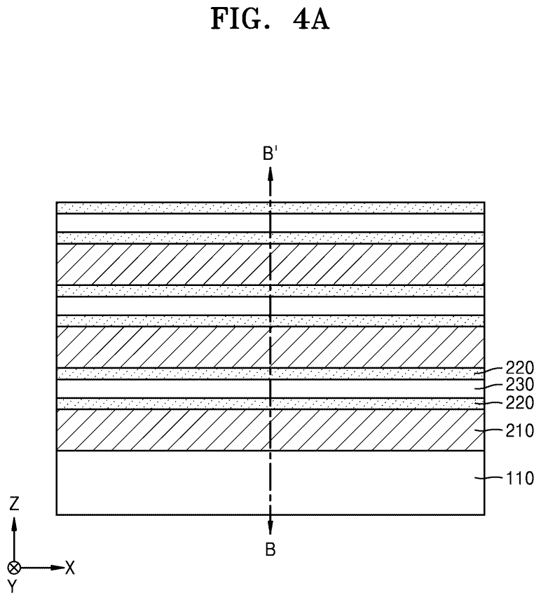

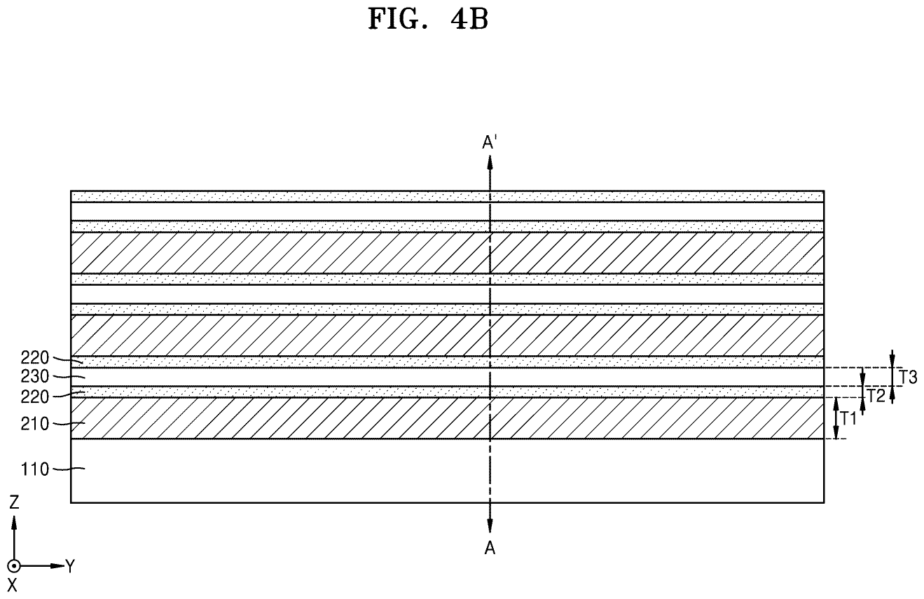

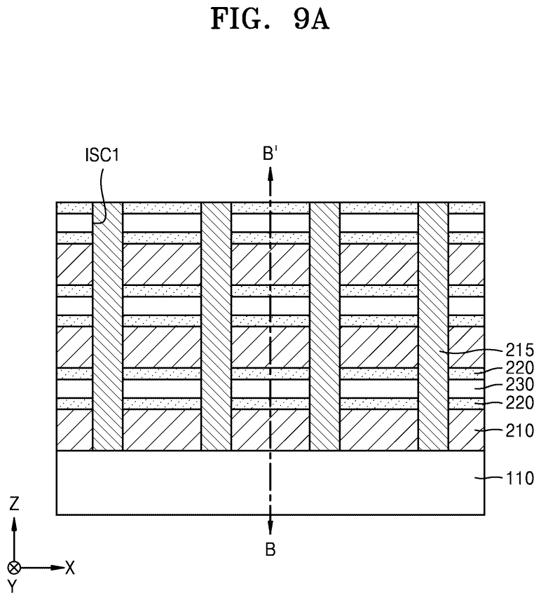

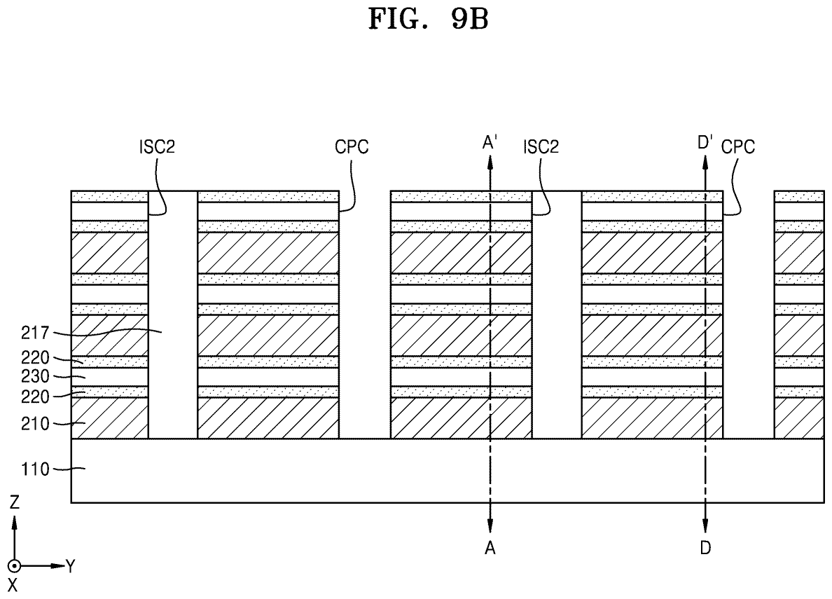

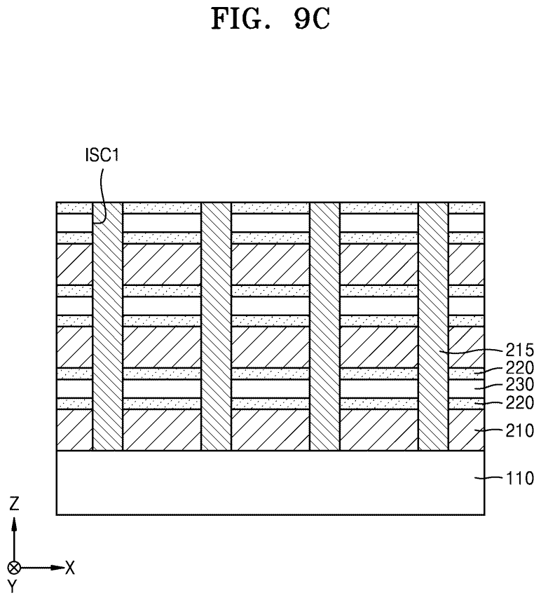

FIGS. 4A, 4B, 5A, 5B, 6A, 6B, 7A, 7B, 8A, 8B, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 21A, 21B, 22A, 22B, 23A, 23B, 24A, 24B, 25A, 25B, 26A, 26B,. 27A, 27B, 28A, 28B, 29A, 29B, 30A, 30B, 31A, 31B, 32A, 32B, 33A, 33B, 34A, 34B, 34C, 35A, 35B, 35C, 36A, 36B, 36C, 37A, 37B, 37C, 38A, 38B, and 38C are views illustrating a method of manufacturing a semiconductor memory device, according to an implementation. Specifically, FIGS. 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, 33A, 34A, 35A, 36A, 37A, and 38A are cross-sectional views respectively taken along lines A-A′ of FIGS. 4B, 5B, 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, 30B, 31B, 32B, 33B, 34B, 35B, 36B, 37B, and 38B. FIGS. 4B, 5B, 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, 30B, 31B, 32B, 33B, 34B, 35B, 36B, 37B, and 38B are cross-sectional views respectively taken along lines B-B′ of FIGS. 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, 33A, 34A, 35A, 36A, 37A, and 38A. FIGS. 34C, 35C, 36C, 37C, and 38C are cross-sectional views respectively taken along lines C-C′ of FIGS. 34B, 35B, 36B, 37B, and 38B. FIGS. 9C, 10C, 11C, 12C, 13C, 14C, 15C, 16C, 17C, 18C, and 19C are cross-sectional views respectively taken along lines D-D′ of FIGS. 9B, 10B, 11B, 12B, 13B, 14B, 15B, 16B, 17B, 18B, and 19B.

Referring to FIG. 4A and FIG. 4B, a plurality of sacrificial insulating layers 210, a plurality of base insulating layers 220, and a plurality of sacrificial semiconductor layers 230 are formed on a substrate 110. The plurality of sacrificial insulating layers 210, the plurality of base insulating layers 220, and the plurality of sacrificial semiconductor layers 230 may be formed by a deposition process, such as chemical vapor deposition (CVD), plasma enhanced CVD (PECVD), or atomic layer deposition (ALD).

In some implementations, the base insulating layer 220 may be between the sacrificial insulating layer 210 and the sacrificial semiconductor layer 230. For example, the base insulating layer 220 may be on and beneath the sacrificial insulating layer 210, and the base insulating layer 220 may be on and beneath the sacrificial semiconductor layer 230. For example, the plurality of sacrificial insulating layers 210 and the plurality of sacrificial semiconductor layers 230 may be alternately arranged between a pair of base insulating layers 220 adjacent to each other in a vertical direction (the Z direction) among the plurality of base insulating layers 220.

Although FIGS. 4A and 4B illustrate that the base insulating layer 220 is on the uppermost portion of a stack structure in which the plurality of sacrificial insulating layers 210, the plurality of base insulating layers 220, and the plurality of sacrificial semiconductor layers 230 are stacked, the present disclosure is not limited thereto. For example, a plurality of sub-stack structures may be stacked on the substrate 110 in which the sacrificial insulating layer 210, one base insulating layer 220, one sacrificial semiconductor layer 230, and another base insulating layer 220 are sequentially stacked in the vertical direction (the Z direction). The base insulating layer 220 beneath the sacrificial semiconductor layer 230 may be referred to as a first base insulating layer, and the base insulating layer 220 on the sacrificial semiconductor layer 230 may be referred to as a second base insulating layer. In some implementations, the sacrificial insulating layer 210 may be on the uppermost portion of the stack structure in which the plurality of sacrificial insulating layers 210, the plurality of base insulating layers 220, and the plurality of sacrificial semiconductor layers 230 are stacked. For example, a plurality of sub-stack structures, each including the sacrificial insulating layer 210, one base insulating layer 220, the sacrificial semiconductor layer 230, and another base insulating layer 220, and the sacrificial insulating layer 210 on the plurality of sub-stack structures may be provided on the substrate 110.

The substrate 110 may include, for example, silicon (Si), such as crystalline Si, polycrystalline Si, or amorphous Si. Alternatively, the substrate 110 may include at least one compound semiconductor selected from among a semiconductor element such as germanium (Ge, germanium), silicon germanium (SiGe), silicon carbide (SiC), gallium arsenide (GaAs), indium arsenide (InAs), and indium phosphide (InP). Alternatively, the substrate 110 may include a silicon-on-insulator (SOI) substrate, or a germanium-on-insulator (GeOI) substrate. For example, the substrate 110 may include a buried oxide layer (BOX). The substrate 110 may include a conductive region, for example, a well doped with an impurity, or a structure doped with an impurity.

The sacrificial insulating layer 210, the base insulating layer 220, and the sacrificial semiconductor layer 230 may be formed of materials having etching selectivity with respect to each other. In some implementations, the sacrificial insulating layer 210 may include a nitride, and the base insulating layer 220 may include an oxide. For example, the sacrificial insulating layer 210 may include a silicon nitride. The base insulating layer 220 may be formed of at least one selected from among a silicon oxide, a high-k dielectric material with a higher dielectric constant than the silicon oxide, and a ferroelectric material. For example, the high-k dielectric material and the ferroelectric material may each be formed of at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). For example, the base insulating layer 220 may be formed of a metal oxide. In some implementations, the sacrificial semiconductor layer 230 may be formed of silicon (Si). For example, the sacrificial semiconductor layer 230 may be formed of polysilicon.

The sacrificial insulating layer 210 may have a first thickness T1, the base insulating layer 220 may have a second thickness T2, and the sacrificial semiconductor layer 230 may have a third thickness T3. The first thickness T1 may be greater than the second thickness T2 and the third thickness T3. The second thickness T2 may be less than or equal to the third thickness T3. For example, the first thickness T1 may be several tens of nm, and each of the second thickness T2 and the third thickness T3 may be several nm.

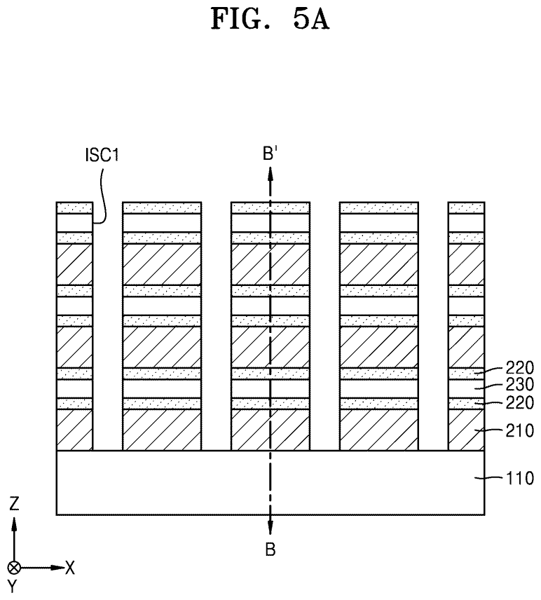

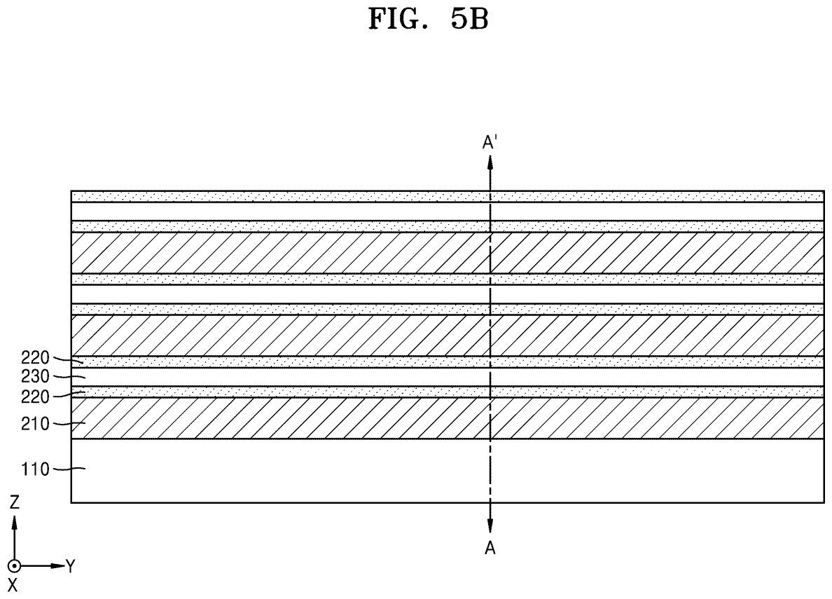

Referring to FIGS. 5A and 5B, the plurality of sacrificial insulating layers 210, the plurality of base insulating layers 220, and the plurality of sacrificial semiconductor layers 230 may be partially removed to form a plurality of first element isolation cut regions ISC1. The plurality of first element isolation cut regions ISC1 may be separated from each other in a first horizontal direction (the X direction) and extend in a second horizontal direction (the Y direction). The second horizontal direction (the Y direction) may be orthogonal to the first horizontal direction (the X direction). In some implementations, the plurality of first element isolation cut regions ISC1 may each have a substantially constant width in the first horizontal direction (the X direction) and may extend in the second horizontal direction (the Y direction). In some implementations, the substrate 110 may be exposed on bottom surfaces of the plurality of first element isolation cut regions ISC1.

The plurality of sacrificial insulating layers 210, the plurality of base insulating layers 220, and the plurality of sacrificial semiconductor layers 230 may each be divided into multiple pieces in the first horizontal direction (the X direction) by the plurality of first element isolation cut regions ISC1.

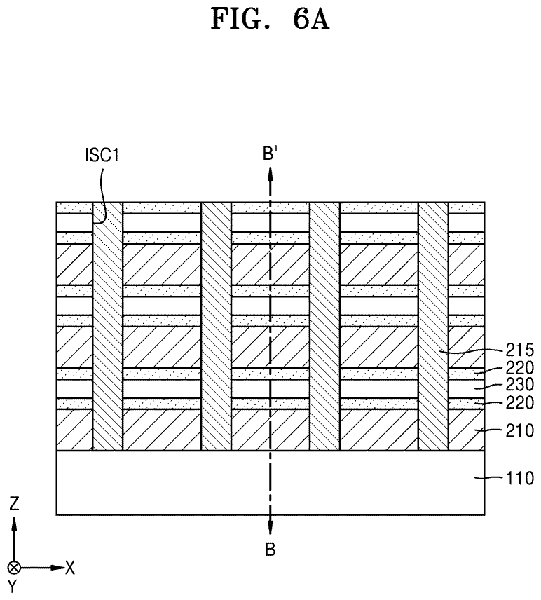

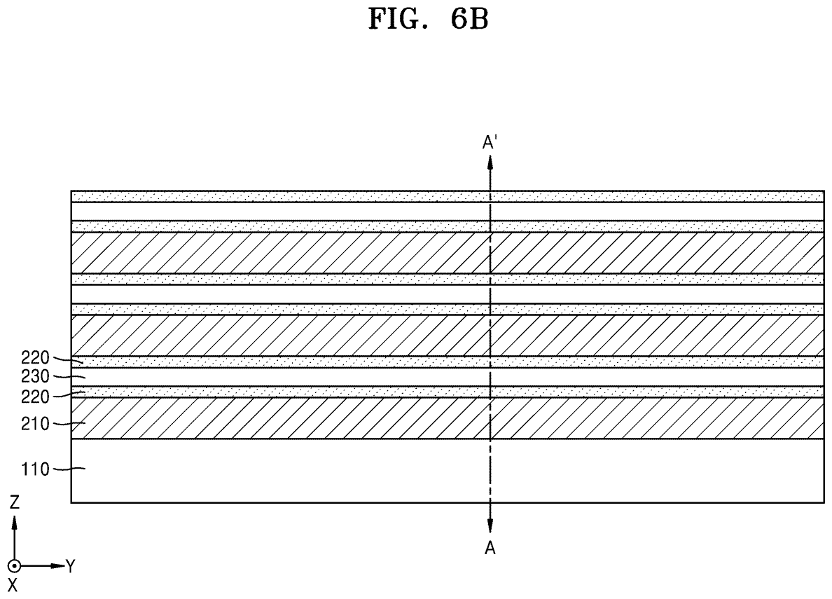

Referring to FIGS. 6A and 6B, a plurality of first filling insulating sacrificial layers 215 are formed to fill the plurality of first element isolation cut regions ISC1. The plurality of first filling insulating sacrificial layers 215 may each include a nitride. In some implementations, the plurality of first filling insulating sacrificial layers 215 may be formed of the same material as or materials with similar etching characteristics to the plurality of sacrificial insulating layers 210. For example, the plurality of first filling insulating sacrificial layers 215 may each include a silicon nitride.

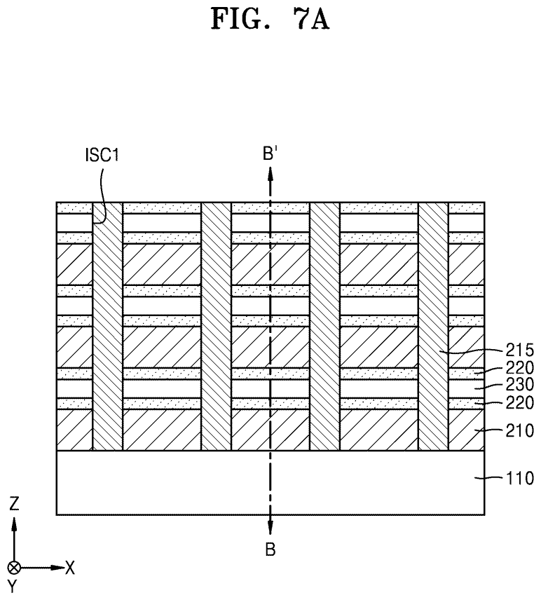

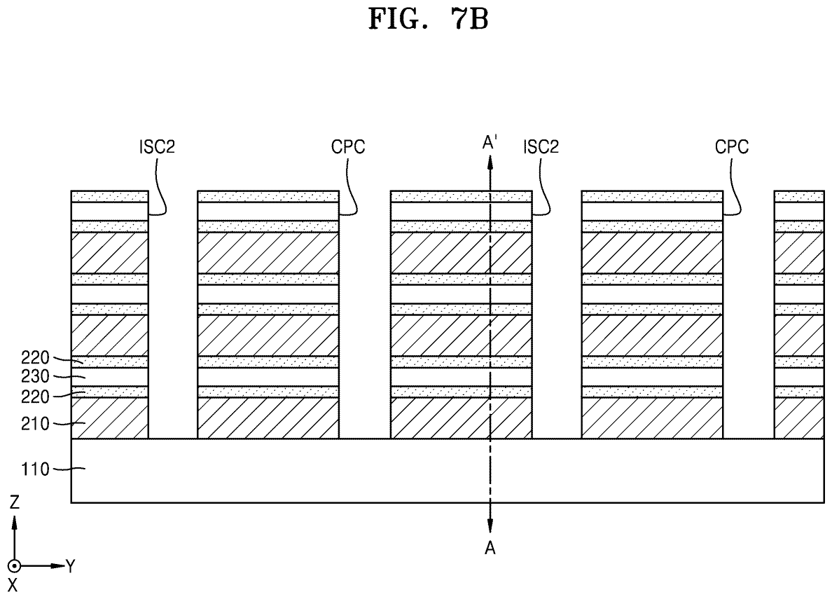

Referring to FIGS. 7A and 7B, the plurality of sacrificial insulating layers 210, the plurality of base insulating layers 220, the plurality of sacrificial semiconductor layers 230, and the plurality of first filling insulating sacrificial layers 215 may be partially removed to form a plurality of second element isolation cut regions ISC2 and a plurality of capacitor isolation cut regions CPC. The plurality of second element isolation cut regions ISC2 and the plurality of capacitor isolation cut regions CPC may be alternately arranged in the second horizontal direction (the Y direction). For example, each of the plurality of capacitor isolation cut regions CPC may be arranged between a pair of second element isolation cut regions ISC2 adjacent to each other in the second horizontal direction (the Y direction) among the plurality of second element isolation cut regions ISC2, and each of the plurality of second element isolation cut regions ISC2 may be arranged between a pair of capacitor isolation cut regions CPC adjacent to each other in the second horizontal direction (the Y direction) among the plurality of capacitor isolation cut regions CPC.

The plurality of second element isolation cut regions ISC2 and the plurality of capacitor isolation cut regions CPC may be separated from each other in the second horizontal direction (the Y direction) and may each extend in the first horizontal direction (the X direction). The plurality of second element isolation cut regions ISC2 and the plurality of capacitor isolation cut regions CPC may be formed to intersect the plurality of first element isolation cut regions ISC1.

In some implementations, horizontal widths of the plurality of second element isolation cut regions ISC2 and horizontal widths of the plurality of capacitor isolation cut regions CPC in the second horizontal direction (the Y direction) may be greater than horizontal widths of the plurality of first element isolation cut regions ISC1 in the first horizontal direction (the X direction). In some implementations, the plurality of second element isolation cut regions ISC2 and the plurality of capacitor isolation cut regions CPC may have substantially constant widths in the second horizontal direction (the Y direction) and may extend in the first horizontal direction (the X direction). In some implementations, the substrate 110 may be exposed on bottom surfaces of the plurality of second element isolation cut regions ISC2 and the plurality of capacitor isolation cut regions CPC.

The plurality of sacrificial insulating layers 210, the plurality of base insulating layers 220, and the plurality of sacrificial semiconductor layers 230 may each be divided into multiple pieces in the second horizontal direction (the Y direction) by the plurality of second element isolation cut regions ISC2 and the plurality of capacitor isolation cut regions CPC. That is, the plurality of sacrificial insulating layers 210, the plurality of base insulating layers 220, and the plurality of sacrificial semiconductor layers 230 may each be divided into multiple pieces in the first horizontal direction (the X direction) and the second horizontal direction (the Y direction) by the plurality of first element isolation cut regions ISC1, the plurality of second element isolation cut regions ISC2, and the plurality of capacitor isolation cut regions CPC. For example, the plurality of sacrificial insulating layers 210, the plurality of base insulating layers 220, and the plurality of sacrificial semiconductor layers 230 isolated by the plurality of first element isolation cut regions ISC1, the plurality of second element isolation cut regions ISC2, and the plurality of capacitor isolation cut regions CPC may each be arranged in a single row in the first horizontal direction (the X direction) and the second horizontal direction (the Y direction) like a matrix form.

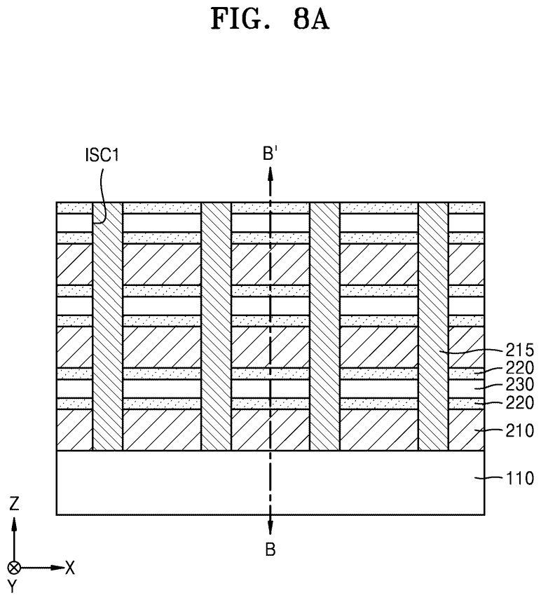

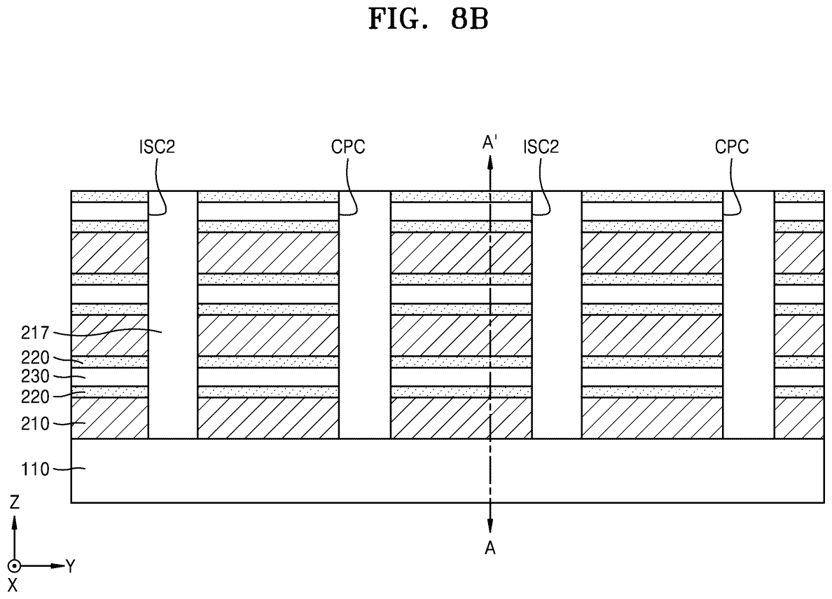

Referring to FIGS. 8A and 8B, a plurality of second filling insulating sacrificial layers 217 may be formed to fill the plurality of second element isolation cut regions ISC2 and the plurality of capacitor isolation cut regions CPC. The plurality of second filling insulating sacrificial layers 217 may each be formed of a material having etching selectivity with respect to each of the plurality of first filling insulating sacrificial layers 215. The plurality of second filling insulating sacrificial layers 217 may each be formed of a material having etching selectivity with respect to each of the plurality of base insulating layers 220. In some implementations, the plurality of second filling insulating sacrificial layers 217 may each include an oxide. For example, the plurality of second filling insulating sacrificial layers 217 may each include a silicon oxide.

Referring to FIGS. 9A, 9B, and 9C, the second filling insulating sacrificial layers 217 that fill the plurality of capacitor isolation cut regions (CPCs) among the plurality of second filling insulating sacrificial layers 217 may be removed. The second filling insulating sacrificial layers 217 that fill the plurality of second element isolation cut regions ISC2 among the plurality of second filling insulating sacrificial layers 217 may remain without being removed.

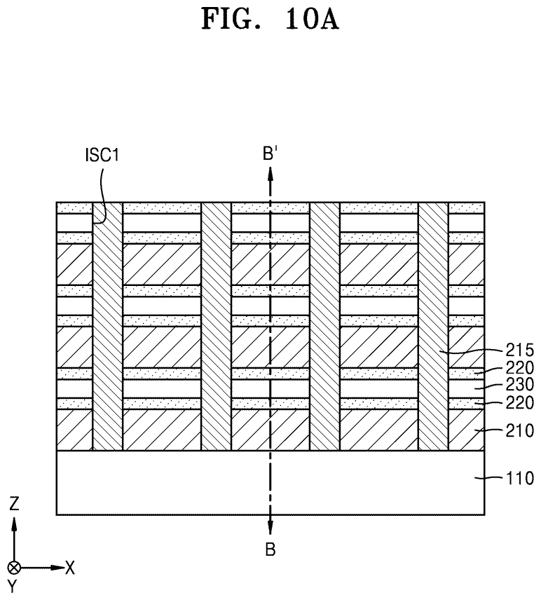

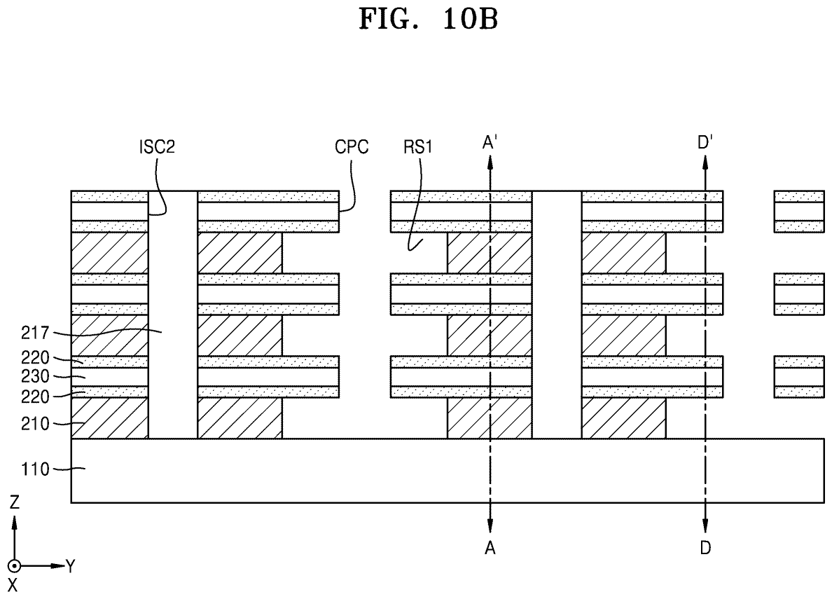

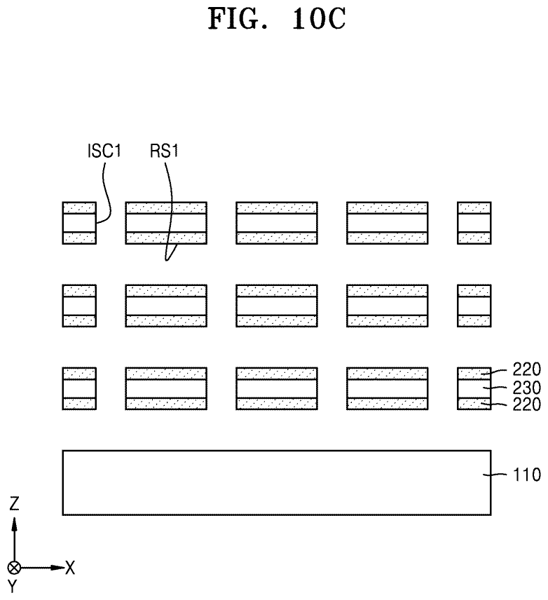

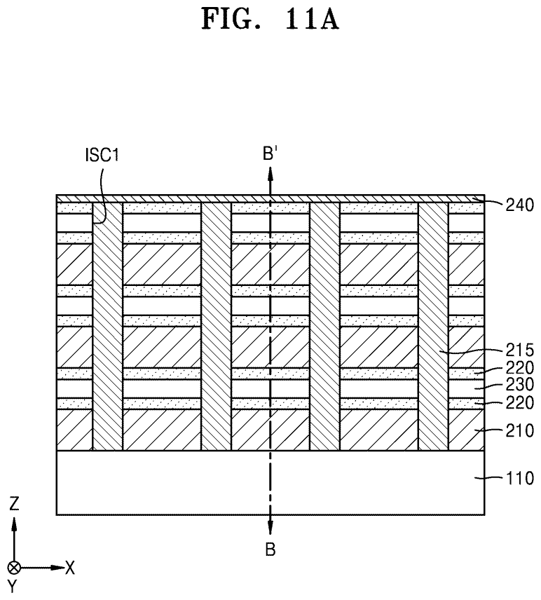

Referring to FIGS. 10A, 10B, and 10C, the plurality of sacrificial insulating layers 210 and the plurality of first filling insulating sacrificial layers 215 may be partially removed through the plurality of capacitor isolation cut regions CPC to form a plurality of first removal spaces RS1. The plurality of first removal spaces RS1 may be formed by partially removing the plurality of sacrificial insulating layers 210 such that the plurality of second filling insulating sacrificial layers 217 are not exposed. Among the plurality of first filling insulating sacrificial layers 215, portions adjacent to the plurality of capacitor isolation cut regions CPC may be removed, while portions adjacent to the plurality of second element isolation cut regions ISC2 may remain without being removed.

Among the plurality of first removal spaces RS1, portions from which the plurality of first filling insulating sacrificial layers 215 are partially removed may be parts of the plurality of first element isolation cut regions ISC1.

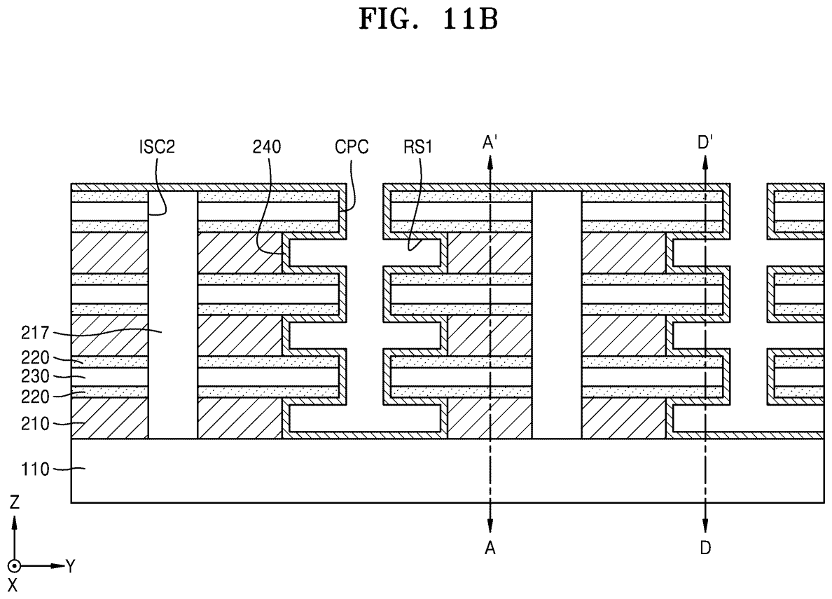

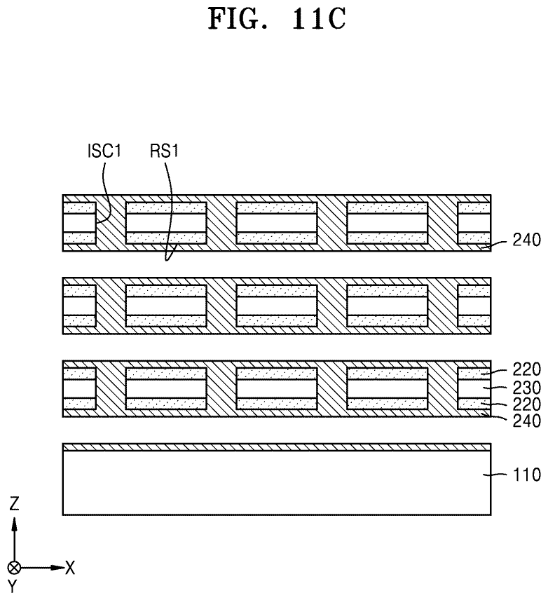

Referring to FIGS. 11A, 11B, and 11C, a first cover insulating layer 240 may be formed to cover surfaces exposed in the results of FIGS. 10A, 10B, and 10C. For example, the first cover insulating layer 240 may conformally cover an upper surface of a stack structure in which the plurality of sacrificial insulating layers 210, the plurality of base insulating layers 220, and the plurality of sacrificial semiconductor layers 230 are stacked, the substrate 110 exposed within the plurality of capacitor isolation cut regions CPC and the plurality of first removal spaces RS1, and surfaces of the plurality of sacrificial insulating layers 210, the plurality of base insulating layers 220, the plurality of sacrificial semiconductor layers 230, and the plurality of first filling insulating sacrificial layers 215. In some implementations, the first cover insulating layer 240 may fill all of spaces between the sacrificial insulating layers 210, spaces between the base insulating layers 220, and spaces between the sacrificial semiconductor layers 230 which are adjacent to each other in the first horizontal direction (X direction) among the plurality of first removal spaces RS1, and may not fill all of spaces between the sacrificial insulating layers 210, spaces between base insulating layers 220, and spaces between sacrificial semiconductor layers 230 which are adjacent to each other in the first horizontal direction (the X direction) among the plurality of capacitor isolation cut regions CPC. The first cover insulating layer 240 may include a nitride. For example, the first cover insulating layer 240 may include a silicon nitride.

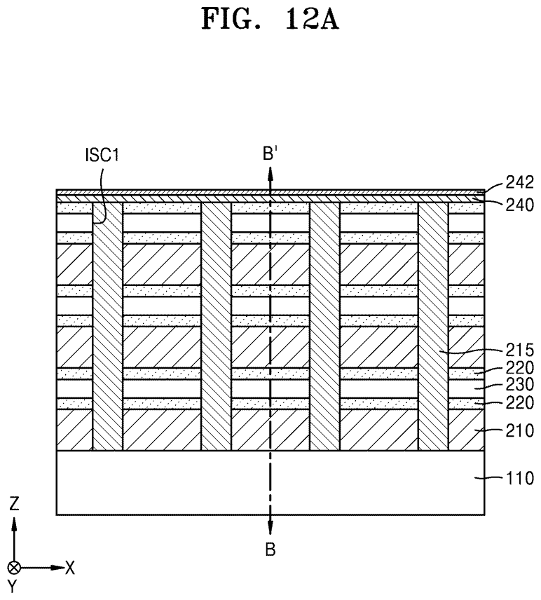

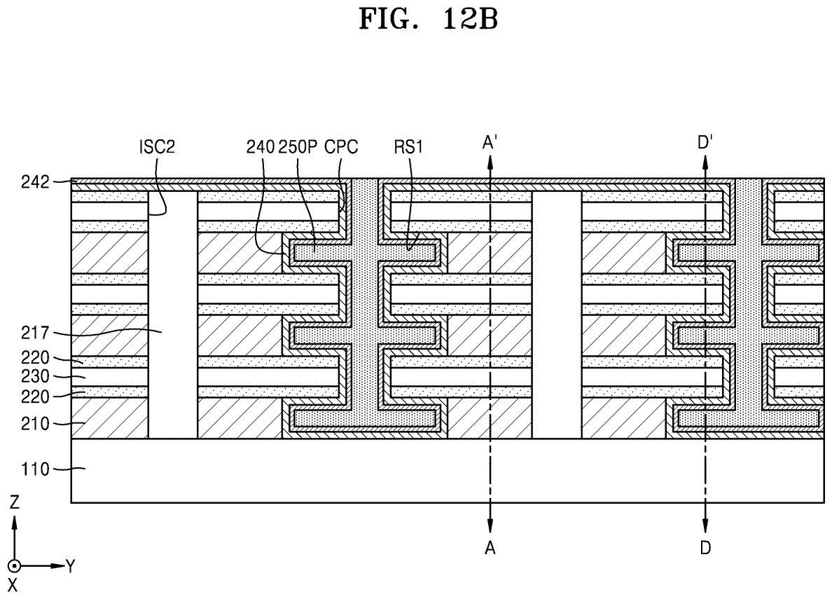

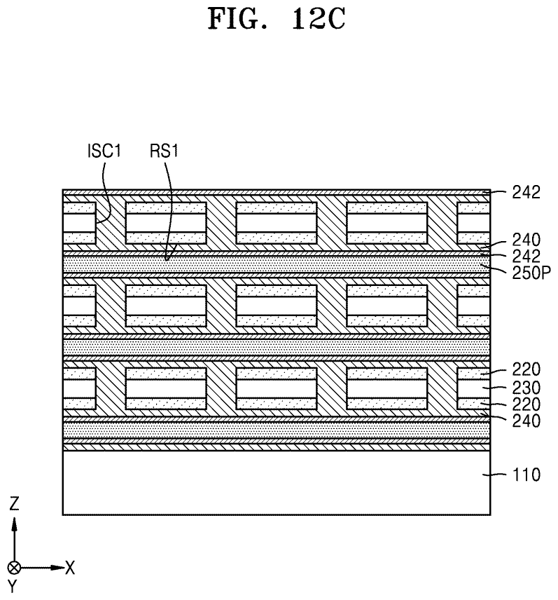

Referring to FIGS. 12A, 12B, and 12C, a second cover insulating layer 242 covering a surface of the first cover insulating layer 240 may be formed, and a plurality of pre-filling insulating layers 250P that fill the plurality of capacitor isolation cut regions CPC and the plurality of first removal spaces RS1 may be formed. The second cover insulating layer 242 may conformally cover the surface of the first cover insulating layer 240. The second cover insulating layer 242 may not fill all of the plurality of capacitor isolation cut regions CPC. In some implementations, a thickness of the second cover insulating layer 242 may be less than a thickness of the first cover insulating layer 240. The plurality of pre-filling insulating layers 250P may cover the second cover insulating layer 242 and fill all of the plurality of capacitor isolation cut regions CPC. The second cover insulating layer 242 may include a nitride. For example, the second cover insulating layer 242 may include a silicon nitride. The plurality of pre-filling insulating layers 250P may each include an oxide. For example, the plurality of pre-filling insulating layers 250P may each include a silicon oxide.

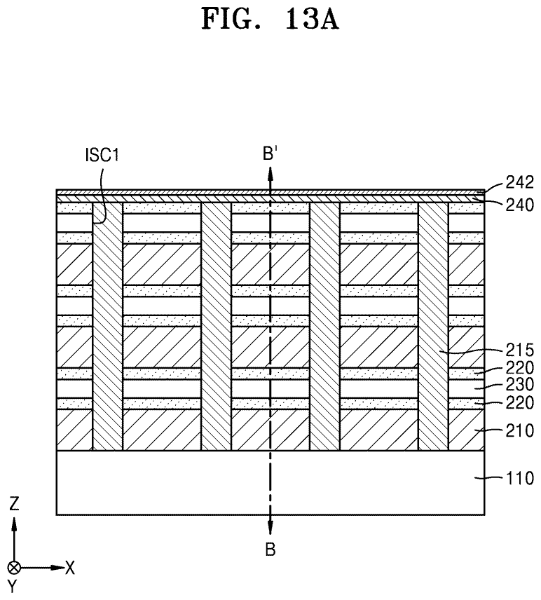

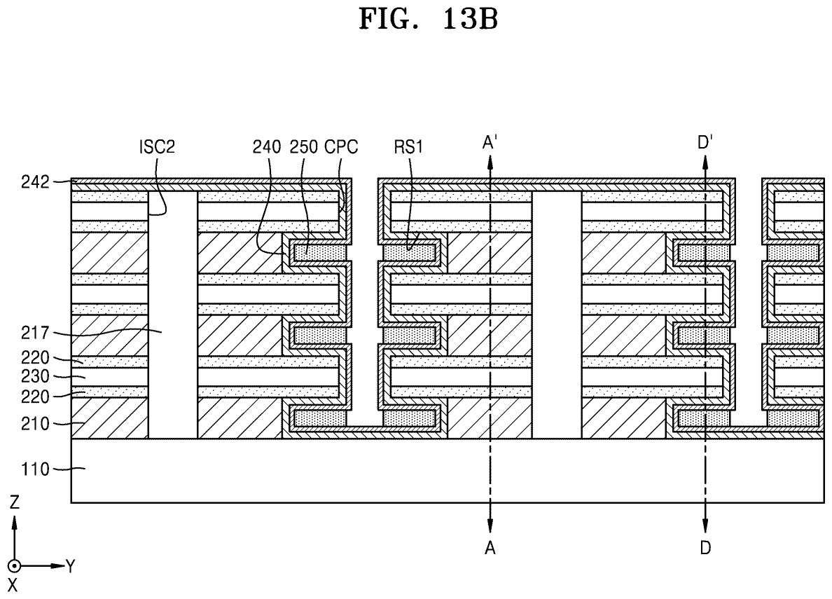

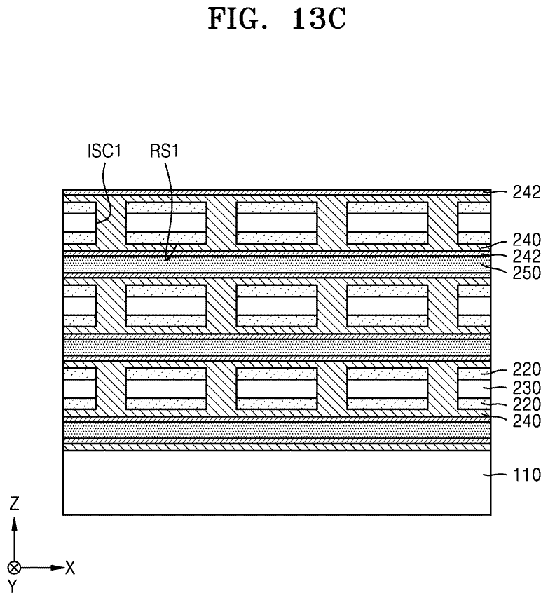

Referring to FIGS. 12A, 12B, and 12C, and FIGS. 13A, 13B, and 13C, the plurality of pre-filling insulating layers 250P may be partially removed to form a plurality of filling insulating layers 250. For example, the plurality of filling insulating layers 250 may be formed by partially removing the plurality of pre-filling insulating layers 250P through the plurality of capacitor isolation cut regions CPC. The plurality of filling insulating layers 250 may completely fill the plurality of first removal spaces RS1 but may not fill at least parts of the plurality of capacitor isolation cut regions CPC. The plurality of filling insulating layers 250 may each have a substantially constant horizontal width in the second horizontal direction (the Y direction) and have a bar shape extending in the first horizontal direction (the X direction).

The plurality of filling insulating layers 250 may be formed by partially removing the plurality of preliminary filling insulating layers 250P such that side surfaces of the plurality of filling insulating layers 250 exposed within the plurality of capacitor isolation cut regions CPC are shifted toward the plurality of first removal spaces RS1 more than side surfaces of the second cover insulating layer 242. For example, in the plurality of capacitor isolation cut regions CPC, a horizontal width of a space defined by the filling insulating layers 250 facing each other in the second horizontal direction (the Y direction) may be greater than a horizontal width of a space defined by the second cover insulating layers 242 facing each other in the second horizontal direction (the Y direction).

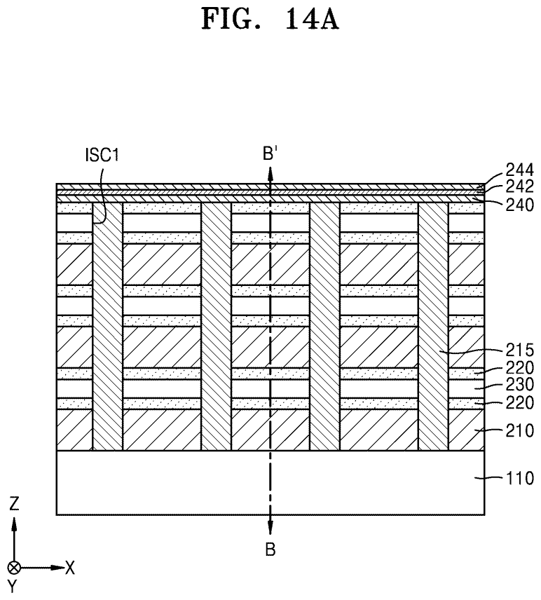

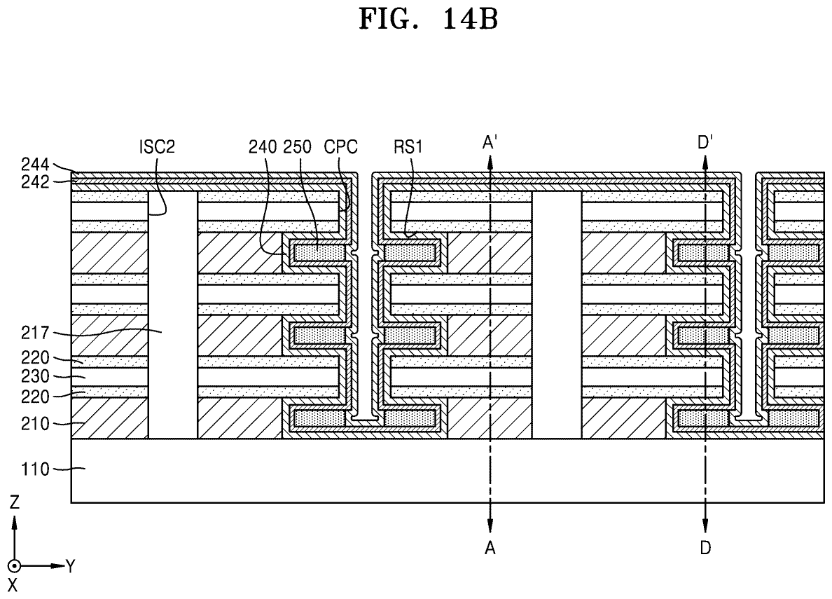

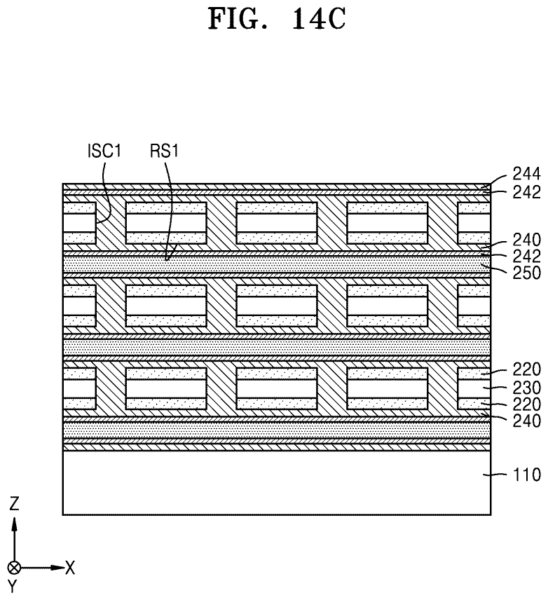

Referring to FIGS. 14A, 14B, and 14C, a third cover insulating layer 244 may be formed to cover surfaces exposed in the results of FIGS. 13A, 13B, and 13C. For example, the third cover insulating layer 244 may conformally cover a surface of the second cover insulating layer 242 and surfaces of the plurality of filling insulating layers 250. The third cover insulating layer 244 may not completely fill the plurality of capacitor isolation cut regions CPC. In some implementations, a thickness of the third cover insulating layer 244 may be greater than a thickness of the second cover insulating layer 242. The third cover insulating layer 244 may include a nitride. For example, the third cover insulating layer 244 may include a silicon nitride. The first cover insulating layer 240, the second cover insulating layer 242, and the third cover insulating layer 244 may have substantially the same etching characteristics but are not limited thereto. In some implementations, at least one of the first cover insulating layer 240, the second cover insulating layer 242, and the third cover insulating layer 244 may have etching selectivity with respect to at least one of other cover insulating layers.

In the plurality of capacitor isolation cut regions CPC, a horizontal width of a space defined by portions of the third cover insulating layer 244 which face each other and cover the plurality of filling insulating layers 250 in the second horizontal direction (the Y direction) may be greater than a horizontal width of a space defined by portions of the third cover insulating layer 244 which face each other and cover the second cover insulating layer 242 in the second horizontal direction (the Y direction).

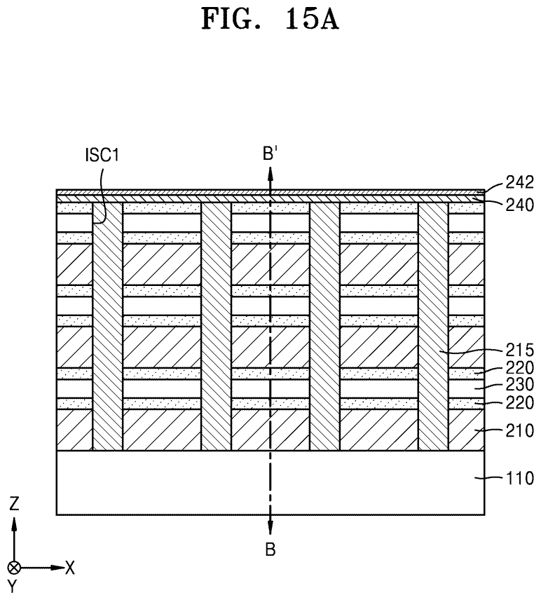

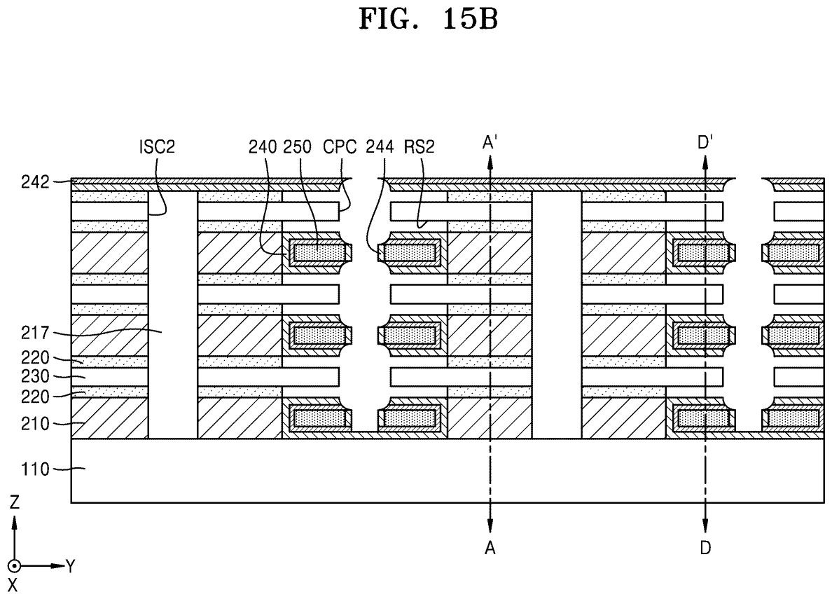

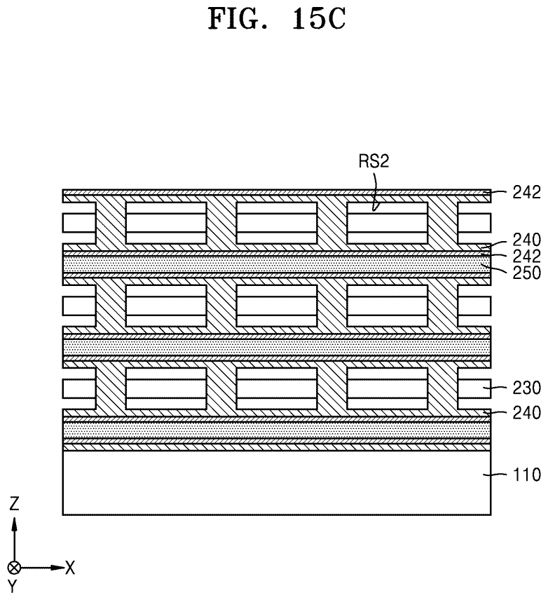

Referring to FIGS. 15A, 15B, and 15C, the third cover insulating layer 244 may be partially removed. In some implementations, the third cover insulating layer 244 may be removed by performing an anisotropic etching process. For example, portions of the third cover insulating layer 244, which cover the plurality of filling insulating layers 250, may remain without being removed. Thereafter, in the plurality of capacitor isolation cut regions CPC, a part of the second cover insulating layer 242 and a part of the first cover insulating layer 240 may be removed to expose the plurality of base insulating layers 220 and the plurality of sacrificial semiconductor layers 230, and then the plurality of base insulating layers 220 may be partially removed to form the plurality of second removal spaces RS2. The plurality of base insulating layers 220, the plurality of sacrificial semiconductor layers 230, and the first cover insulating layer 240 may be partially exposed within the plurality of second removal spaces RS2.

In a process of forming the plurality of second removal spaces RS2, portions of the third cover insulating layers 244 which cover the plurality of filling insulating layers 250 and the plurality of sacrificial semiconductor layers 230 may remain without being removed. The plurality of filling insulation layers 250 may be surrounded by the remaining portions of the first cover insulation layer 240, the remaining portions of the second cover insulation layer 242, and the remaining portions of the third cover insulation layer 244.

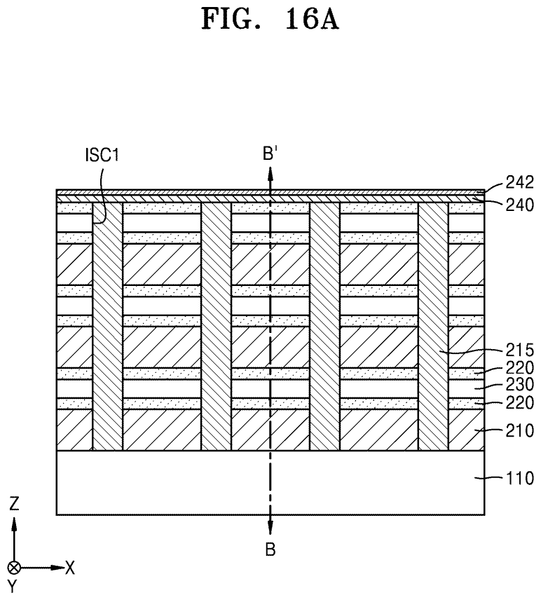

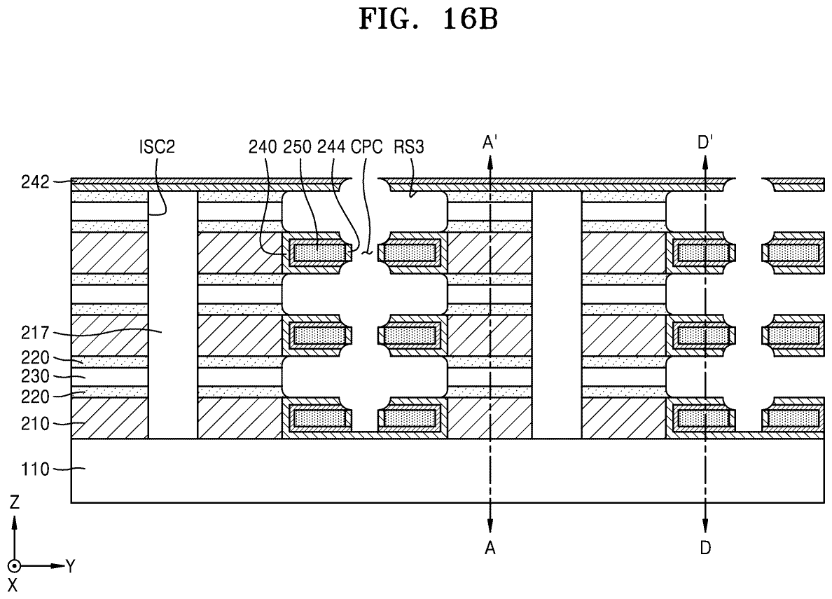

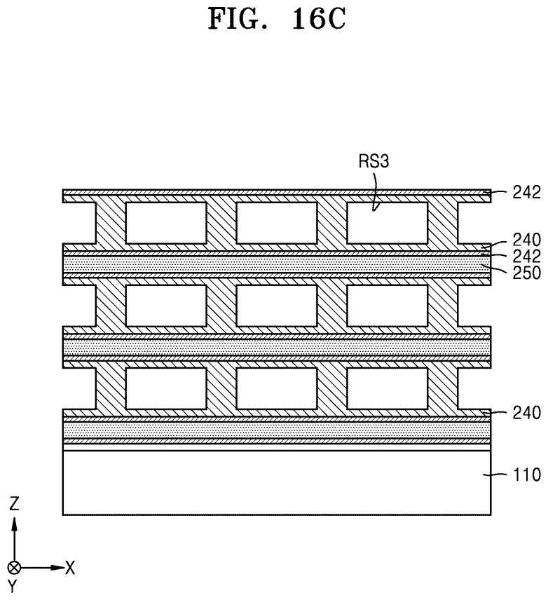

Referring to FIGS. 15A, 15B, and 15C, and FIGS. 16A, 16B, and 16C, the plurality of sacrificial semiconductor layers 230 may be partially removed. The plurality of second removal spaces RS2 and spaces from which the plurality of sacrificial semiconductor layers 230 are removed may constitute a plurality of third removal spaces RS3.

Within the plurality of third removal spaces RS3, the plurality of base insulation layers 220, the plurality of sacrificial semiconductor layers 230, and the first cover insulation layer 240 may be partially exposed.

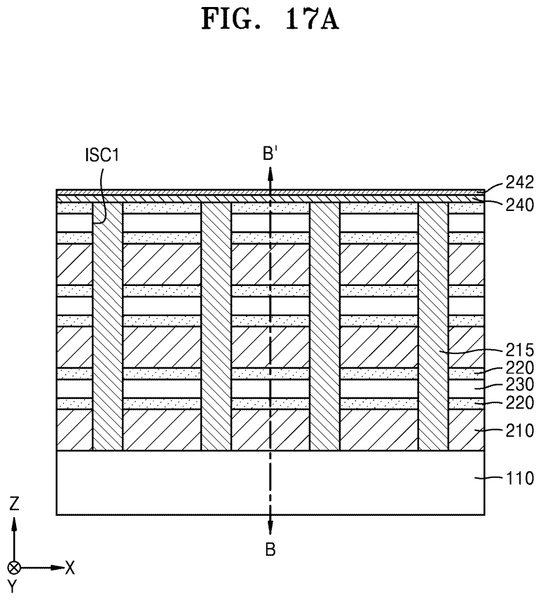

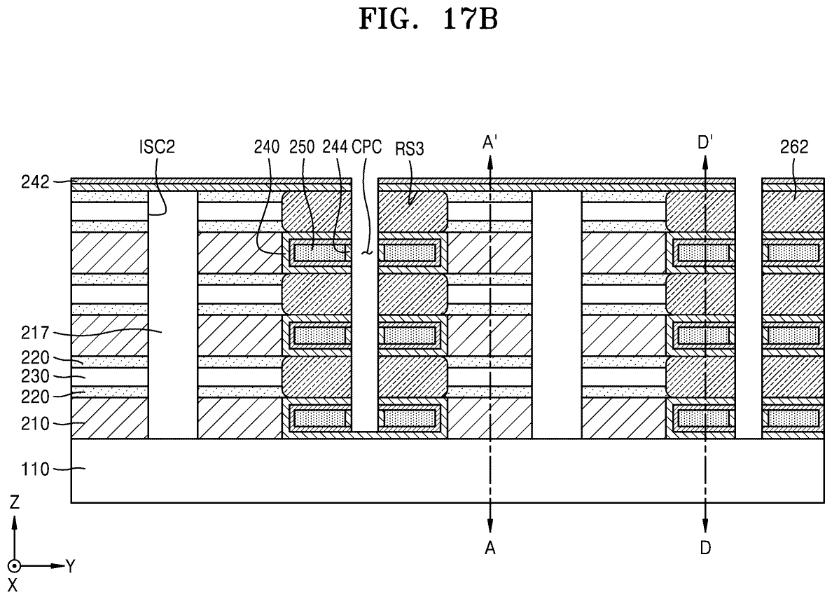

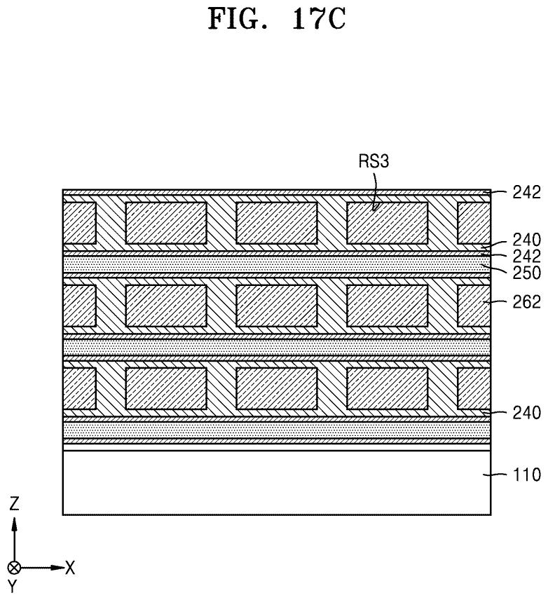

Referring to FIGS. 17A, 17B, and 17C, a plurality of first electrodes 262 that fill the plurality of third removal spaces RS3 may be formed. The plurality of first electrodes 262 may each include a metal or a conductive metal nitride. For example, the plurality of first electrodes 262 may each include a high-melting point metal, such as cobalt, titanium, nickel, tungsten, and molybdenum, and/or a conductive metal nitride, such as titanium nitride, titanium silicon nitride, titanium aluminum nitride, tantalum nitride, tantalum silicon nitride, tantalum aluminum nitride, and tungsten nitride.

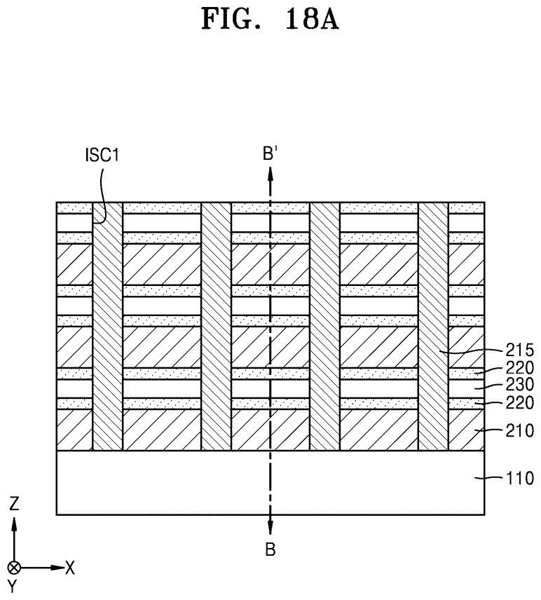

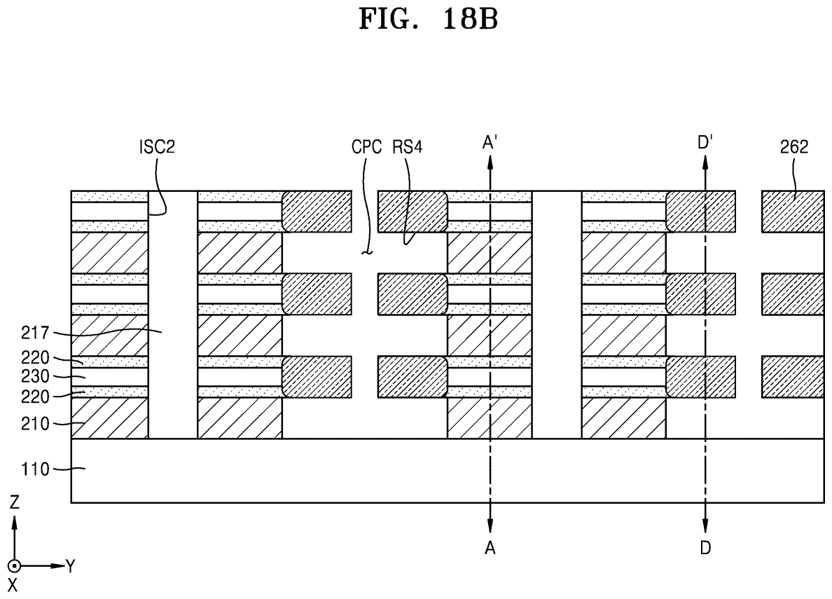

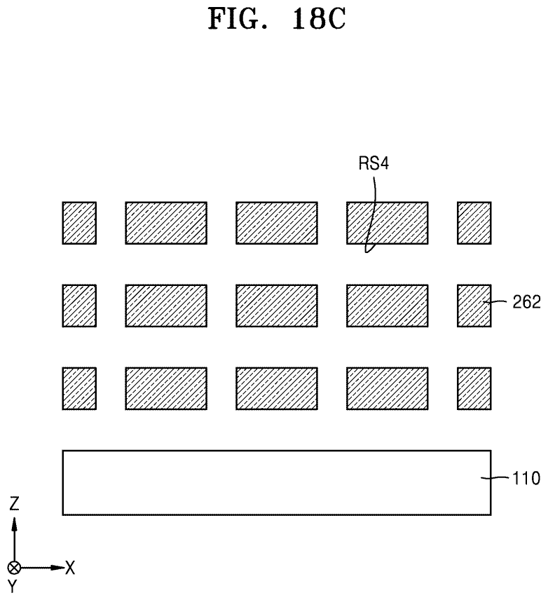

Referring to FIGS. 17A, 17B, and 17C, and FIGS. 18A, 18B, and 18C, the first cover insulating layer 240, the second cover insulating layer 242, the third cover insulating layer 244, and the plurality of filling insulating layers 250 may be removed to form a plurality of fourth removal spaces RS4. The plurality of sacrificial insulating layers 210 and the plurality of first electrodes 262 may be exposed within the plurality of fourth removal spaces RS4.

In some implementations, after the first cover insulating layer 240, the second cover insulating layer 242, the third cover insulating layer 244, and the plurality of filling insulating layers 250 are removed to form the plurality of fourth removal spaces RS4, the plurality of first electrodes 262 may be partially removed to reduce horizontal widths of the plurality of first electrodes 262 in the second horizontal direction (the Y direction) and heights of the plurality of first electrodes 262 in a vertical direction (the Z direction). For example, surfaces of the plurality of first electrodes 262 exposed in the plurality of capacitor isolation cut regions CPC and the plurality of fourth removal spaces RS4 may be partially removed.

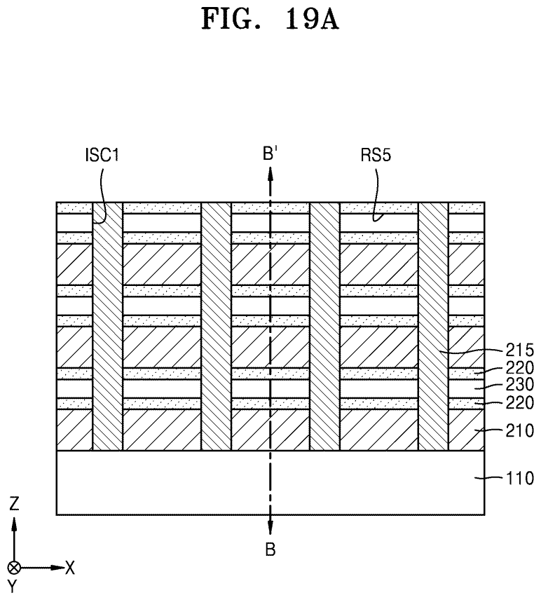

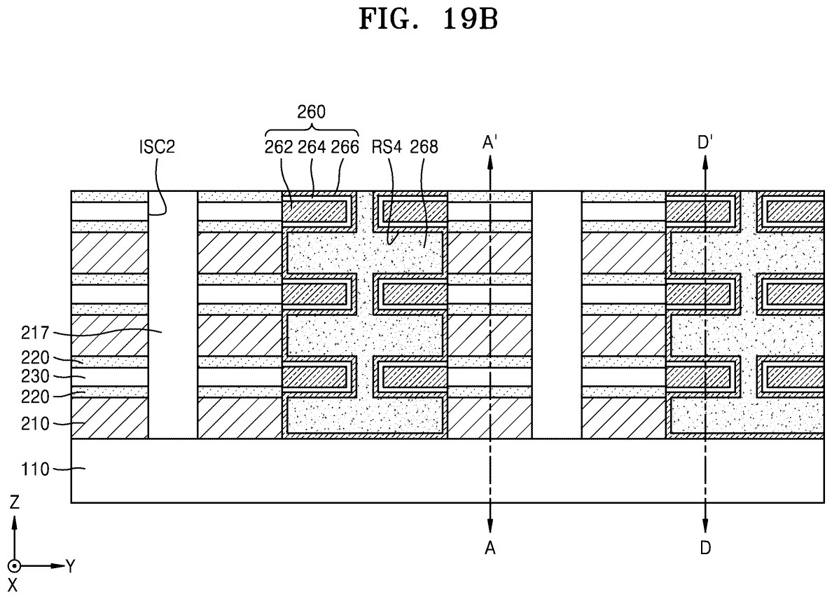

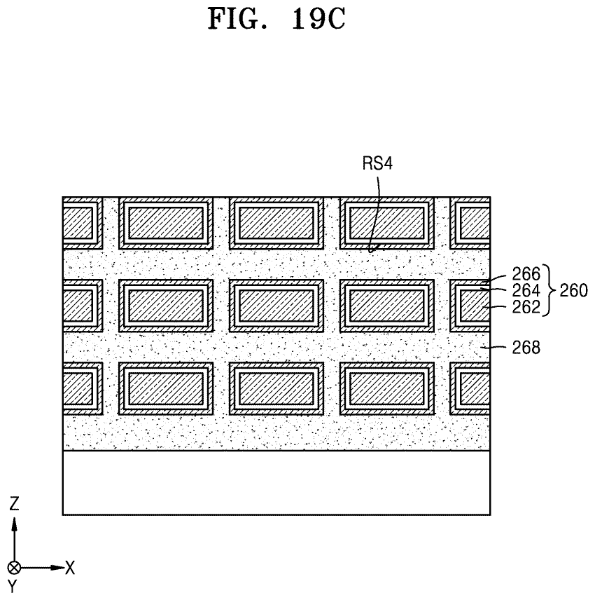

Referring to FIGS. 18A, 18B, and 18C, and FIGS. 19A, 19B, and 19C, a plurality of capacitor dielectric layers 264 and a plurality of second electrodes 266 covering the plurality of first electrodes 262 may be sequentially formed to form a plurality of capacitor structures 260. In some implementations, the plurality of capacitor dielectric layers 264 may conformally cover surfaces of the plurality of first electrodes 262. In some implementations, the plurality of second electrodes 266 may conformally cover surfaces of the plurality of capacitor dielectric layers 264 and surfaces of the plurality of sacrificial insulating layers 210. Thereafter, a plurality of capacitor spacer layers 268 may be formed to cover the plurality of second electrodes 266 and fill a capacitor isolation cut region CPC and the plurality of fourth removal spaces RS4.

The plurality of capacitor dielectric layers 264 may each be formed of at least one selected from among a high-k dielectric material and a ferroelectric material having a higher dielectric constant than a silicon oxide. For example, the plurality of capacitor dielectric layers 264 may each include at least one of a metal oxide and a dielectric material having a perovskite structure. In some implementations, the plurality of capacitor dielectric layers 264 may each be formed of at least one selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). For example, the plurality of second electrodes 266 may each be formed of doped silicon, Ru, RuO, Pt, PtO, Ir, IrO, SrRuO (SRO), (Ba, Sr)RuO (BSRO), CaRuO (CRO), BaRuO, La (Sr, Co)O, Ti, TiN, W, WN, Ta, TaN, TiAlN, TiSiN, TaAlN, TaSiN, or a combination thereof. In some implementations, the plurality of second electrodes 266 may each include tungsten (W).

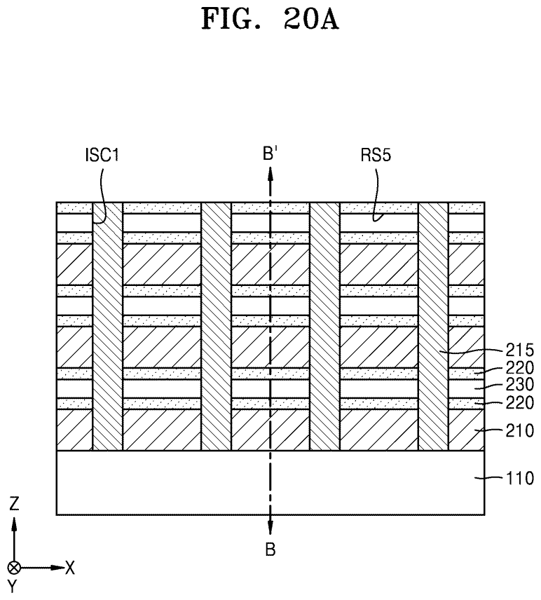

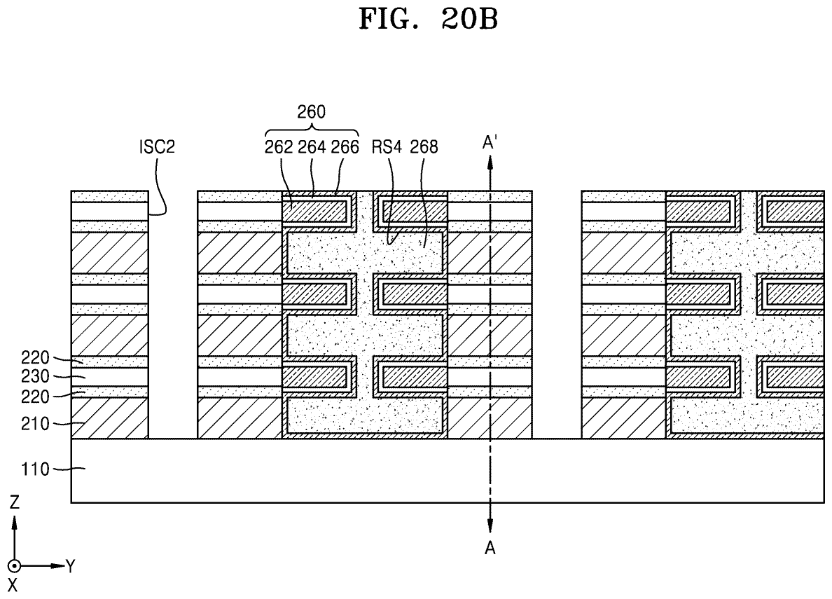

Referring to FIGS. 19A, 19B, and19C, and FIGS. 20A and 20B, the plurality of second filling insulating sacrificial layers 217 that fill the plurality of second element isolation cut regions ISC2 may be removed.

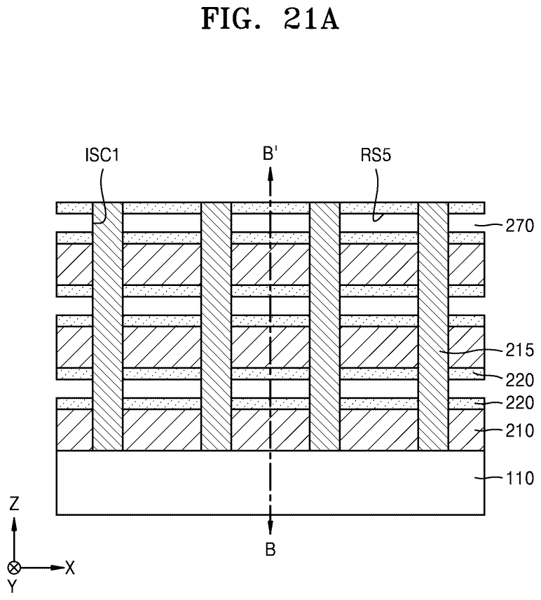

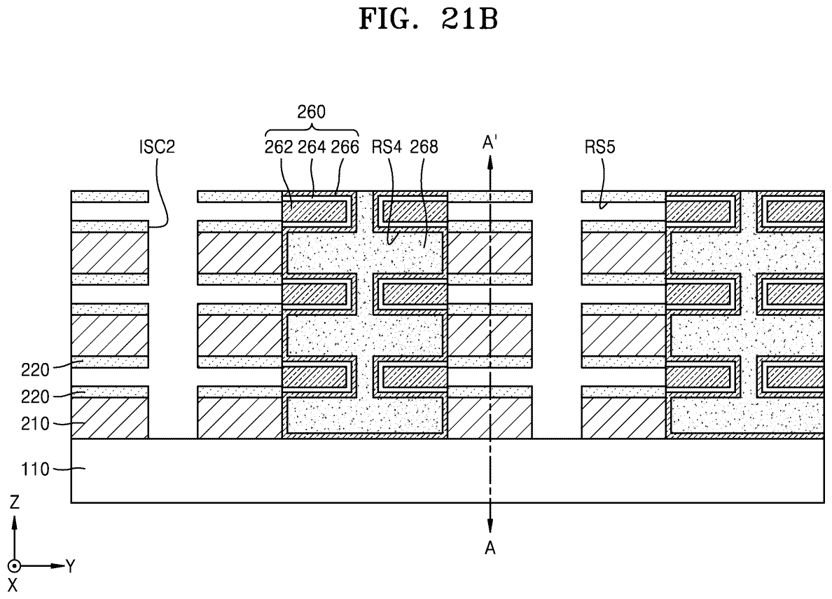

Referring to FIGS. 20A and 20B and FIGS. 21A and 21B, the plurality of sacrificial semiconductor layers 230 may be removed through the plurality of second element isolation cut regions ISC2 to form a plurality of fifth removal spaces RS5. For example, the plurality of fifth removal spaces RS5 may be formed by removing all of the plurality of sacrificial semiconductor layers 230.

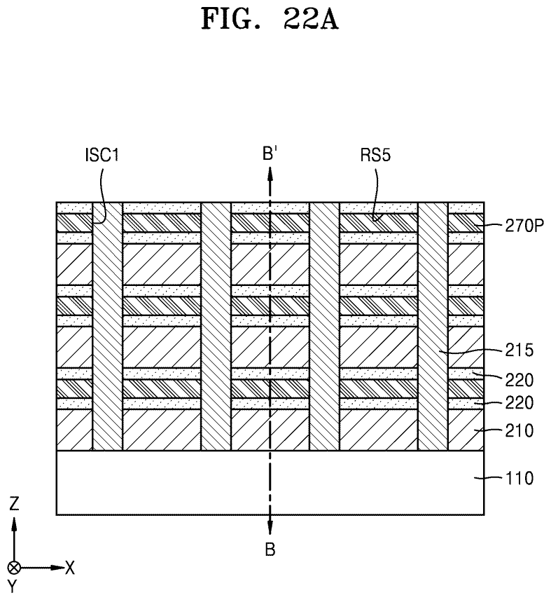

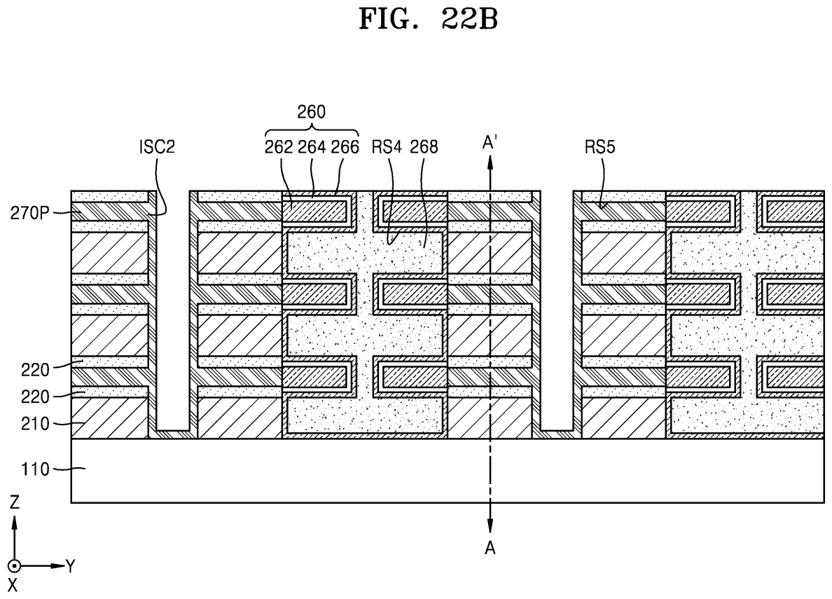

Referring to FIGS. 22A and 22B, a plurality of channel material layers 270P, which fill the plurality of fifth removal spaces RS5 and partially fill the plurality of second element isolation cut regions ISC2, may be formed. The plurality of channel material layers 270P may fill all of the plurality of fifth removal spaces RS5 but not all of the plurality of second element isolation cut regions ISC2. The plurality of channel material layers 270P may each include an oxide semiconductor material. For example, the plurality of channel material layers 270P may each include InₓGa_{y}Zn_{z}O, Sn doped InₓGa_{y}Zn_{z}O, InₓGa_{y}Si_{z}O, InₓSn_{y}Zn_{z}O, InₓZn_{y}O, W doped InO, InZnₓO, ZnₓSn_{y}O, ZnₓO_{y}N, ZrₓZn_{y}Sn_{z}O, Y(Yttrium) doped ZnO, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or a combination thereof.

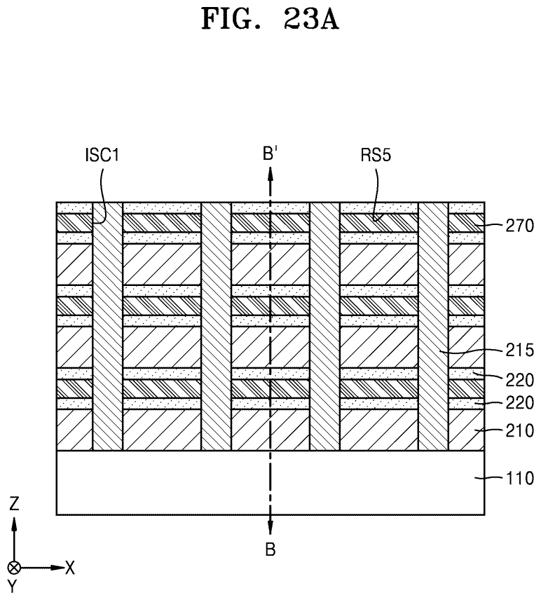

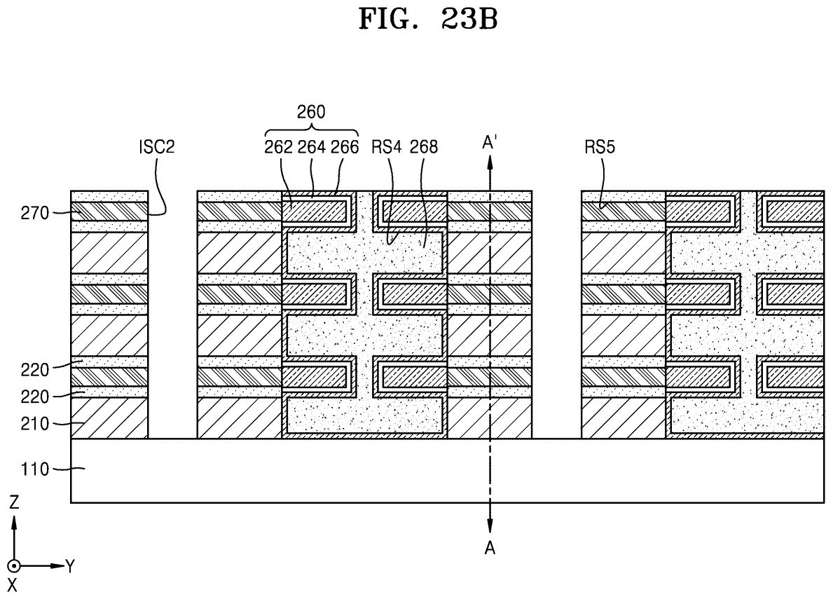

Referring to FIGS. 22A and 22B, and FIGS. 23A and 23B, the plurality of channel material layers 270P may be partially removed to form the plurality of channel patterns 270 that fill the plurality of fifth removal spaces RS5. The plurality of channel patterns 270 may be formed by removing the portions that partially fill the plurality of second element isolation cut regions ISC2 among the plurality of channel material layers 270P. In some implementations, the plurality of channel patterns 270 may fill all of the plurality of fifth removal spaces RS5.

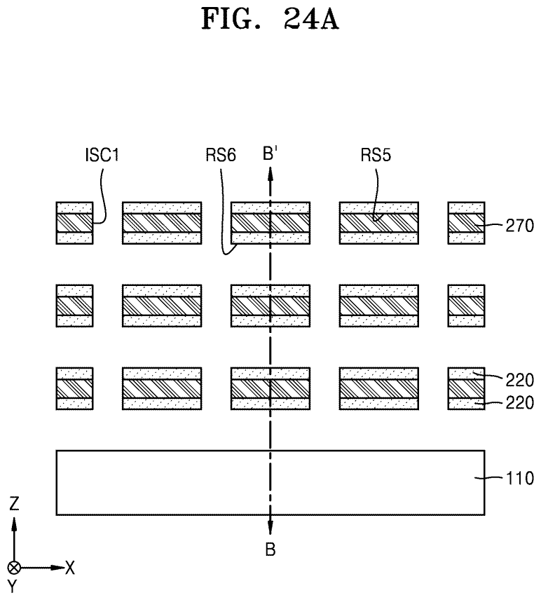

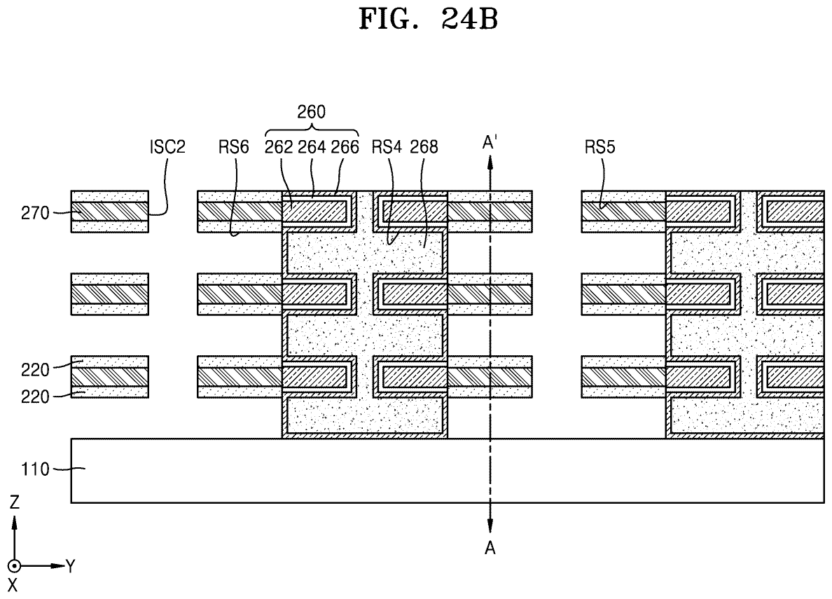

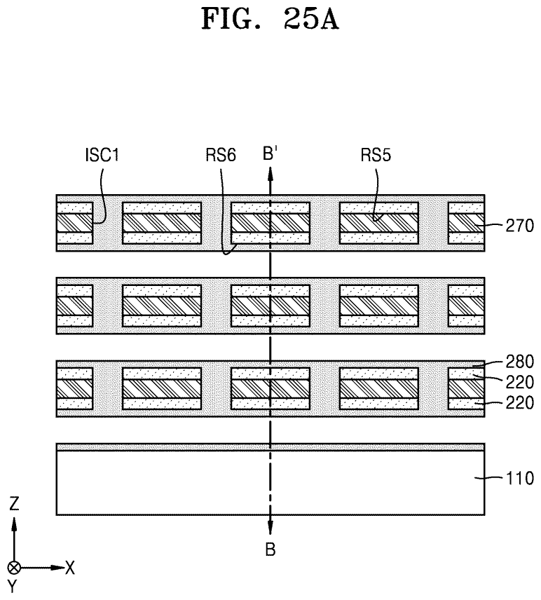

Referring to FIGS. 24A and 24B, the plurality of first filling insulating sacrificial layers 215 that fill the plurality of first element isolation cut regions ISC1 may be removed, and the plurality of sacrificial insulating layers 210 may be removed to form a plurality of sixth removal spaces RS6. The plurality of sixth removal spaces RS6 may be connected to the plurality of first element isolation cut regions ISC1 and the plurality of second element isolation cut regions ISC2.

The plurality of base insulating layers 220 and the plurality of second electrodes 266 may be exposed within the plurality of sixth removal spaces RS6.

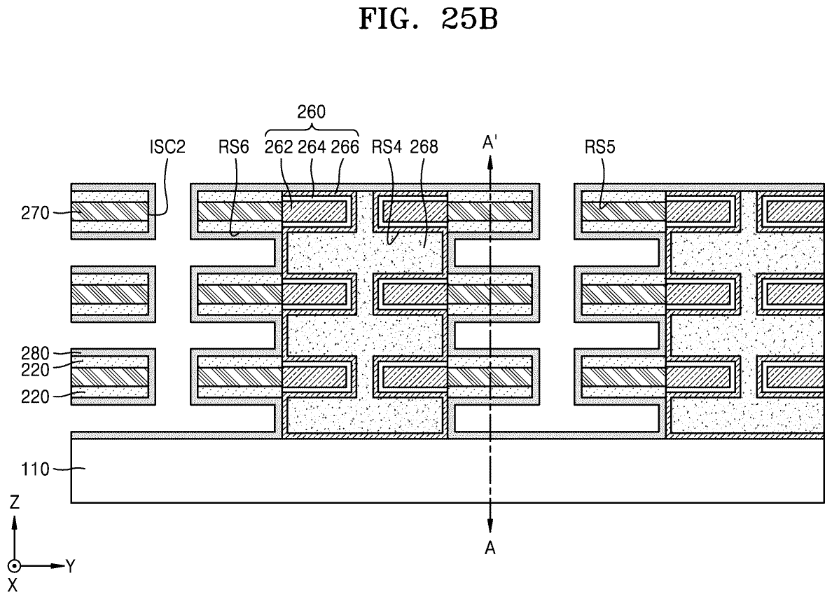

Referring to FIGS. 25A and 25B, a channel cover insulating layer 280 may be formed to cover surfaces exposed in the results of FIGS. 24A and 24B. The channel cover insulating layer 280 may conformally cover a surface of each of the substrate 110, the plurality of base insulating layers 220, the plurality of channel patterns 270, and the plurality of capacitor spacer layers 268. In some implementations, the channel cover insulating layer 280 may fill all of spaces between the base insulating layers 220 adjacent to each other in the first horizontal direction (the X direction) among the plurality of first element isolation cut regions ISC1 and spaces between the channel patterns 270, but may not fill all of spaces between the base insulating layers 220 adjacent to each other in the second horizontal direction (the Y direction) among the plurality of second element isolation cut regions ISC2 and spaces between the channel patterns 270. The channel cover insulating layer 280 may not fill a part of each of the plurality of sixth removal spaces RS6 and a part of each of the plurality of second element isolation cut regions ISC2. The channel cover insulating layer 280 may be formed of at least one material selected from among a silicon oxide, a high-k dielectric material having a higher dielectric constant than the silicon oxide, and a ferroelectric material. The channel cover insulating layer 280 may be formed of the same material as the base insulating layer 220 but is not limited thereto. For example, the base insulating layer 220 and the channel cover insulating layer 280 may each be formed of another material selected from among the silicon oxide, the high-k dielectric material having a higher dielectric constant than the silicon oxide, and the ferroelectric material.

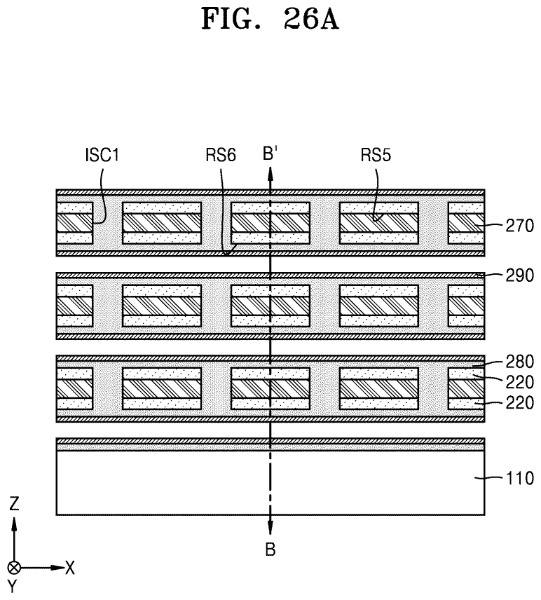

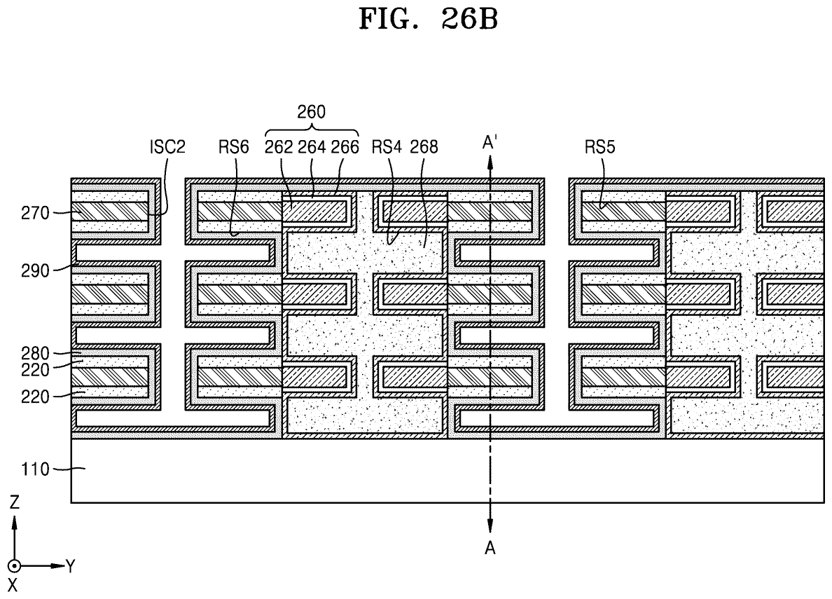

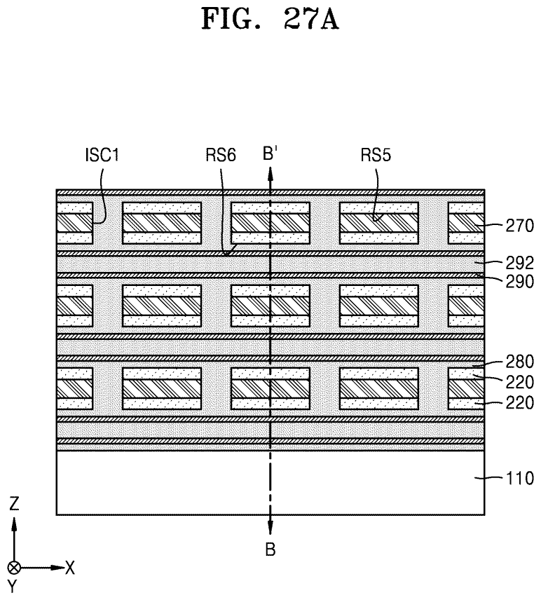

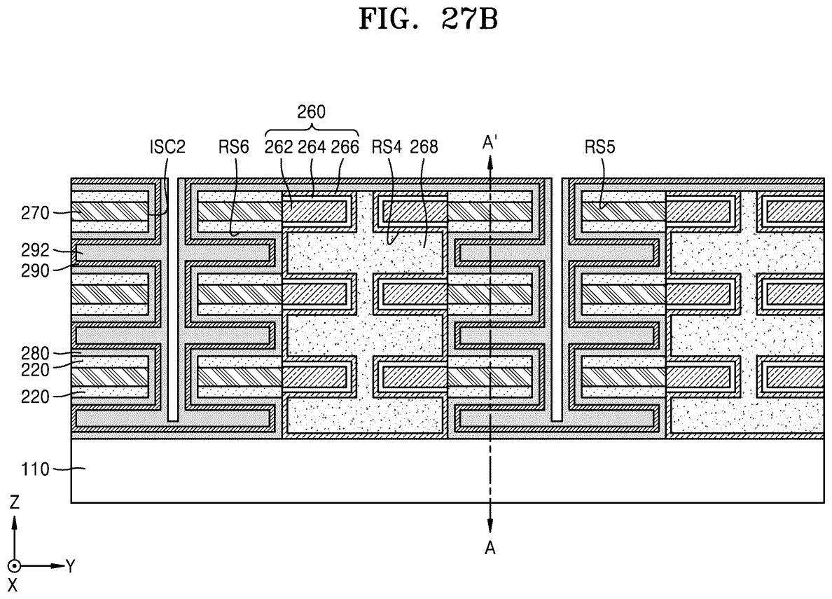

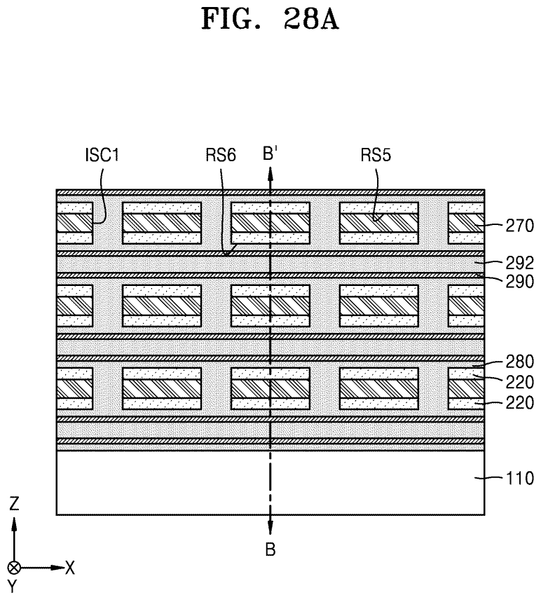

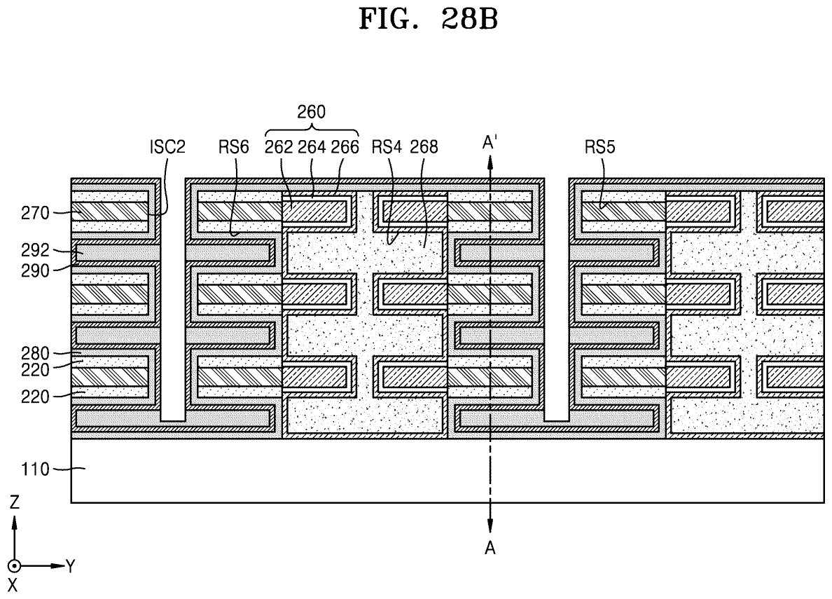

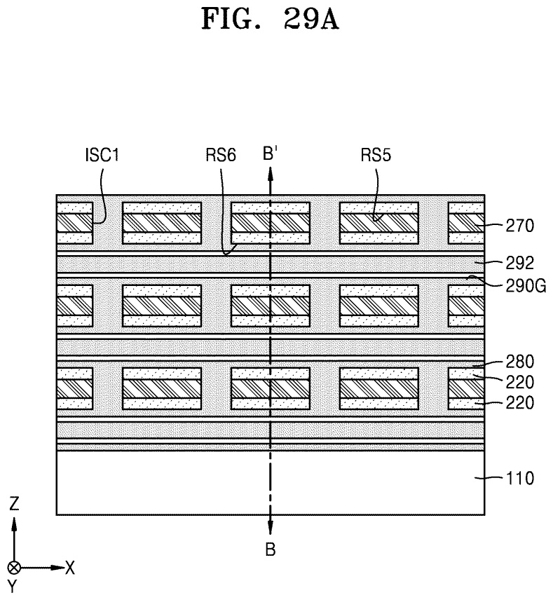

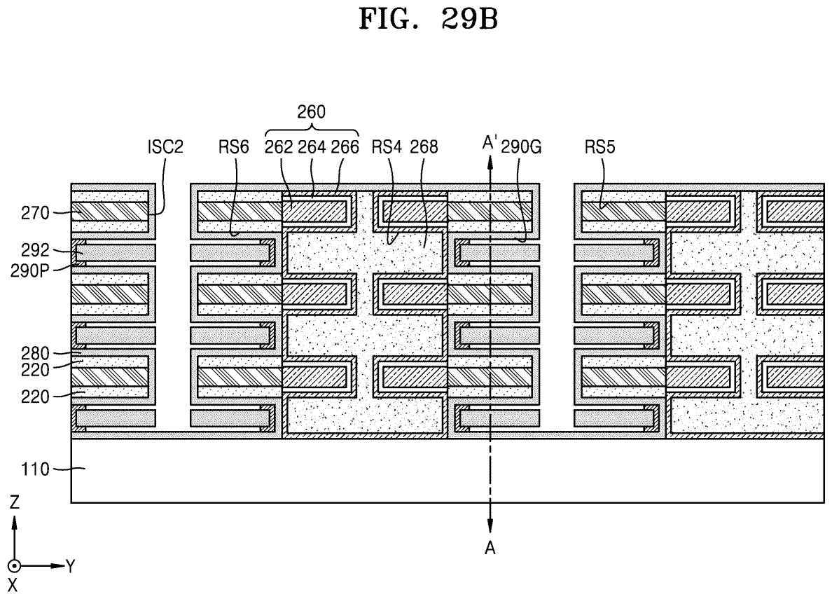

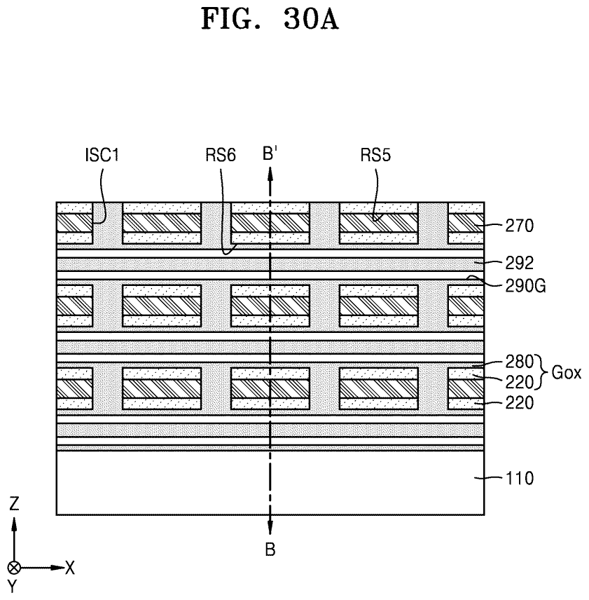

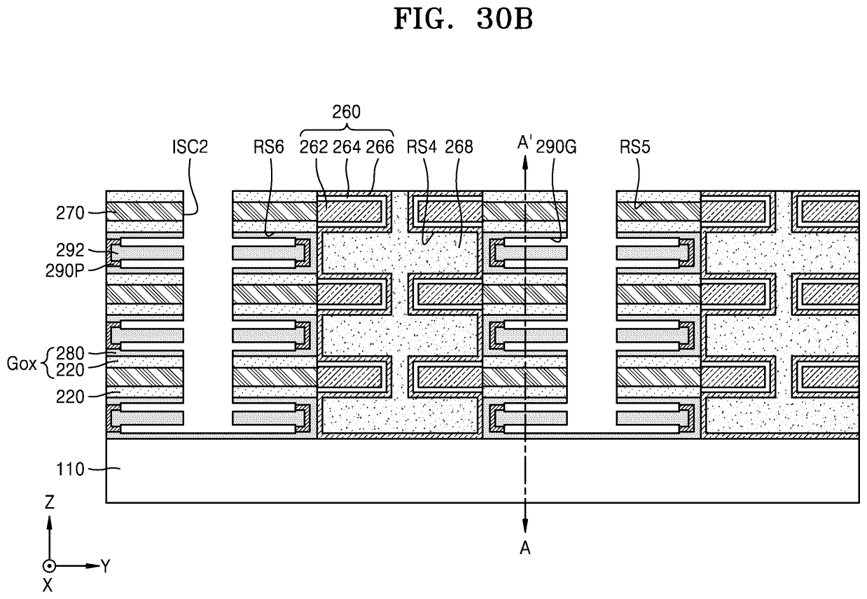

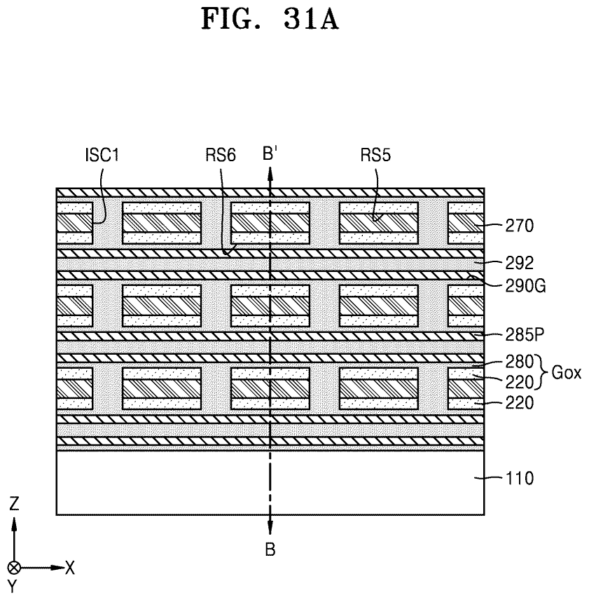

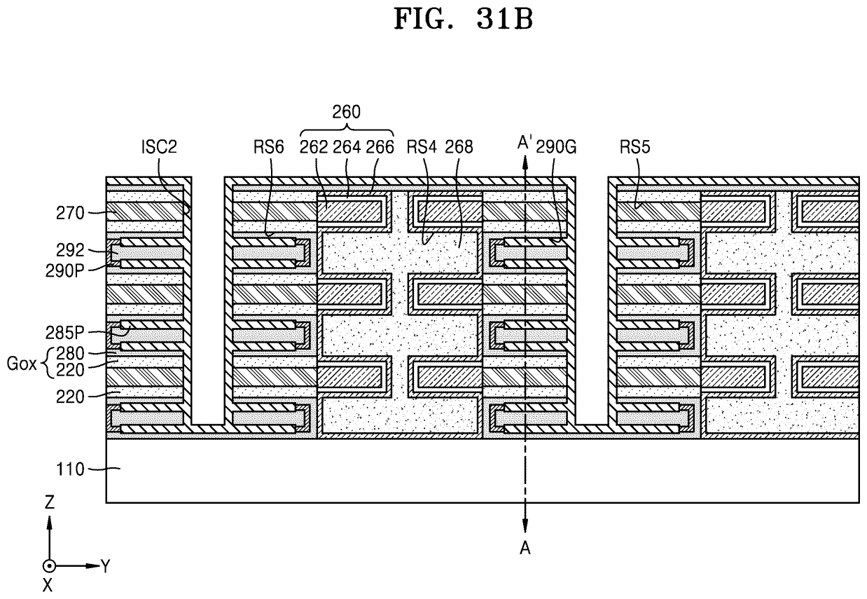

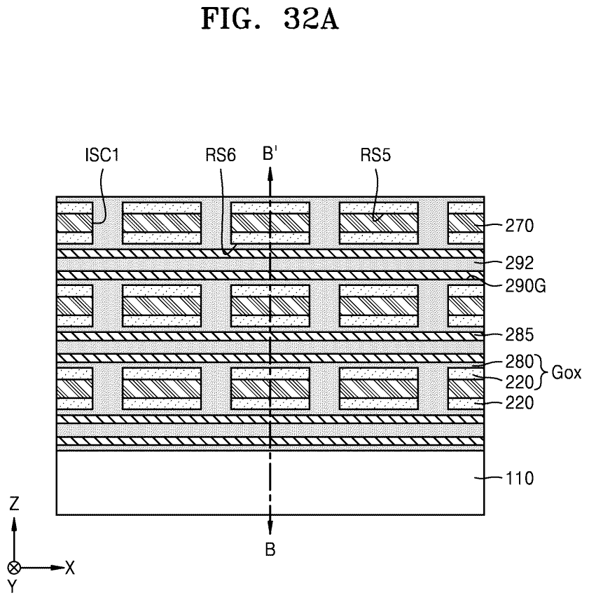

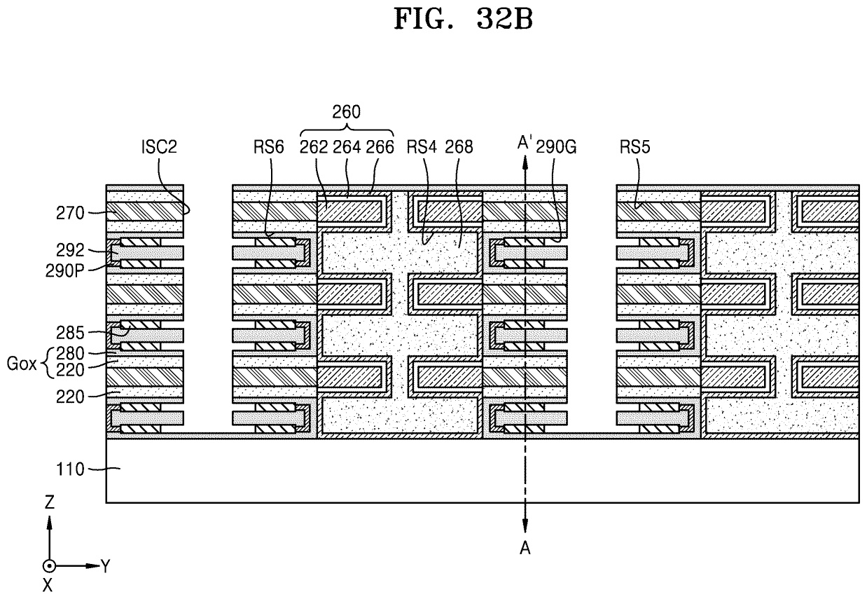

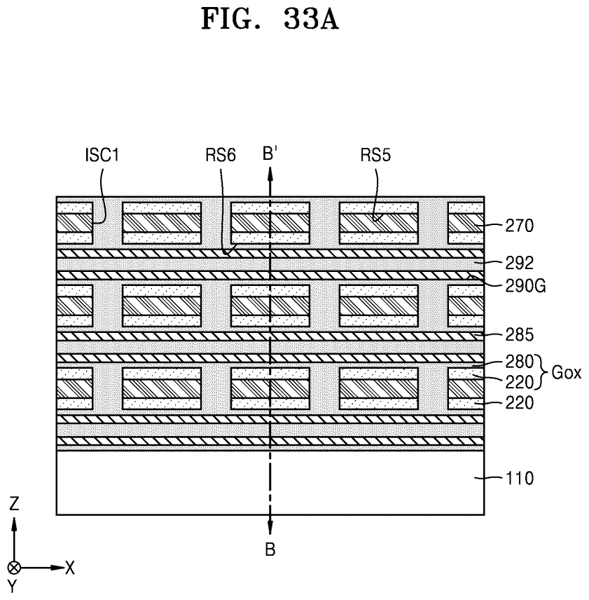

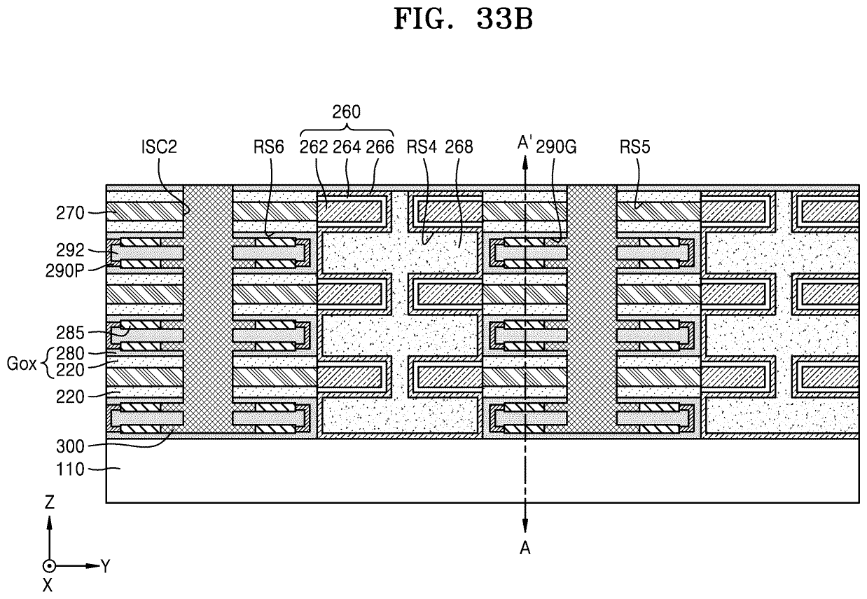

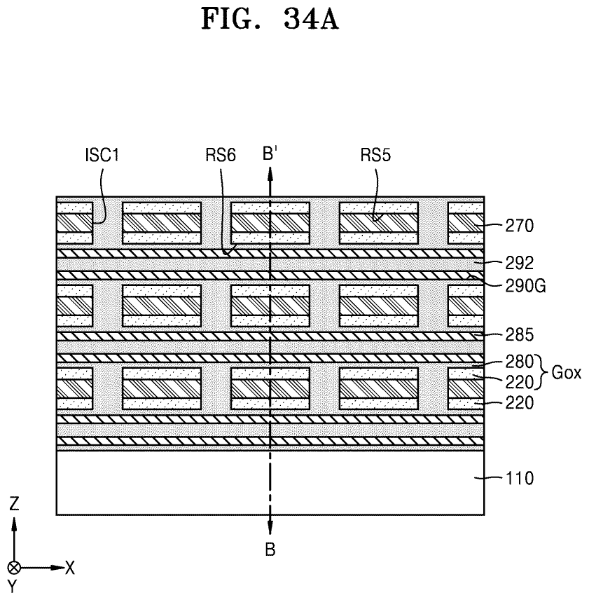

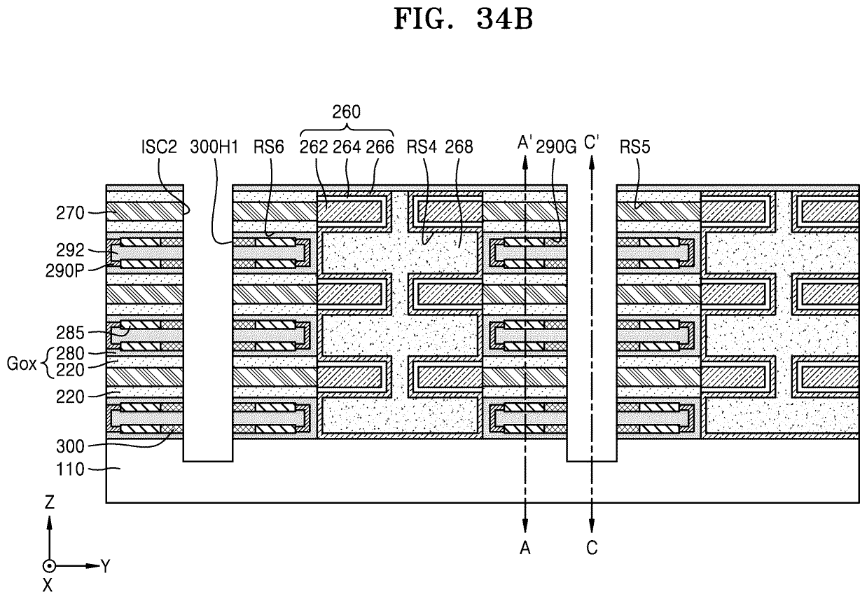

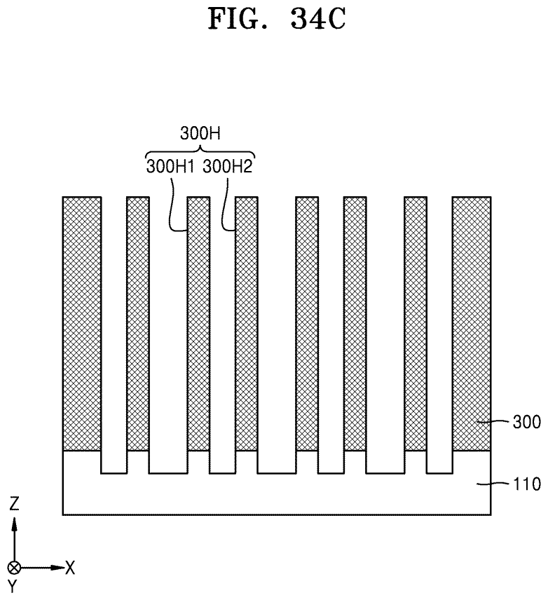

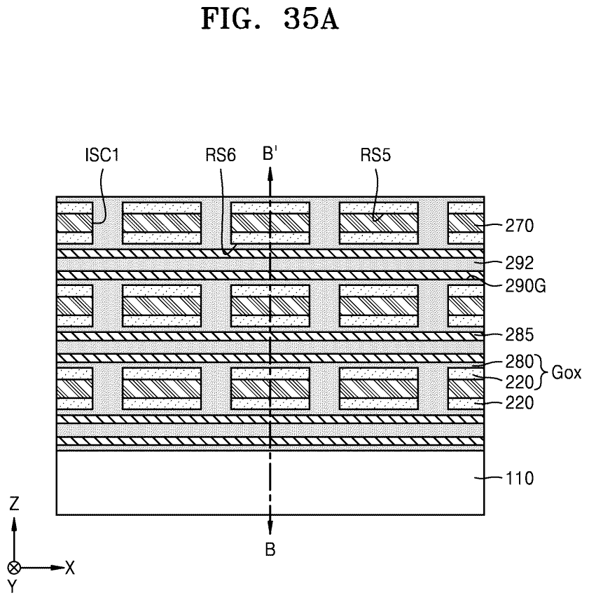

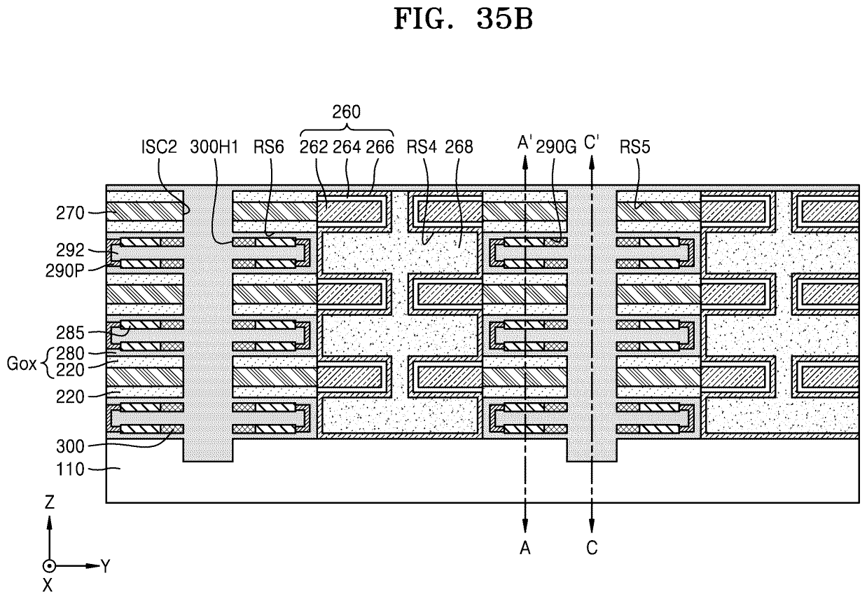

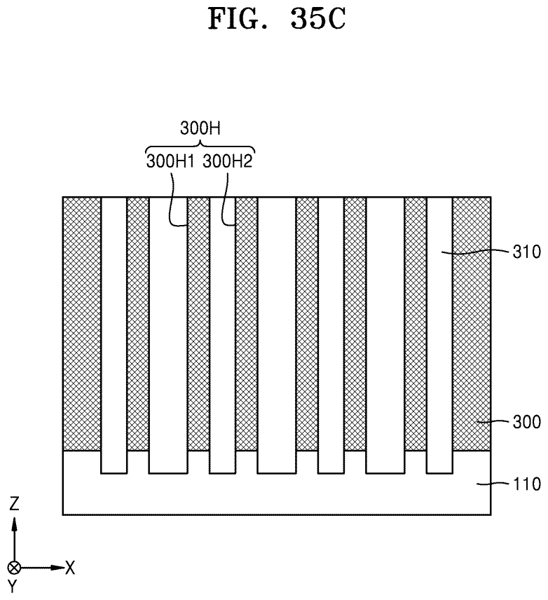

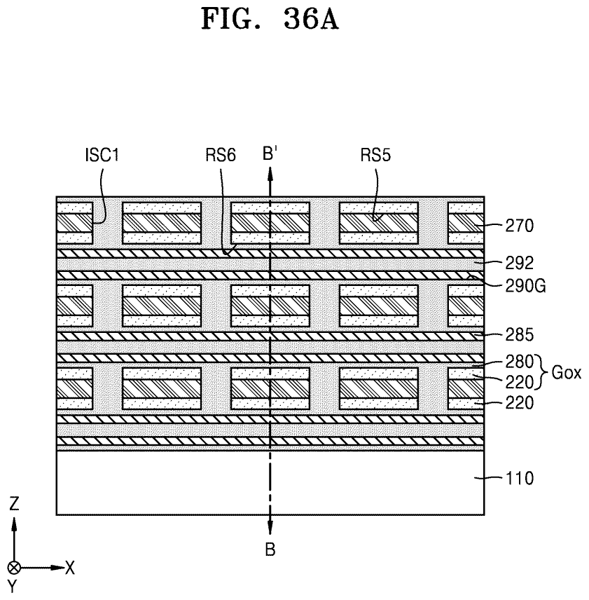

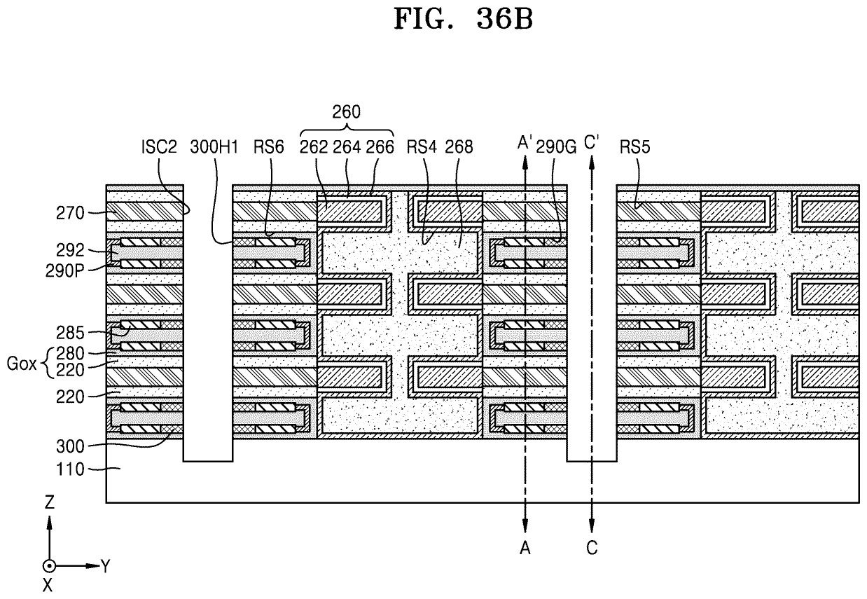

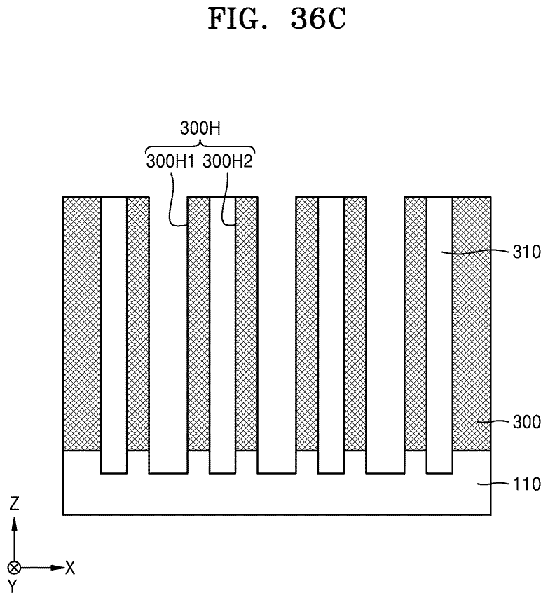

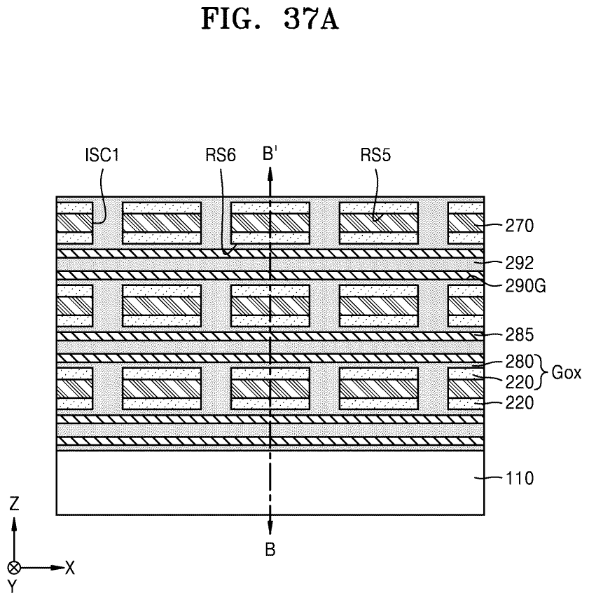

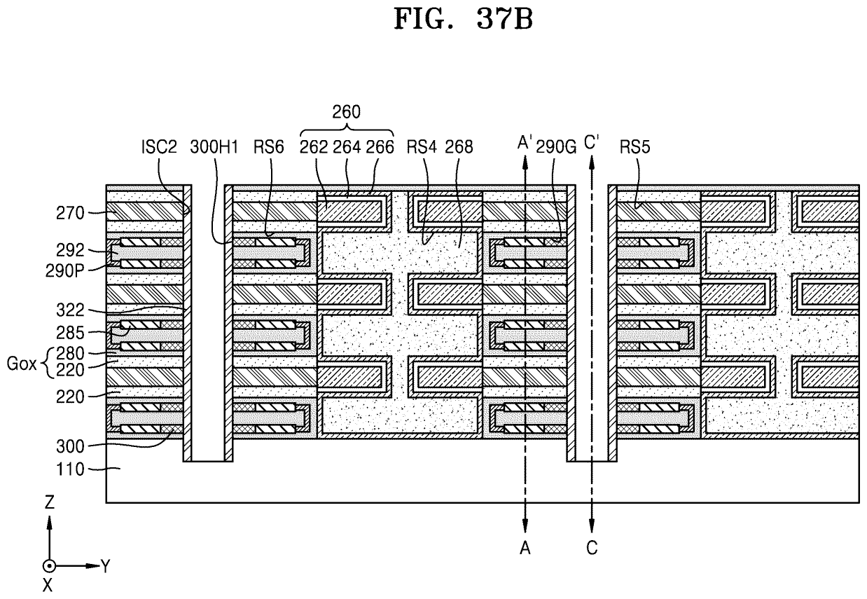

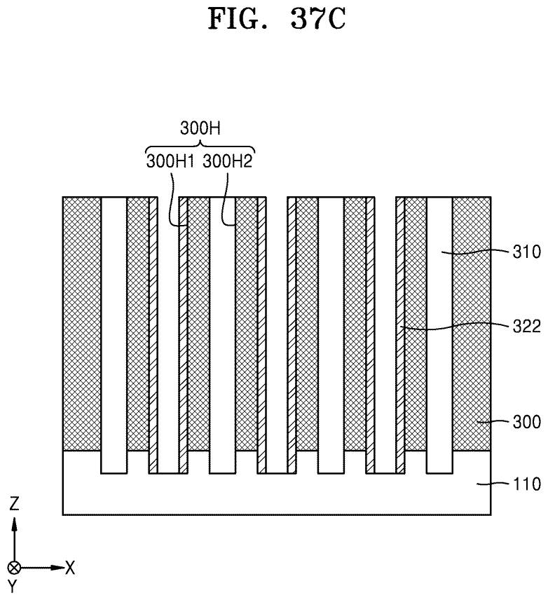

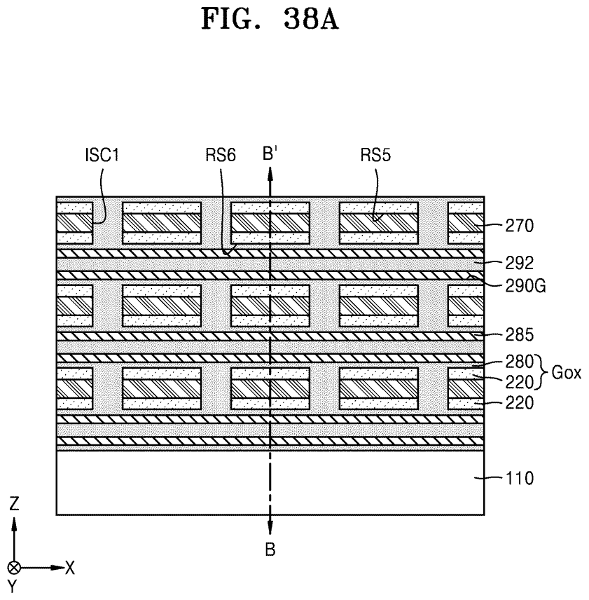

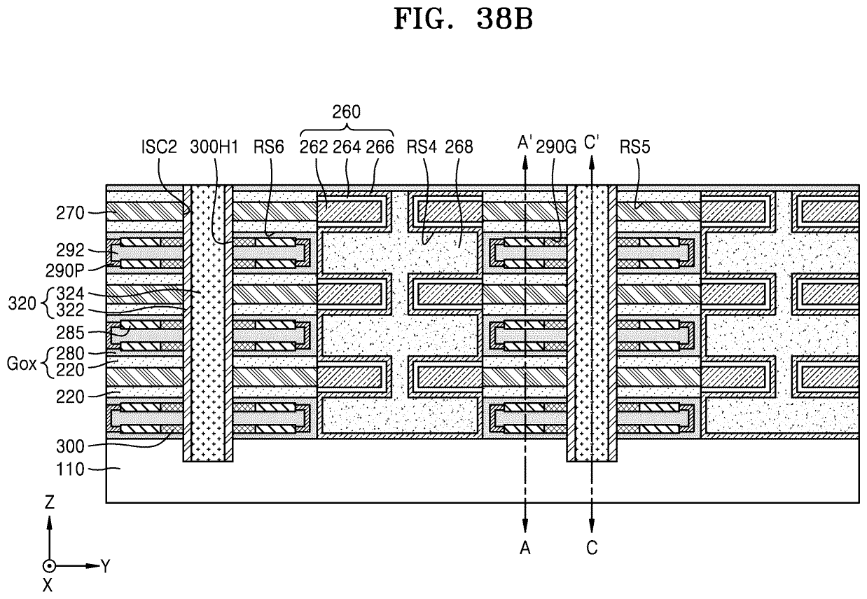

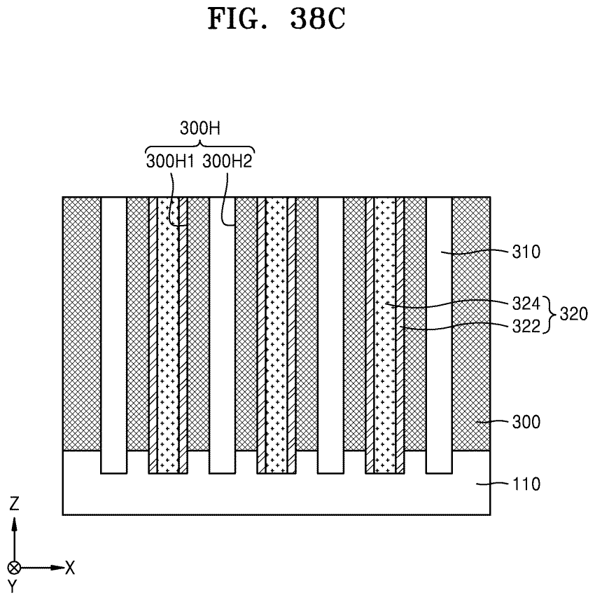

Referring to FIGS. 26A and 26B, a gate isolation insulating layer 290 that covers the channel cover insulating layer 280 may be formed. The gate isolation insulating layer 290 may conformally cover the channel cover insulating layer 280. The gate isolation insulating layer 290 may not fill a part of each of the plurality of sixth removal spaces RS6, a part of each of the plurality of first element isolation cut regions ISC1, and a part of each of the plurality of second element isolation cut regions ISC2. The gate isolation insulating layer 290 may include a nitride. For example, the gate isolation insulating layer 290 may include a silicon nitride.

Referring to FIGS. 27A and 27B, an interlayer insulating layer 292 that covers the gate isolation insulating layer 290 may be formed. The interlayer insulating layer 292 may be formed to fill all of the plurality of sixth removal spaces RS6 but not all of the plurality of second element isolation cut regions ISC2. The interlayer insulating layer 292 may include an oxide. For example, the interlayer insulating layer 292 may include a silicon oxide.

Referring to FIGS. 28A and 28B, a portion of the interlayer insulating layer 292 which covers a side surface of the gate isolation insulating layer 290 may be removed to divide the interlayer insulating layer 292 into multiple pieces within the plurality of second element isolation cut regions ISC2. In some implementations, a side surface of the gate isolation insulating layer 290 may be aligned with a side surface of the interlayer insulating layer 292 in the vertical direction (the Z direction) within the plurality of second element isolation cut regions ISC2.

Referring to FIGS. 28A and 28B and FIGS. 29A and 29B, the gate isolation insulating layer 290 may be partially removed to form a plurality of gate isolation insulating patterns 290P. The plurality of gate isolation insulating patterns 290P may be formed by removing portions of the gate isolation insulating layer 290 located within the plurality of second element isolation cut regions ISC2 and at least portions between a plurality of channel cover insulating layers 280 and a plurality of interlayer insulating layers 292. A gate space 290G may be defined between the channel cover insulating layers 280 and the plurality of interlayer insulating layers 292 adjacent to each other in the vertical direction (the Z direction) by removing a part of the gate isolation insulating layer 290.

In some implementations, the plurality of gate isolation insulating patterns 290P may each have a U-shaped vertical cross-section in a vertical cross-section (a Y-Z vertical cross-section) formed by the second horizontal direction (the Y direction) and the vertical direction (the Z direction), but may have a U-shaped vertical cross-section rotated by 90 degrees such that a closed portion of a U shape faces the plurality of second electrodes 266 and an open portion of the U shape faces the plurality of second element isolation cut regions ISC2. For example, each of the plurality of gate isolation insulating patterns 290P may have a pair of horizontal portions between a pair of channel cover insulating layers 280 and the interlayer insulating layer 292, and a vertical portion between the second electrode 266 and the interlayer insulating layer 292. A vertical height of the gate space 290G may be substantially equal to a vertical height (that is, a thickness) of the horizontal portion of the gate isolation insulating pattern 290P.

In some implementations, the plurality of gate isolation insulating patterns 290P may be formed by removing a portion of the gate isolation insulating layer 290 which is located within the plurality of second element isolation cut regions ISC2, and removing portions between the plurality of channel cover insulating layers 280 and the plurality of interlayer insulating layers 292. For example, the plurality of gate isolation insulating patterns 290P may have an I-shaped vertical shape separated from the plurality of second electrodes 266 while having the plurality of channel cover insulating layers 280 between the plurality of gate isolation insulating patterns 290P in a vertical cross-section (a Y-Z vertical cross-section) formed by the second horizontal direction (the Y direction) and the vertical direction (the Z direction). The plurality of gate isolation insulating patterns 290P may each be composed of only a vertical portion between the second electrode 266 and the interlayer insulating layer 292.

Referring to FIGS. 30A and 30B, the plurality of channel cover insulating layers 280 and the plurality of interlayer insulating layers 292 may be partially removed to expose side surfaces of the plurality of base insulating layers 220 and side surfaces of the plurality of channel patterns 270 within the plurality of second element isolation cut regions ISC2.

By partially removing the plurality of channel cover insulating layers 280 and the plurality of interlayer insulating layers 292, vertical height of a plurality of gate spaces 290G defined between the plurality of channel cover insulating layers 280 and the plurality of interlayer insulating layers 292 may be increased. For example, the vertical heights of the plurality of gate spaces 290G may be greater than vertical heights (that is, thicknesses) of the horizontal portions of the plurality of gate isolation insulating patterns 290P. The plurality of base insulating layers 220 and the plurality of channel cover insulating layers 280 may constitute a plurality of gate dielectric layers Gox.

Referring to FIGS. 31A and 31B, an electrode material layer 285P may be formed to cover surfaces exposed in the results of FIGS. 30A and 30B. The electrode material layer 285P may be formed to fill all of the plurality of gate spaces 290G. The electrode material layer 285P may include a metal, a conductive metal nitride, or a combination thereof. In some implementations, the electrode material layer 285P may be formed of a conductive barrier layer and a conductive filling layer that covers the conductive barrier layer. The conductive barrier layer may include, for example, a metal, a conductive metal nitride, a conductive metal silicide, or a combination thereof. For example, the conductive barrier layer may be formed of TiN. The conductive filling layer may be formed of, for example, doped silicon, Ru, RuO, Pt, PtO, Ir, IrO, SrRuO (SRO), (Ba, Sr)RuO (BSRO), CaRuO (CRO), BaRuO, La(Sr, Co)O, Ti, TiN, W, WN, Ta, TaN, TiAlN, TiSiN, TaAlN, TaSiN, or a combination thereof. In some implementations, the conductive filling layer may include tungsten (W).

Referring to FIGS. 31A and 31B, and FIGS. 32A and 32B, a part of the electrode material layer 285P may be removed to form a plurality of gate electrode layers 285. The plurality of gate electrode layers 285 may be formed by causing only portions of the electrode material layer 285P which are located in inner portions of the plurality of gate spaces 290G, to remain and by removing the other portions. The plurality of gate electrode layers 285 may be in contact with the plurality of gate isolation insulating patterns 290P and may fill some inner portions of the plurality of gate spaces 290G.

Referring to FIGS. 33A and 33B, a spacer layer 300 may be formed to fill the plurality of gate spaces 290G and the plurality of second element isolation cut regions ISC2. The spacer layer 300 may include oxide, nitride, oxynitride, carbonitride, or a combination thereof.

Referring to FIGS. 34A, 34B, and 34C, portions of the spacer layer 300 which fill the plurality of second element isolation cut regions ISC2 may be removed to form a plurality of vertical holes 300H. The plurality of vertical holes 300H may be arranged in rows to be separated from each other in the first horizontal direction (the X direction), within each of the plurality of second element isolation cut regions ISC2. In some implementations, the plurality of vertical holes 300H may be formed by partially removing the spacer layer 300 and an upper side of the substrate 110. For example, the plurality of vertical holes 300H may penetrate the spacer layer 300 and extend into the substrate 110.

The plurality of vertical holes 300H may include a plurality of first vertical holes 300H1 and a plurality of second vertical holes 300H2 that are alternately arranged in the first horizontal direction (the X direction). The plurality of channel patterns 270 may be exposed within the plurality of first vertical holes 300H1. The plurality of channel patterns 270 may not be exposed within the plurality of second vertical holes 300H2. In some implementations, horizontal widths of the plurality of first vertical holes 300H1 in the first horizontal direction (the X direction) may be greater than horizontal widths of the plurality of second vertical holes 300H2. The horizontal widths of the plurality of first vertical holes 300H1 may be substantially equal to the horizontal widths of the plurality of second vertical holes 300H2 in the second horizontal direction (the Y direction).

Referring to FIGS. 35A, 35B, and 35C, a plurality of mold layers 310 may be formed to fill the plurality of vertical holes 300H. The plurality of mold layers 310 may each be formed of a material having etching selectivity with respect to the spacer layer 300. In some implementations, the plurality of mold layers 310 may each include an oxide. For example, the plurality of mold layers 310 may each include a silicon oxide.

Referring to FIGS. 35A, 35B, and 35C, and FIGS. 36A, 36B, and 36C, the mold layers 310 that fill the plurality of first vertical holes 300H1 among the plurality of mold layers 310 may be removed to expose the plurality of channel patterns 270 within the plurality of first vertical holes 300H1. The mold layers 310 that fill the plurality of second vertical holes 300H2 among the plurality of mold layers 310 may remain without being removed.

Referring to FIGS. 37A, 37B, and 37C, a plurality of oxide semiconductor layers 322 that cover inner surfaces of the plurality of first vertical holes 300H1 may be formed. The plurality of oxide semiconductor layers 322 may conformally cover the inner surfaces of the plurality of first vertical holes 300H1 to cover only a part of each of the plurality of first vertical holes 300H1. The plurality of oxide semiconductor layers 322 may be in contact with the plurality of channel patterns 270. In some implementations, the plurality of oxide semiconductor layers 322 may not cover at least a part of portions of the substrate 110 which are exposed to bottom surfaces of the plurality of first vertical holes 300H1. The plurality of oxide semiconductor layers 322 may each be formed of InₓGa_{y}Zn_{z}O, Sn doped InₓGa_{y}Zn_{z}O, InₓGa_{y}Si_{z}O, InₓSn_{y}Zn_{z}O, InₓZn_{y}O, W doped InO, InZnₓO, ZnₓSn_{y}O, ZnₓO_{y}N, ZrₓZn_{y}Sn_{z}O, Y(Yttrium) doped ZnO, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof.

Referring to FIGS. 38A, 38B, and 38C, a plurality of core conductive layers 324 that fill the plurality of first vertical holes 300H1 may be formed on the plurality of oxide semiconductor layers 322 to form a plurality of bit line structures 320, each including the core conductive layer 324 and the oxide semiconductor layer 322. The plurality of core conductive layers 324 may each include a metal, a conductive metal nitride, or a combination thereof. In some implementations, the plurality of core conductive layers 324 may each be formed of a conductive barrier layer and a conductive filling layer that covers the conductive barrier layer.

Thereafter, the plurality of mold layers 310 that fill the plurality of second vertical holes 300H2 may be removed, and the bit line shield structures 330 illustrated in FIGS. 3A, 3B, 3C, 3D, and 3E which fill the plurality of second vertical holes 300H2 may be formed to form the semiconductor memory device 1. The bit line shield structures 330 may each include a metal, a conductive metal nitride, or a combination thereof. In some implementations, the bit line shield structures 330 may each be formed of the same material as the core conductive layer 324. In some implementations, before the plurality of core conductive layers 324 are formed, the plurality of mold layers 310 that fill the plurality of second vertical holes 300H2 may be removed, and then a plurality of conductive material layers that fill both the plurality of first vertical holes 300H1 and the plurality of second vertical holes 300H2 may be formed to form the plurality of core conductive layers 324 and the bit line shield structures 330.

In the method of manufacturing the semiconductor memory device 1, according to the present disclosure, main components of the semiconductor memory device 1 may be formed through a deposition process rather than an epitaxial growth process, and thus, the semiconductor memory device 1 may be easily manufactured.

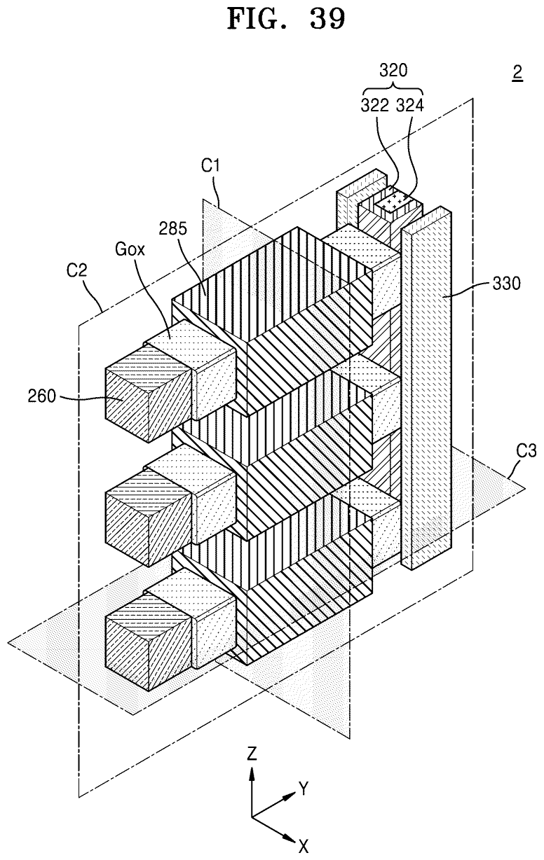

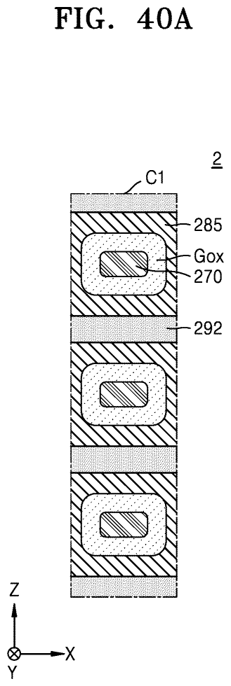

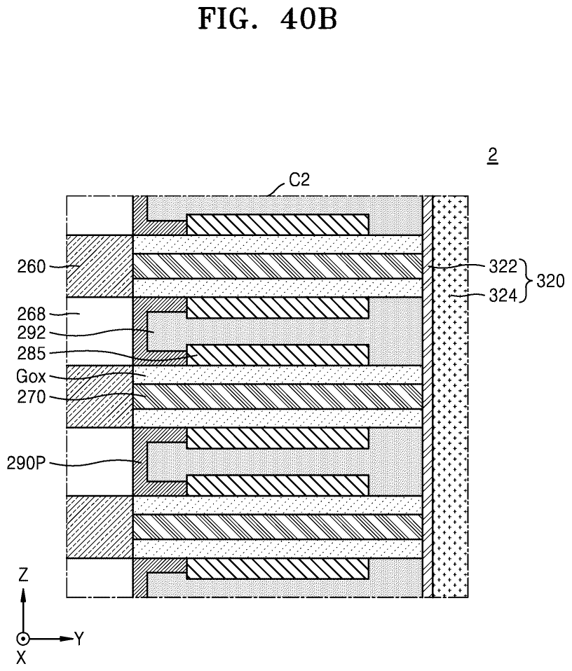

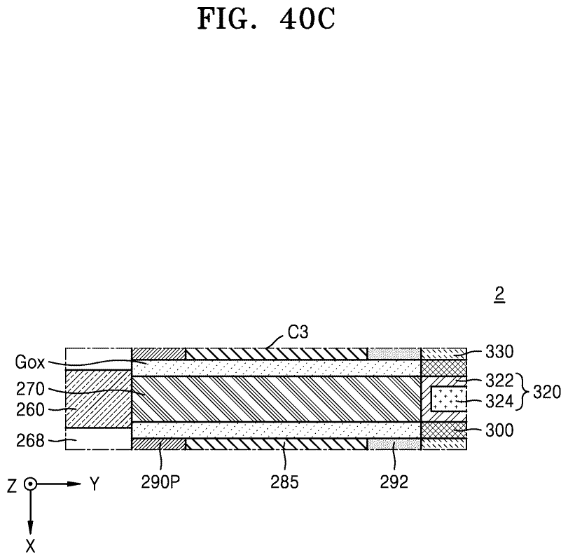

FIG. 39 is a perspective view illustrating a semiconductor memory device according to an implementation, and FIGS. 40A, 40B, and 40C are cross-sectional views illustrating the semiconductor memory device according to the implementation. Specifically, FIGS. 40A, 40B, and 40C are cross-sectional views respectively taken along a plane C1, a plane C2, and a plane C3 of FIG. 39. Descriptions of FIG. 39 and FIGS. 40A, 40B, and 40C which are made above with reference to FIGS. 3A, 3B, 3C, 3D, and 3E may be omitted.

Referring to FIG. 39 and FIGS. 40A, 40B, and 40C, a semiconductor memory device 2 may include a substrate 110, a plurality of channel patterns 270 on the substrate 110, a plurality of gate electrode layers 285 provided between a plurality of gate dielectric layers Gox and surrounding at least parts of the plurality of channel patterns 270, a plurality of bit line structures 320 connected to the plurality of channel patterns 270, and a plurality of capacitor structures 260 connected to the plurality of channel patterns 270. In a second horizontal direction (the Y direction), each of the plurality of bit line structures 320 may be connected to one end of each of the plurality of channel patterns 270, and each of the plurality of capacitor structures 260 may be connected to the other end of each of the plurality of channel patterns 270. The plurality of gate dielectric layers Gox may respectively surround the plurality of channel patterns 270. The plurality of gate electrode layers 285 may each surround an upper surface, a lower surface, and both side surfaces of each of the plurality of channel patterns 270 in a first horizontal direction (the X direction) with the plurality of gate dielectric layers Gox between the plurality of gate electrode layers 285 and the plurality of channel patterns 270. In a vertical cross-section (an X-Z vertical cross-section) formed by the first horizontal direction (the X direction) and a vertical direction (the Z direction), the gate electrode layer 285 may continuously extend and surround the channel pattern 270. For example, the gate electrode layer 285 may have a gate-all-around (GAA) structure that completely surrounds the channel pattern 270 in the vertical cross-section (the X-Z vertical cross-section) formed by the first horizontal direction (the X direction) and the vertical direction (the Z direction).

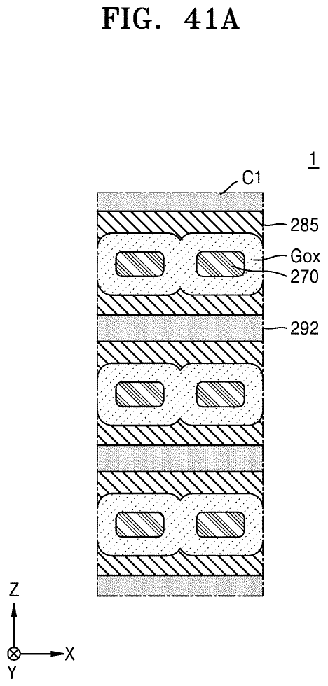

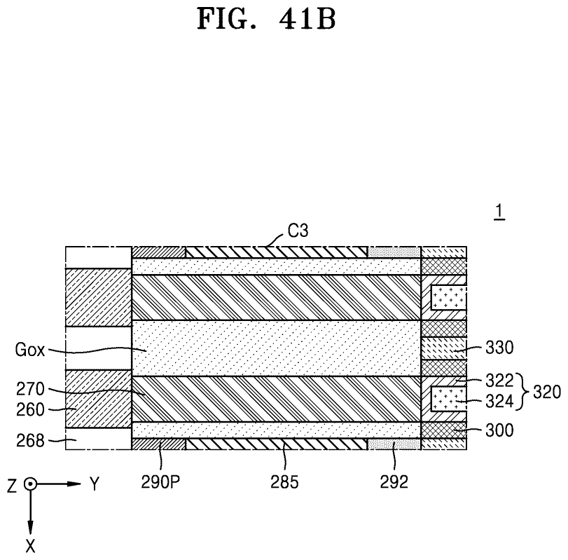

FIG. 41A and FIG. 41B are cross-sectional views illustrating the semiconductor memory device according to an implementation. Specifically, FIGS. 41A and 41B are cross-sectional views respectively taken along planes of the semiconductor memory device 1 of FIGS. 3A, 3B, 3C, 3D, and 3E which correspond to a plane C1 and a plane C3 of FIG. 39.

Referring to FIGS. 41A and 41B, the plurality of gate dielectric layers Gox included in the semiconductor memory device 1 may surround the plurality of channel patterns 270. In the semiconductor memory devices 1 illustrated in FIGS. 41A and 41B, a cross-sectional view taken along a plane corresponding to the plane C2 of FIG. 39 may be substantially the same as the cross-section of FIG. 40B. Each of the plurality of gate electrode layers 285 may surround a part of an upper surface, a part of a lower surface, and both side surfaces of each of the plurality of channel patterns 270 with each of the plurality of gate dielectric layers Gox between the plurality of gate electrode layers 285 and the plurality of channel patterns 270. In the vertical cross-section (the X-Z vertical cross-section) formed by the first horizontal direction (the X direction) and the vertical direction (the Z direction), the gate electrode layer 285 may have a double gate shape that covers the upper and lower surfaces of the channel pattern 270.

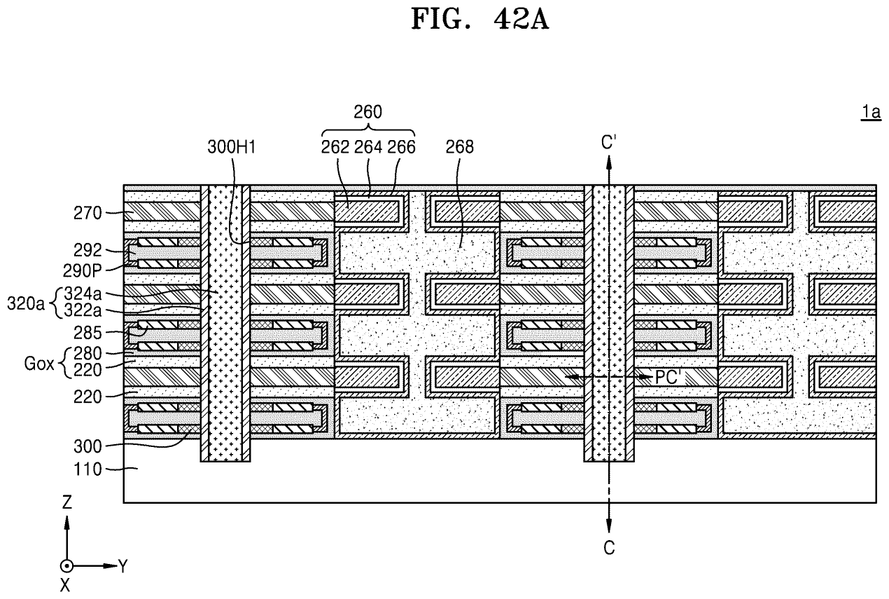

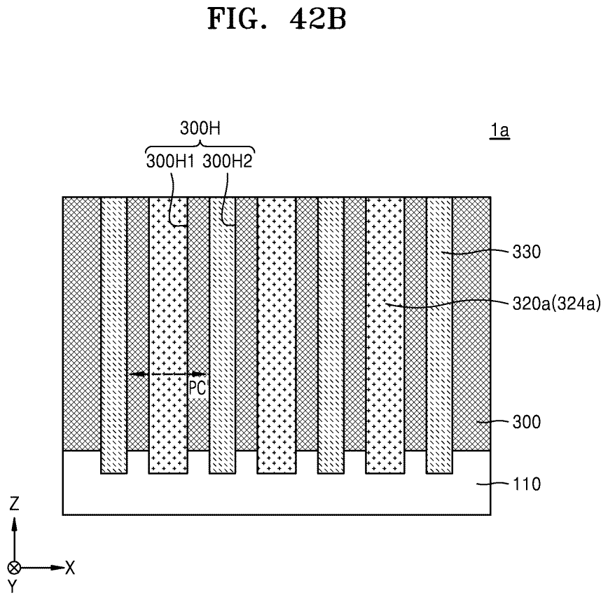

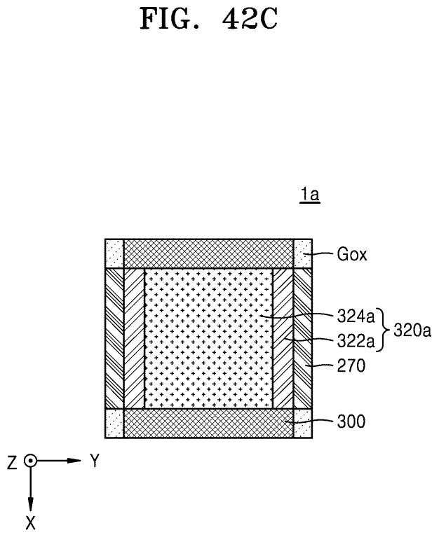

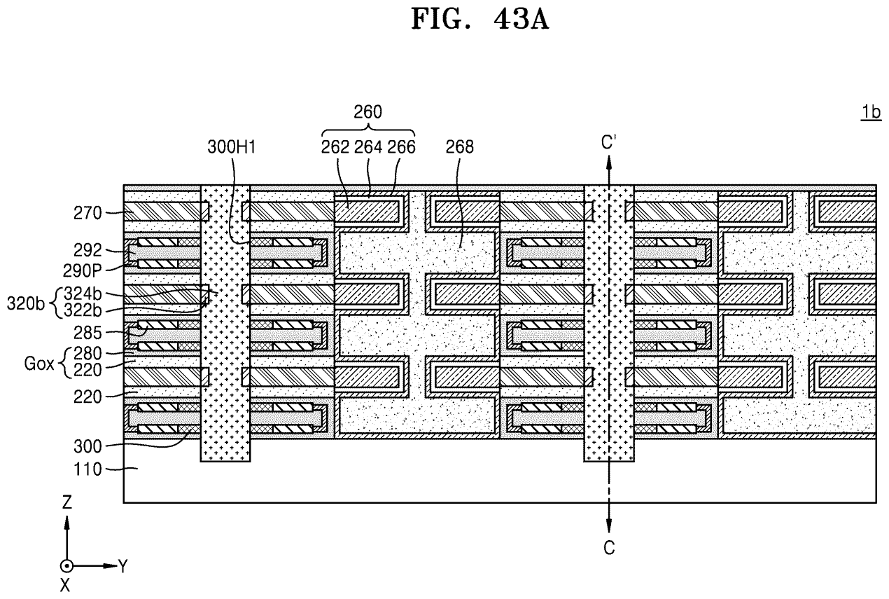

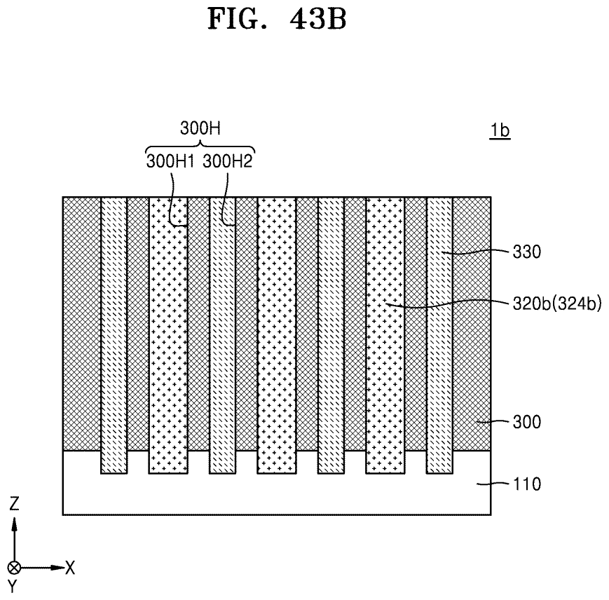

FIGS. 42A, 42B, and 42C are cross-sectional views illustrating a semiconductor memory device according to an implementation. FIG. 42A is a cross-sectional view taken along a position corresponding to line B-B′ of FIG. 3A, FIG. 42B is a cross-sectional view taken along line C-C′ of FIG. 42A, and FIG. 43C is a cross-sectional view taken along line PC′ of FIGS. 42A and 42B.

Referring to FIGS. 42A, 42B, and 42C, a semiconductor memory device 1a may include a substrate 110, a plurality of channel patterns 270 on the substrate 110, a plurality of gate electrode layers 285 provided between a plurality of gate dielectric layers Gox and surrounding at least part of each of the plurality of channel patterns 270, a plurality of bit line structures 320a connected to the plurality of channel patterns 270, and a plurality of capacitor structures 260 connected to the plurality of channel patterns 270. In a second horizontal direction (the Y direction), the plurality of bit line structures 320a may each be connected to one end of each of the plurality of channel patterns 270, and the plurality of capacitor structures 260 may each be connected to the other end of each of the plurality of channel patterns 270.

The plurality of bit line structures 320a may each include a core conductive layer 324a and an oxide semiconductor layer 322a. The oxide semiconductor layer 322a may be between the core conductive layer 324a and the channel pattern 270. The oxide semiconductor layer 322a may cover a side surface of the core conductive layer 324a. In some implementations, the oxide semiconductor layer 322a may cover both sides of the core conductive layer 324a in the second horizontal direction (the Y direction). The oxide semiconductor layer 322a may not cover both side surfaces of the core conductive layer 324a in a first horizontal direction (the X direction).

FIGS. 43A and 43B are cross-sectional views illustrating semiconductor memory devices according to implementations. Specifically, FIG. 43A is a cross-sectional view taken along a position corresponding to line B-B′ of FIG. 3A, and FIG. 43B is a cross-sectional view taken along line C-C′ of FIG. 43A.

Referring to FIGS. 43A and 43B, a semiconductor memory device 1b includes a substrate 110, a plurality of channel patterns 270 on the substrate 110, a plurality of gate electrode layers 285 provided between a plurality of gate dielectric layers Gox and surrounding at least parts of the plurality of channel patterns 270, a plurality of bit line structures 320b connected to the plurality of channel patterns 270, and a plurality of capacitor structures 260 connected to the plurality of channel patterns 270. In a second horizontal direction (the Y direction), each of the plurality of bit line structures 320b may be connected to one end of each of the plurality of channel patterns 270, and each of the plurality of capacitor structures 260 may be connected to the other end of each of the plurality of channel patterns 270.

The plurality of bit line structures 320b may each include a core conductive layer 324b and an oxide semiconductor layer 322b. The oxide semiconductor layer 322b may be between the core conductive layer 324b and the channel pattern 270. The oxide semiconductor layer 322b may cover a part of a side surface of the core conductive layer 324b. In some implementations, the oxide semiconductor layer 322b may cover a part of one side surface of the core conductive layer 324b facing the channel pattern 270. The oxide semiconductor layer 322b may cover only the other end of the channel pattern 270 facing the bit line structure 320b. For example, the oxide semiconductor layer 322b may not be provided between the core conductive layer 324b and the gate dielectric layer Gox, between the core conductive layer 324b and a spacer layer 300, and between the core conductive layer 324b and an interlayer insulating layer 292.

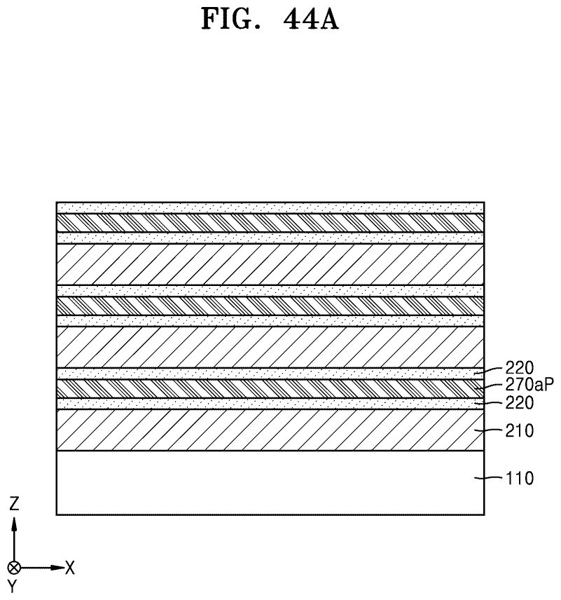

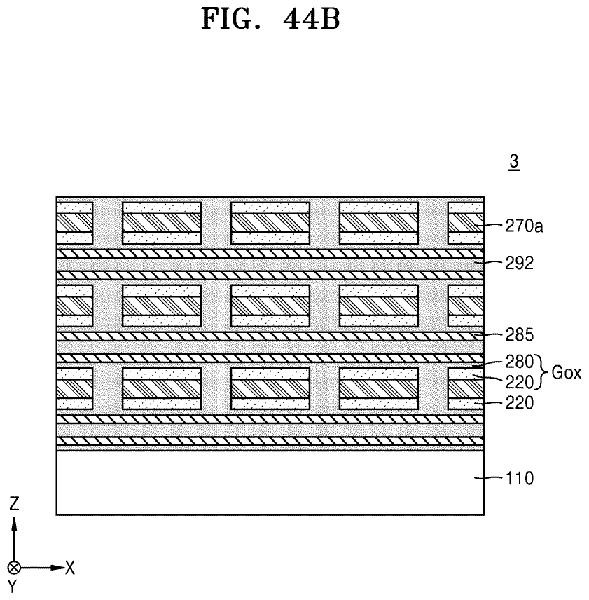

FIG. 44A is a view illustrating a method of manufacturing a semiconductor memory device, according to an implementation, and FIG. 44B is a view illustrating a semiconductor memory device according to an implementation. Specifically, FIG. 44A is a cross-sectional view taken along a position corresponding to line A-A′ of FIG. 4B, and FIG. 44B is a cross-sectional view taken along a position corresponding to line A-A′ of FIG. 3B.

Referring to FIGS. 44A and 44B, a plurality of sacrificial insulating layers 210, a plurality of base insulating layers 220, and a plurality of channel material layers 270aP are formed on a substrate 110. The plurality of sacrificial insulating layers 210, the plurality of base insulating layers 220, and the plurality of channel material layers 270aP may be formed by a deposition process, such as chemical vapor deposition (CVD), plasma enhanced CVD (PECVD), or atomic layer deposition (ALD).

In some implementations, a base insulating layer 220 may be between the sacrificial insulating layer 210 and the channel material layer 270aP. For example, the base insulating layers 220 may be on and beneath the sacrificial insulating layer 210, and the base insulating layers 220 may be on and beneath the channel material layer 270aP. For example, a plurality of sacrificial insulating layers 210 and a plurality of channel material layers 270aP may be alternately arranged between a pair of base insulating layers 220 adjacent to each other in a vertical direction (the Z direction) among the plurality of base insulating layers 220.

Thereafter, a semiconductor memory device 3 may be manufactured by referring to FIGS. 5A, 5B, 6A, 6B, 7A, 7B, 8A, 8B, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, and 20B and FIGS. 24A, 24B, 25A, 25B, 26A, 26B,. 27A, 27B, 28A, 28B, 29A, 29B, 30A, 30B, 31A, 31B, 32A, 32B, 33A, 33B, 34A, 34B, 34C, 35A, 35B, 35C, 36A, 36B, 36C, 37A, and 37B. The channel material layer 270aP may be divided into a plurality of channel patterns 270a, just as the sacrificial semiconductor layer 230 illustrated in FIGS. 5A, 5B, 6A, 6B, 7A, 7B, 8A, 8B, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, and 16C may be divided into the plurality of channel patterns 270a. For example, when the channel material layer 270aP has relatively superior thermal stability than the channel material layer 270P illustrated in FIGS. 22A and 22B, the process of forming the channel material layer 270aP instead of the sacrificial semiconductor layer 230 illustrated in FIGS. 4A and 4B and forming the channel pattern 270 after removing the sacrificial semiconductor layer 230 illustrated in FIGS. 21A, 21B, 22A, 22B, 23A, and 23B may be omitted, and thus, a process of manufacturing the semiconductor memory device 3 may be simplified.

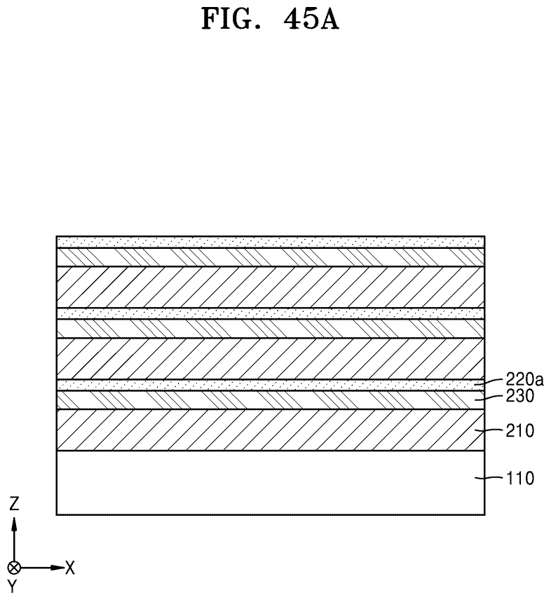

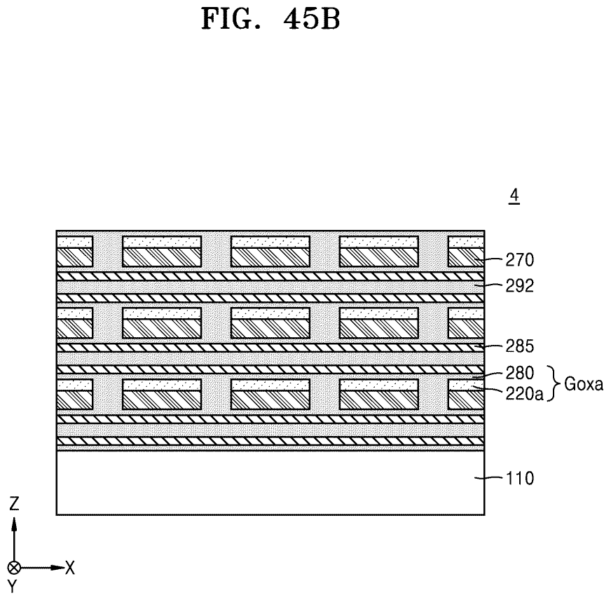

FIG. 45A is a view illustrating a method of manufacturing a semiconductor memory device, according to an implementation, and FIG. 45B is a view illustrating a semiconductor memory device according to an implementation. Specifically, FIG. 45A is a cross-sectional view taken along a position corresponding to line A-A′ of FIG. 4B, and FIG. 45B is a cross-sectional view taken along a position corresponding to line A-A′ of FIG. 3B.

Referring to FIG. 45A and FIG. 45B, a plurality of sacrificial insulating layers 210, a plurality of sacrificial semiconductor layers 230, and a plurality of base insulating layers 220a are formed on a substrate 110. The plurality of sacrificial insulating layers 210, the plurality of sacrificial semiconductor layers 230, and the plurality of base insulating layers 220a may be alternately stacked on the substrate 110.

For example, the base insulating layer 220a may be below the sacrificial insulating layer 210 but may not be on the sacrificial insulating layer 210, and the base insulating layer 220a may be on the sacrificial semiconductor layer 230 but may not be beneath the sacrificial semiconductor layer 230.

Thereafter, a semiconductor memory device 4 may be manufactured by referring to FIGS. 5A, 5B, 6A, 6B, 7A, 7B, 8A, 8B, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 21A, 21B, 22A, 22B, 23A, 23B, 24A, 24B, 25A, 25B, 26A, 26B,. 27A, 27B, 28A, 28B, 29A, 29B, 30A, 30B, 31A, 31B, 32A, 32B, 33A, 33B, 34A, 34B, 34C, 35A, 35B, 35C, 36A, 36B, 36C, 37A, and 37B. The semiconductor memory device 4 illustrated in FIG. 45B does not include the first base insulating layer among the plurality of base insulating layers 220 included in the semiconductor memory device 1 illustrated in FIGS. 3A, 3B, 3C, 3D, and 3E, and includes the second base insulating layers as the plurality of base insulating layers 220a. The semiconductor memory device 4 may include a plurality of gate dielectric layers Goxa. The plurality of gate dielectric layers Goxa may each include the base insulating layer 220a and a channel cover insulating layer 280. The base insulating layer 220a may cover an upper surface of the channel pattern 270, and the channel cover insulating layer 280 may cover an upper surface, a lower surface, and both side surfaces, in a first horizontal direction (the X direction), of a channel structure including the channel pattern 270 and the base insulating layer 220a covering the upper surface of the channel pattern 270.

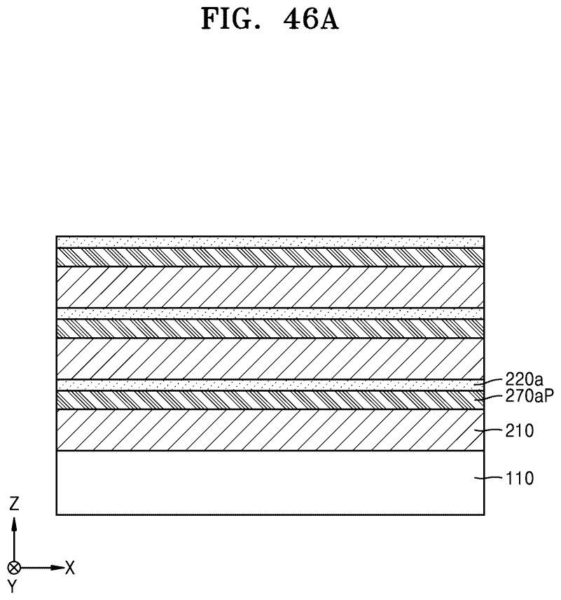

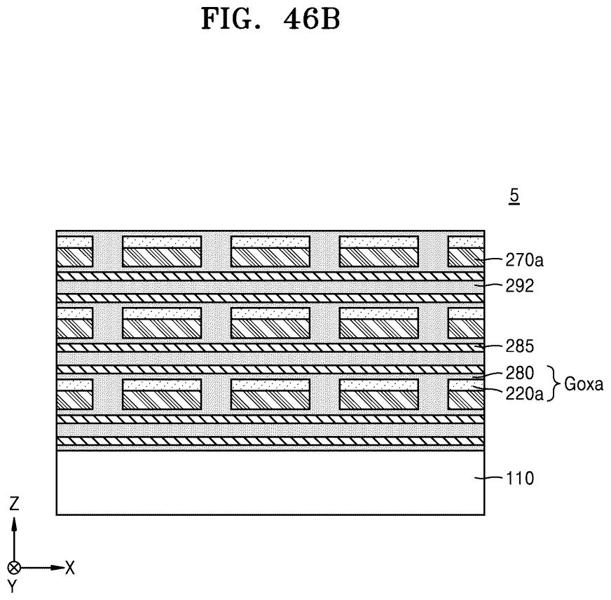

FIG. 46A is a view illustrating a method of manufacturing a semiconductor memory device, according to an implementation, and FIG. 46B is a view illustrating a semiconductor memory device according to an implementation. Specifically, FIG. 46A is a cross-sectional view taken along a position corresponding to line A-A′ of FIG. 4B, and FIG. 46B is a cross-sectional view taken along a position corresponding to line A-A′ of FIG. 3B.

Referring to FIGS. 46A and 46B, a plurality of sacrificial insulating layers 210, a plurality of channel material layers 270aP, and a plurality of base insulating layers 220a may be formed on a substrate 110. The plurality of sacrificial insulating layers 210, the plurality of channel material layers 270aP, and the plurality of base insulating layers 220a may be alternately stacked on the substrate 110.

Thereafter, a semiconductor memory device 5 may be manufactured by referring to FIGS. 5A, 5B, 6A, 6B, 7A, 7B, 8A, 8B, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, and 20B, and FIGS. 24A, 24B, 25A, 25B, 26A, 26B,. 27A, 27B, 28A, 28B, 29A, 29B, 30A, 30B, 31A, 31B, 32A, 32B, 33A, 33B, 34A, 34B, 34C, 35A, 35B, 35C, 36A, 36B, 36C, 37A, and37B.

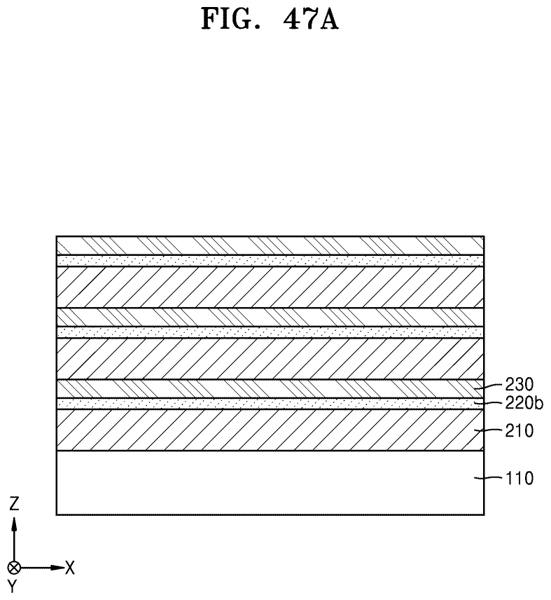

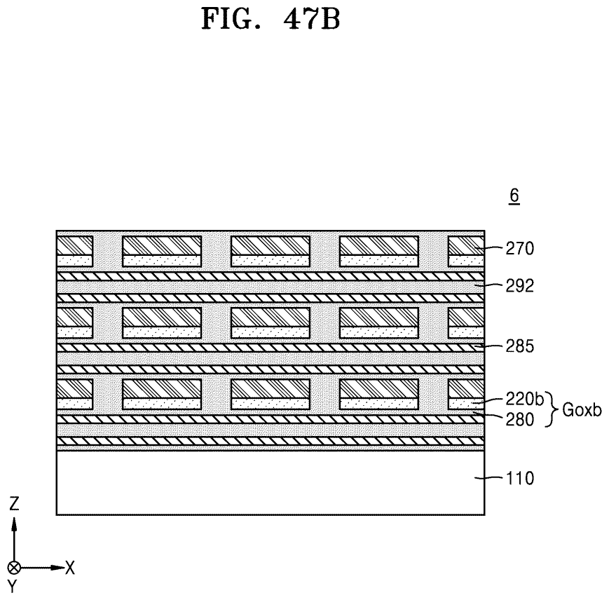

FIG. 47A is a view illustrating a method of manufacturing a semiconductor memory device, according to an implementation, and FIG. 47B is a view illustrating a semiconductor memory device according to an implementation. Specifically, FIG. 47A is a cross-sectional view taken along a position corresponding to line A-A′ of FIG. 4B, and FIG. 47B is a cross-sectional view taken along a position corresponding to line A-A′ of FIG. 3B.

Referring to FIG. 47A and FIG. 47B, a plurality of sacrificial insulating layers 210, a plurality of base insulating layers 220b, and a plurality of sacrificial semiconductor layers 230 are formed on a substrate 110. The plurality of sacrificial insulating layers 210, the plurality of base insulating layers 220b, and the plurality of sacrificial semiconductor layers 230 may be alternately stacked on the substrate 110.

For example, the base insulating layer 220b may be on the sacrificial insulating layer 210 but may not be beneath the sacrificial insulating layer 210, and the base insulating layer 220b may be beneath the sacrificial semiconductor layer 230 but may not be on the sacrificial semiconductor layer 230.

Thereafter, a semiconductor memory device 6 may be manufactured by referring to FIGS. 5A, 5B, 6A, 6B, 7A, 7B, 8A, 8B, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 21A, 21B, 22A, 22B, 23A, 23B, 24A, 24B, 25A, 25B, 26A, 26B,. 27A, 27B, 28A, 28B, 29A, 29B, 30A, 30B, 31A, 31B, 32A, 32B, 33A, 33B, 34A, 34B, 34C, 35A, 35B, 35C, 36A, 36B, 36C, 37A, and 37B. A semiconductor memory device 6 illustrated in FIG. 47B does not include the second base insulating layers 220 among the plurality of base insulating layers 220 included in the semiconductor memory device 1 illustrated in FIGS. 3A, 3B, 3C, 3D, and 3E, and includes the first base insulating layers as the plurality of base insulating layers 220b. The semiconductor memory device 6 may include a plurality of gate dielectric layers Goxb. The plurality of gate dielectric layers Goxb may each include a base insulating layer 220b and a channel cover insulating layer 280. The base insulating layer 220b may cover a lower surface of the channel pattern 270, and the channel cover insulating layer 280 may cover an upper surface, a lower surface, and both side surfaces, in a first horizontal direction (the X direction), of a channel structure including the channel pattern 270 and the base insulating layer 220b covering the lower surface of the channel pattern 270.

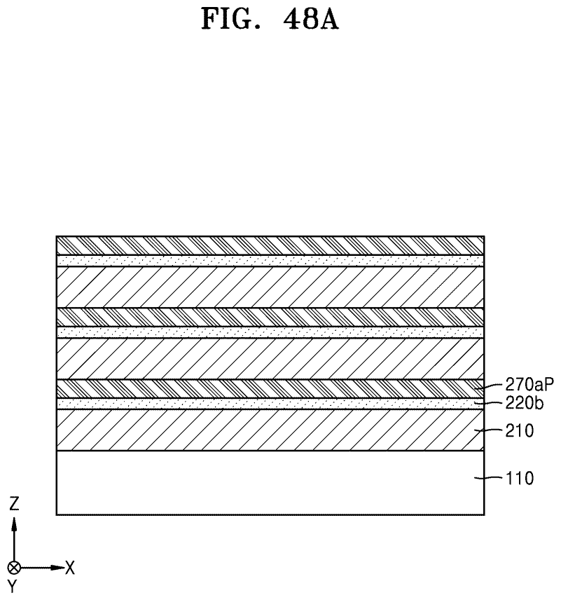

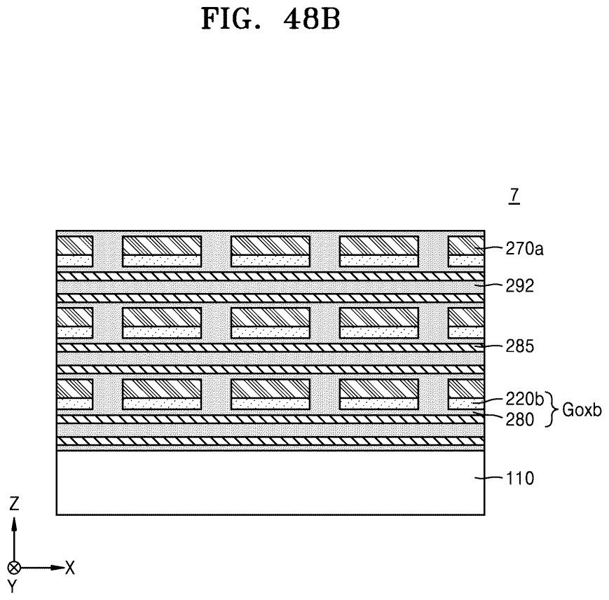

FIG. 48A is a view illustrating a method of manufacturing a semiconductor memory device, according to an implementation, and FIG. 48B is a view illustrating a semiconductor memory device according to an implementation. Specifically, FIG. 48A is a cross-sectional view taken along a position corresponding to line A-A′ of FIG. 4B, and FIG. 48B is a cross-sectional view taken along a position corresponding to line A-A′ of FIG. 3B.

Referring to FIGS. 48A and 48B, a plurality of sacrificial insulating layers 210, a plurality of base insulating layers 220b, and a plurality of channel material layers 270aP are formed on a substrate 110. The plurality of sacrificial insulating layers 210, the plurality of base insulating layers 220b, and the plurality of channel material layers 270aP may be alternately stacked on the substrate 110.

Thereafter, a semiconductor memory device 7 may be manufactured by referring to FIGS. 5A, 5B, 6A, 6B, 7A, 7B, 8A, 8B, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, and20B and FIGS. 24A, 24B, 25A, 25B, 26A, 26B,. 27A, 27B, 28A, 28B, 29A, 29B, 30A, 30B, 31A, 31B, 32A, 32B, 33A, 33B, 34A, 34B, 34C, 35A, 35B, 35C, 36A, 36B, 36C, 37A, and 37B.

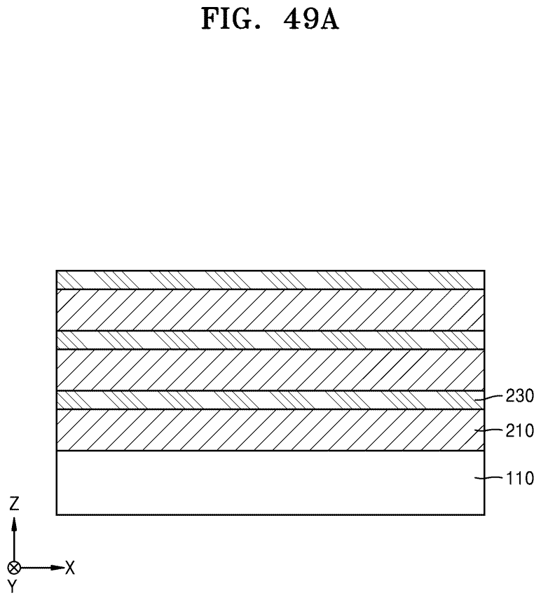

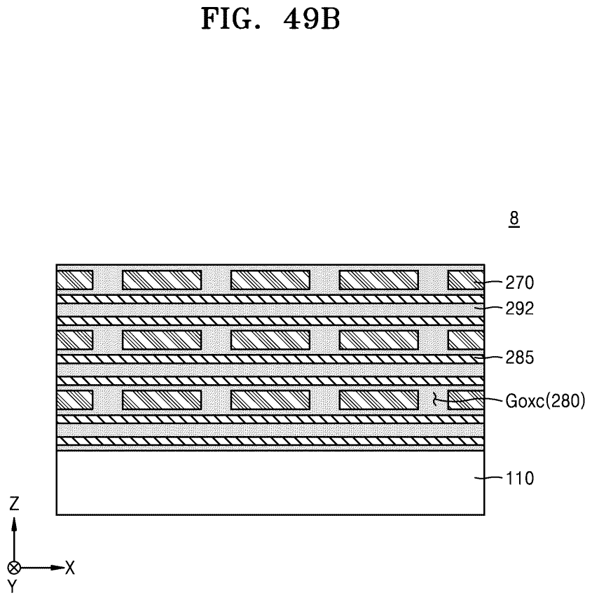

FIG. 49A is a view illustrating a method of manufacturing a semiconductor memory device, according to an implementation, and FIG. 49B is a view illustrating a semiconductor memory device according to an implementation. Specifically, FIG. 49A is a cross-sectional view taken along a position corresponding to line A-A′ of FIG. 4B, and FIG. 49B is a cross-sectional view taken along a position corresponding to line A-A′ of FIG. 3B.

Referring to FIGS. 49A and 49B, a plurality of sacrificial insulating layers 210 and a plurality of sacrificial semiconductor layers 230 are formed on a substrate 110. The plurality of sacrificial insulating layers 210 and the plurality of sacrificial semiconductor layers 230 may be alternately stacked on the substrate 110.

Thereafter, a semiconductor memory device 8 may be manufactured by referring to FIGS. 5A, 5B, 6A, 6B, 7A, 7B, 8A, 8B, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 21A, 21B, 22A, 22B, 23A, 23B, 24A, 24B, 25A, 25B, 26A, 26B,. 27A, 27B, 28A, 28B, 29A, 29B, 30A, 30B, 31A, 31B, 32A, 32B, 33A, 33B, 34A, 34B, 34C, 35A, 35B, 35C, 36A, 36B, 36C, 37A, and 37B. The semiconductor memory device 8 illustrated in FIG. 49B may not include the plurality of base insulating layers 220 included in the semiconductor memory device 1 illustrated in FIGS. 3A, 3B, 3C, 3D, and 3E. The semiconductor memory device 8 may include a plurality of gate dielectric layers Goxc. The plurality of gate dielectric layers Goxc may each include a channel cover insulating layer 280. The channel cover insulating layer 280 may cover an upper surface, a lower surface, and both side surfaces, in a first horizontal direction (the X direction), of the channel pattern 270.

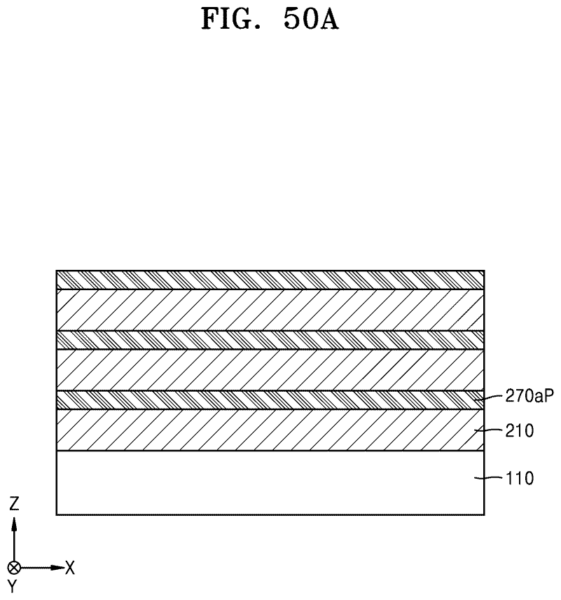

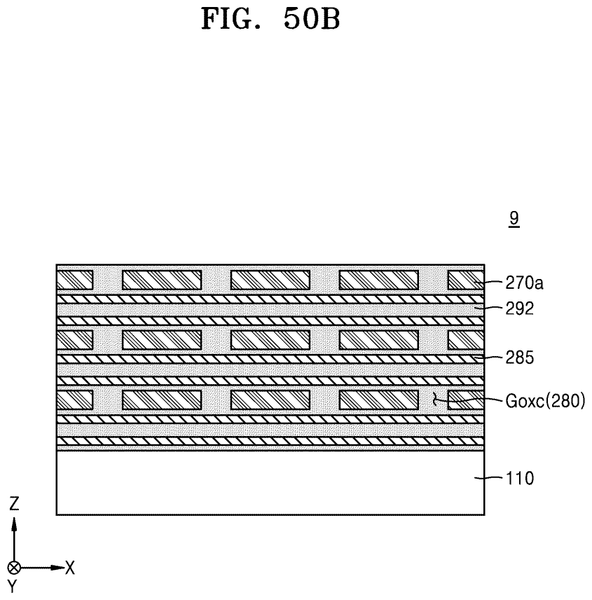

FIG. 50A is a view illustrating a method of manufacturing a semiconductor memory device, according to an implementation, and FIG. 50B is a view illustrating a semiconductor memory device according to an implementation. Specifically, FIG. 50A is a cross-sectional view taken along a position corresponding to line A-A′ of FIG. 4B, and FIG. 50B is a cross-sectional view taken along a position corresponding to line A-A′ of FIG. 3B.

Referring to FIGS. 50A and 50B, a plurality of sacrificial insulating layers 210 and a plurality of channel material layers 270aP are formed on a substrate 110. The plurality of sacrificial insulating layers 210 and the plurality of channel material layers 270aP may be alternately stacked on the substrate 110.

Thereafter, a semiconductor memory device 9 may be manufactured by referring to FIGS. 5A, 5B, 6A, 6B, 7A, 7B, 8A, 8B, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, and 20B and FIGS. 24A, 24B, 25A, 25B, 26A, 26B,. 27A, 27B, 28A, 28B, 29A, 29B, 30A, 30B, 31A, 31B, 32A, 32B, 33A, 33B, 34A, 34B, 34C, 35A, 35B, 35C, 36A, 36B, 36C, 37A, and 37B.

Although the present disclosure is described in detail with reference to preferred implementations, the present disclosure is not limited to the implementations described above, and various modifications and changes may be made by those skilled in the art within the technical idea and scope of the present disclosure.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor memory device comprising:
a channel pattern;
a gate electrode layer surrounding at least part of each of an upper surface and a lower surface of the channel pattern, the gate electrode layer extending in a first horizontal direction;
a bit line structure connected to a first end of the channel pattern in a second horizontal direction that is orthogonal to the first horizontal direction, the bit line structure extending in a vertical direction;
a capacitor structure connected to a second end of the channel pattern in the second horizontal direction;
a gate dielectric layer between the channel pattern and the gate electrode layer, the gate dielectric layer covering the upper surface of the channel pattern, the lower surface of the channel pattern, and both side surfaces of the channel pattern that are opposite to each other in the first horizontal direction; and
a bit line shield structure on a side of the bit line structure in the first horizontal direction, the bit line shield structure extending in the vertical direction,
wherein the gate dielectric layer includes
a base insulating layer covering at least one of the upper surface and the lower surface of the channel pattern, and
a channel cover insulating layer covering an upper surface of a channel structure, a lower surface of the channel structure, and both side surfaces of the channel structure that are opposite to each other in the first horizontal direction, the channel structure including the channel pattern and the base insulating layer.

2. The semiconductor memory device of claim 1, wherein the base insulating layer comprises a pair of base insulating layers respectively covering the upper surface and the lower surface of the channel pattern.

3. The semiconductor memory device of claim 1, wherein the bit line structure comprises a core conductive layer and an oxide semiconductor layer, and the oxide semiconductor layer is between the core conductive layer and the channel pattern.

4. The semiconductor memory device of claim 1, wherein the channel pattern includes an oxide semiconductor material.

5. The semiconductor memory device of claim 1, wherein a horizontal width of the gate electrode layer in the second horizontal direction is less than a horizontal width of the channel pattern in the second horizontal direction.

6. The semiconductor memory device of claim 5, comprising a gate spacer layer connected to a first end of the gate electrode layer in the second horizontal direction, and the gate spacer layer is between the gate electrode layer and the bit line structure.

7. The semiconductor memory device of claim 6, comprising a gate isolation insulating pattern connected to a second end of the gate electrode layer in the second horizontal direction,
wherein the gate isolation insulating pattern has a U-shaped vertical cross-section including a pair of horizontal portions and a vertical portion connected to the pair of horizontal portions,
wherein a first end of each of the pair of horizontal portions in the second horizontal direction is connected to the second end of the gate electrode layer, and
wherein a second end of each of the pair of horizontal portions in the second horizontal direction is connected to a respective end of both ends of the vertical portion in the vertical direction.

8. The semiconductor memory device of claim 7, wherein a thickness of each of the pair of horizontal portions of the gate isolation insulating pattern along the vertical direction is less than a thickness of the gate electrode layer along the vertical direction.

9. The semiconductor memory device of claim 6, comprising a bit line spacer layer between the bit line structure and the bit line shield structure,
wherein the gate spacer layer and the bit line spacer layer include the same material.

10. The semiconductor memory device of claim 1, wherein
a horizontal width of the bit line structure in the first horizontal direction is greater than a horizontal width of the bit line shield structure in the first horizontal direction, and
a horizontal width of the bit line structure in the second horizontal direction is equal to a horizontal width of the bit line shield structure in the second horizontal direction.

11. A semiconductor memory device comprising:
a plurality of channel patterns separated from each other in a first horizontal direction, a second horizontal direction that is orthogonal to the first horizontal direction, and a vertical direction;
a plurality of gate electrode layers respectively surrounding at least part of each of upper surfaces and lower surfaces of the plurality of channel patterns, the plurality of gate electrode layers extending in the first horizontal direction;
a plurality of bit line structures connected to first ends of the plurality of channel patterns in the second horizontal direction, the plurality of bit line structures being separated from each other in the first horizontal direction and extending in the vertical direction;
a plurality of bit line shield structures arranged with the plurality of bit line structures in an alternating fashion in the first horizontal direction, the plurality of bit line shield structures extending in the vertical direction;
a plurality of capacitor structures connected to second ends of the plurality of channel patterns in the second horizontal direction; and
a plurality of gate dielectric layers respectively between the plurality of channel patterns and the plurality of gate electrode layers, the plurality of gate dielectric layers respectively covering the upper surfaces, the lower surfaces, and both side surfaces of the plurality of channel patterns that are opposite to each other in the first horizontal direction,
wherein each of the plurality of gate dielectric layers includes
a pair of base insulating layers respectively covering the upper surface and the lower surface of a respective channel pattern of the plurality of channel patterns, and
a channel cover insulating layer covering an upper surface, a lower surface, and both side surfaces of a respective channel structure that are opposite to each other in the first horizontal direction, the respective channel structure including the respective channel pattern and the pair of base insulating layers.

12. The semiconductor memory device of claim 11, wherein channel patterns of the plurality of channel patterns that are aligned in the vertical direction are each connected to both ends of a respective bit line structure of the plurality of bit line structures in the second horizontal direction.

13. The semiconductor memory device of claim 11, wherein
each of the plurality of bit line structures includes a core conductive layer and an oxide semiconductor layer, and the oxide semiconductor layer is between the core conductive layer and each of the plurality of channel patterns, and
each of the plurality of channel patterns includes an oxide semiconductor material.

14. The semiconductor memory device of claim 13, wherein the oxide semiconductor layer covers both side surfaces of the core conductive layer in the second horizontal direction.

15. The semiconductor memory device of claim 13, wherein the oxide semiconductor layer has a ring shape in a plane that is orthogonal to the vertical direction, and the oxide semiconductor layer surrounds the core conductive layer.

16. The semiconductor memory device of claim 11, comprising:
a plurality of gate spacer layers connected respectively to first ends of the plurality of gate electrode layers in the second horizontal direction, the plurality of gate spacer layers being respectively between the plurality of gate electrode layers and the plurality of bit line structures; and
a plurality of gate isolation insulating patterns connected respectively to second ends of the plurality of gate electrode layers in the second horizontal direction,
wherein, in the second horizontal direction, a horizontal width of each of the plurality of gate electrode layers is less than a horizontal width of each of the plurality of channel patterns.

17. The semiconductor memory device of claim 16, wherein
each of the gate isolation insulating patterns has a U-shaped vertical cross-section including a pair of horizontal portions and a vertical portion connected to the pair of horizontal portions, and
the plurality of channel patterns comprise a pair of channel patterns adjacent to each other in the vertical direction, and the plurality of gate electrode layers comprise a pair of gate electrode layers that are between the pair of channel patterns in the vertical direction, and
first ends of the pair of gate electrode layers are respectively connected to first ends of the pair of horizontal portions in the second horizontal direction, and both ends of the vertical portion in the vertical direction are respectively connected to second ends of the pair of horizontal portions in the second horizontal direction.

18. A semiconductor memory device comprising:
a plurality of channel patterns separated from each other in a first horizontal direction, a second horizontal direction that is orthogonal to the first horizontal direction, and a vertical direction, and each of the plurality of channel patterns including an oxide semiconductor material;
a plurality of gate electrode layers respectively surrounding at least part of each of upper surfaces and lower surfaces of the plurality of channel patterns, the plurality of gate electrode layers extending in the first horizontal direction;
a plurality of bit line structures connected to first ends of the plurality of channel patterns in the second horizontal direction, the plurality of bit line structures being separated from each other in the first horizontal direction and extending in the vertical direction, each of the plurality of bit line structures including a core conductive layer and an oxide semiconductor layer, the oxide semiconductor layer being between the core conductive layer and each of the plurality of channel patterns;
a plurality of bit line shield structures arranged with the plurality of bit line structures in an alternating fashion in the first horizontal direction, the plurality of bit line shield structures extending in the vertical direction and being separated from the plurality of channel patterns;
a plurality of capacitor structures connected to second ends of the plurality of channel patterns in the second horizontal direction; and
a plurality of gate dielectric layers respectively between the plurality of channel patterns and the plurality of gate electrode layers, the plurality of gate dielectric layers respectively covering the upper surfaces, the lower surfaces, and both side surfaces of the plurality of channel patterns that are opposite to each other in the first horizontal direction,
wherein each of the plurality of gate dielectric layers includes
a pair of base insulating layers respectively covering the upper surface and the lower surface of a respective channel pattern of the plurality of channel patterns, and
a channel cover insulating layer covering an upper surface, a lower surface, and both side surfaces of a respective channel structure that are opposite to each other in the first horizontal direction, the respective channel structure including the respective channel pattern and the pair of base insulating layers.

19. The semiconductor memory device of claim 18, wherein
channel patterns of the plurality of channel patterns that are aligned in the vertical direction are each connected to both ends of a respective bit line structure of the plurality of bit line structures in the second horizontal direction, and
the oxide semiconductor layer has a ring shape in a plane that is orthogonal to the vertical direction, and the oxide semiconductor layer surrounds the core conductive layer.

20. The semiconductor memory device of claim 18, comprising:
a plurality of gate spacer layers connected respectively to first ends of the plurality of gate electrode layers in the second horizontal direction, the plurality of gate spacer layers being respectively between the plurality of gate electrode layers and the plurality of bit line structures; and
a plurality of bit line spacer layers respectively between the plurality of bit line structures and the plurality of bit line shield structures,
wherein the plurality of gate spacer layers include the same material as the plurality of bit line spacer layers, and
wherein a horizontal width of each of the plurality of gate electrode layers in the second horizontal direction is less than a horizontal width of each of the plurality of channel patterns in the second horizontal direction.
